(19) United States
(12) Patent Application Publication
(10) Pub. No.: US 2026/0293081 A1
(43) Pub. Date: Sep. 24, 2026

(54) SEMICONDUCTOR MEMORY DEVICE

(71) Applicant: Kioxia Corporation, Tokyo (JP)

(72) Inventors: Kazuki ESHIRO, Yokohama Kanagawa (JP); Nobuyoshi SAITO, Ota Tokyo (JP)

(73) Assignee: Kioxia Corporation, Tokyo (JP)

(21) Appl. No.: 19/323,969

(22) Filed: Sep. 9, 2025

(30) Foreign Application Priority Data
Mar. 19, 2025 (JP) 2025-045770

(51) Int. Cl. H10B 12/00

(52) U.S. Cl. CPC H10B 12/00

(57) ABSTRACT

A semiconductor memory device includes: a first wiring extending in a first direction; a second wiring extending in a second direction; a first semiconductor member disposed between the first wiring and the second wiring, extending in a third direction, and electrically connected to the first wiring and the second wiring; a first electrode facing both surfaces in the first direction and both surfaces in the second direction of the first semiconductor member; a connection electrode extending in the third direction and connected to the first semiconductor member and the first wiring; a second semiconductor member extending in the third direction along both surfaces of the connection electrode in the first direction and both surfaces of the connection electrode in the second direction, and connected to the first electrode and the first wiring; and a second electrode facing both surfaces of the second semiconductor member in the first direction.

### CROSS-REFERENCE TO RELATED APPLICATIONS

This application is based upon and claims the benefit of Japanese Patent Application No. 2025-045770, filed on Mar. 19, 2025, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic circuit diagram for describing a write operation of the semiconductor memory device;

FIG. 3 is a schematic circuit diagram for describing a read operation of the semiconductor memory device;

FIG. 4 is a schematic perspective view illustrating a configuration of a part of the semiconductor memory device;

FIG. 5 is a schematic perspective view illustrating a configuration of a part of the semiconductor memory device;

FIG. 6 is a schematic perspective view illustrating a configuration of a part of the semiconductor memory device;

FIG. 7 is a schematic cross-sectional view illustrating a configuration of a part of the semiconductor memory device;

FIG. 8 is a schematic cross-sectional view illustrating a configuration of a part of the semiconductor memory device;

FIG. 9 is a schematic cross-sectional view illustrating a configuration of a part of the semiconductor memory device;

FIG. 10 is a schematic cross-sectional view illustrating a configuration of a part of the semiconductor memory device;

FIG. 11 is a schematic cross-sectional view for describing a manufacturing method of the semiconductor memory device;

FIG. 12 is a schematic cross-sectional view for describing the manufacturing method;

FIG. 13 is a schematic cross-sectional view for describing the manufacturing method;

FIG. 14 is a schematic perspective view for describing the manufacturing method;

FIG. 15 is a schematic perspective view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic cross-sectional view for describing the manufacturing method;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic circuit diagram illustrating a configuration of a part of a semiconductor memory device according to a second embodiment;

FIG. 84 is a schematic circuit diagram for describing a read operation of the semiconductor memory device;

FIG. 85 is a schematic cross-sectional view illustrating a configuration of a part of the semiconductor memory device;

FIG. 86 is a schematic cross-sectional view illustrating a configuration of a part of the semiconductor memory device;

FIG. 87 is a schematic cross-sectional view for describing a manufacturing method of the semiconductor memory device;

FIG. 88 is a schematic cross-sectional view for describing the manufacturing method;

FIG. 89 is a schematic cross-sectional view for describing the manufacturing method;

FIG. 90 is a schematic cross-sectional view for describing the manufacturing method;

FIG. 91 is a schematic cross-sectional view for describing the manufacturing method;

FIG. 92 is a schematic cross-sectional view for describing the manufacturing method;

FIG. 93 is a schematic cross-sectional view for describing the manufacturing method;

FIG. 94 is a schematic cross-sectional view for describing the manufacturing method;

FIG. 95 is a schematic cross-sectional view for describing the manufacturing method;

FIG. 96 is a schematic cross-sectional view for describing the manufacturing method;

FIG. 97 is a schematic cross-sectional view for describing the manufacturing method;

FIG. 98 is a schematic cross-sectional view for describing the manufacturing method;

FIG. 99 is a schematic cross-sectional view for describing the manufacturing method;

FIG. 100 is a schematic cross-sectional view for describing the manufacturing method;

FIG. 101 is a schematic cross-sectional view for describing the manufacturing method;

FIG. 102 is a schematic cross-sectional view for describing the manufacturing method;

FIG. 103 is a schematic cross-sectional view for describing the manufacturing method;

FIG. 104 is a schematic cross-sectional view for describing the manufacturing method;

FIG. 105 is a schematic cross-sectional view for describing the manufacturing method;

FIG. 106 is a schematic cross-sectional view for describing the manufacturing method;

FIG. 107 is a schematic cross-sectional view for describing the manufacturing method;

FIG. 108 is a schematic cross-sectional view for describing the manufacturing method;

FIG. 109 is a schematic cross-sectional view for describing the manufacturing method;

FIG. 110 is a schematic cross-sectional view for describing the manufacturing method;

FIG. 111 is a schematic cross-sectional view illustrating a configuration of a part of a modification of the semiconductor memory device according to the second embodiment;

FIG. 112 is a schematic cross-sectional view illustrating a configuration of a part of a semiconductor memory device according to a third embodiment;

FIG. 113 is a schematic cross-sectional view illustrating a configuration of a part of the semiconductor memory device according to the third embodiment;

FIG. 114 is a schematic cross-sectional view for describing a manufacturing method of the semiconductor memory device;

FIG. 115 is a schematic cross-sectional view for describing the manufacturing method;

FIG. 116 is a schematic cross-sectional view for describing the manufacturing method;

FIG. 117 is a schematic cross-sectional view for describing the manufacturing method;

FIG. 118 is a schematic cross-sectional view for describing the manufacturing method;

FIG. 119 is a schematic cross-sectional view for describing the manufacturing method;

FIG. 120 is a schematic cross-sectional view for describing the manufacturing method;

FIG. 121 is a schematic cross-sectional view for describing the manufacturing method;

FIG. 122 is a schematic cross-sectional view for describing the manufacturing method;

FIG. 123 is a schematic cross-sectional view for describing the manufacturing method;

FIG. 124 is a schematic cross-sectional view for describing the manufacturing method;

FIG. 125 is a schematic cross-sectional view for describing the manufacturing method;

FIG. 126 is a schematic cross-sectional view for describing the manufacturing method;

FIG. 127 is a schematic cross-sectional view for describing the manufacturing method;

FIG. 128 is a schematic cross-sectional view for describing the manufacturing method;

FIG. 129 is a schematic cross-sectional view for describing the manufacturing method;

FIG. 130 is a schematic cross-sectional view for describing the manufacturing method;

FIG. 131 is a schematic cross-sectional view for describing the manufacturing method;

FIG. 132 is a schematic cross-sectional view for describing the manufacturing method;

FIG. 133 is a schematic cross-sectional view for describing the manufacturing method;

FIG. 134 is a schematic cross-sectional view for describing the manufacturing method;

FIG. 135 is a schematic cross-sectional view for describing the manufacturing method;

FIG. 136 is a schematic cross-sectional view for describing the manufacturing method;

FIG. 137 is a schematic cross-sectional view for describing the manufacturing method;

FIG. 138 is a schematic cross-sectional view for describing the manufacturing method;

FIG. 139 is a schematic cross-sectional view for describing the manufacturing method;

FIG. 140 is a schematic cross-sectional view for describing the manufacturing method;

FIG. 141 is a schematic cross-sectional view for describing the manufacturing method;

FIG. 142 is a schematic cross-sectional view for describing the manufacturing method;

FIG. 143 is a schematic cross-sectional view for describing the manufacturing method;

FIG. 144 is a schematic cross-sectional view for describing the manufacturing method;

FIG. 145 is a schematic cross-sectional view for describing the manufacturing method;

FIG. 146 is a schematic cross-sectional view for describing the manufacturing method;

FIG. 147 is a schematic cross-sectional view for describing the manufacturing method;

FIG. 148 is a schematic cross-sectional view for describing the manufacturing method;

FIG. 149 is a schematic cross-sectional view for describing the manufacturing method;

FIG. 150 is a schematic cross-sectional view for describing the manufacturing method;

FIG. 151 is a schematic cross-sectional view for describing the manufacturing method;

FIG. 152 is a schematic cross-sectional view for describing the manufacturing method;

FIG. 153 is a schematic cross-sectional view for describing the manufacturing method;

FIG. 154 is a schematic cross-sectional view for describing the manufacturing method;

FIG. 155 is a schematic cross-sectional view for describing the manufacturing method;

FIG. 156 is a schematic cross-sectional view for describing the manufacturing method;

FIG. 157 is a schematic cross-sectional view for describing the manufacturing method;

FIG. 158 is a schematic cross-sectional view for describing the manufacturing method;

FIG. 159 is a schematic cross-sectional view for describing the manufacturing method;

FIG. 160 is a schematic cross-sectional view for describing the manufacturing method;

FIG. 161 is a schematic cross-sectional view for describing the manufacturing method;

FIG. 162 is a schematic cross-sectional view for describing the manufacturing method;

FIG. 163 is a schematic cross-sectional view for describing the manufacturing method;

FIG. 164 is a schematic cross-sectional view for describing the manufacturing method;

FIG. 165 is a schematic cross-sectional view for describing the manufacturing method;

FIG. 166 is a schematic cross-sectional view for describing the manufacturing method;

FIG. 167 is a schematic cross-sectional view for describing the manufacturing method;

FIG. 168 is a schematic cross-sectional view for describing the manufacturing method;

FIG. 169 is a schematic cross-sectional view for describing the manufacturing method;

FIG. 170 is a schematic cross-sectional view for describing the manufacturing method;

FIG. 171 is a schematic cross-sectional view for describing the manufacturing method;

FIG. 172 is a schematic cross-sectional view for describing the manufacturing method;

FIG. 173 is a schematic cross-sectional view for describing the manufacturing method;

FIG. 174 is a schematic cross-sectional view for describing the manufacturing method;

FIG. 175 is a schematic cross-sectional view for describing the manufacturing method;

FIG. 176 is a schematic cross-sectional view for describing the manufacturing method;

FIG. 177 is a schematic cross-sectional view illustrating a configuration of a part of a semiconductor memory device according to a fourth embodiment;

FIG. 178 is a schematic cross-sectional view for describing a manufacturing method of the semiconductor memory device; and

FIG. 179 is a schematic cross-sectional view for describing the manufacturing method.

### DETAILED DESCRIPTION

A semiconductor memory device according to one embodiment comprises: a first wiring extending in a first direction; a second wiring extending in a second direction intersecting with the first direction; a first semiconductor member disposed between the first wiring and the second wiring, extending in a third direction intersecting with the first direction and the second direction, and electrically connected to the first wiring and the second wiring; a first facing electrode facing both surfaces of the first semiconductor member in the first direction and both surfaces of the first semiconductor member in the second direction; a first connection electrode extending in the third direction and connected to the first semiconductor member and the first wiring; a second semiconductor member extending in the third direction along both surfaces of the first connection electrode in the first direction and both surfaces of the first connection electrode in the second direction, and connected to the first facing electrode and the first wiring; and a second facing electrode facing both surfaces of the second semiconductor member in the first direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction intersecting with a predetermined plane may be referred to as a first direction, a direction along this predetermined plane may be referred to as a second direction, and a direction along this predetermined plane and intersecting with the second direction may be referred to as a third direction. These first direction, second direction, and third direction may each correspond to any of the Z-direction, the X-direction, and the Y-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion of this configuration on a substrate side. An upper surface and an upper end of a certain configuration mean a surface and an end portion of this configuration on a side opposite to the substrate. A surface intersecting with the X-direction or the Y-direction is referred to as a side surface or the like.

In this specification, a “center position” of a certain configuration may mean, for example, a position of the center of a circumscribed circle of this configuration, and may mean the centroid on an image of this configuration.

In this specification, when indicating a material of each member, while elements contained in the material are described in parentheses, a component ratio of the elements is not described.

### First Embodiment

### Circuit Configuration

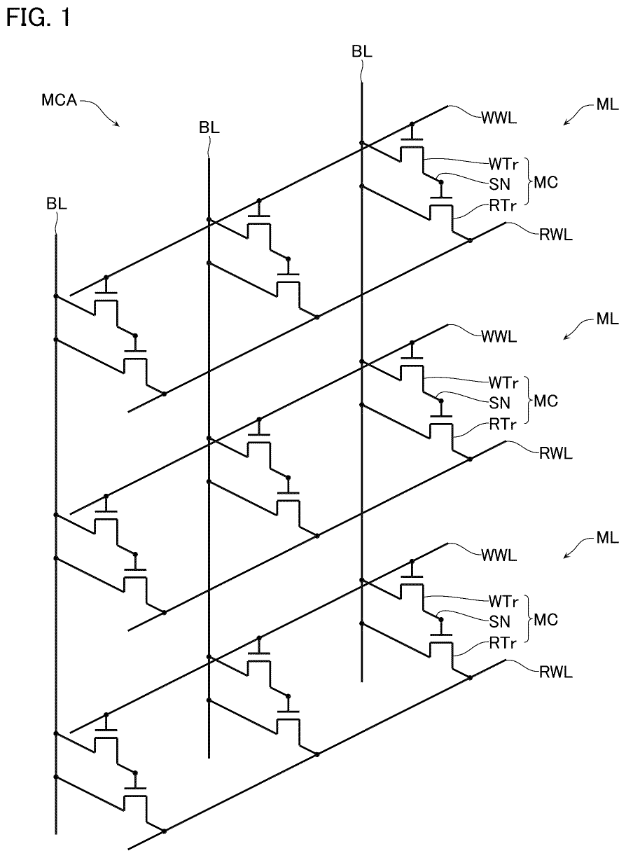

FIG. 1 is a schematic circuit diagram illustrating a configuration of a part of a semiconductor memory device according to the first embodiment. As illustrated in FIG. 1, the semiconductor memory device according to the embodiment includes a memory cell array MCA. The memory cell array MCA includes a plurality of memory layers ML, and a plurality of bit lines BL connected to these plurality of memory layers ML.

Each of the memory layers ML includes a write word line WWL, a read word line RWL, and a plurality of memory cells MC connected to these write word line WWL and read word line RWL. Each of the memory cells MC includes a write transistor WTr, a storage node SN, and a read transistor RTr.

The write transistor WTr is, for example, a field-effect type NMOS transistor. The write transistor WTr has one electrode connected to the bit line BL. The write transistor WTr has the other electrode connected to the storage node SN. The one and the other electrodes of the write transistor WTr function as a source electrode or a drain electrode corresponding to a voltage applied to the write transistor WTr. The write transistor WTr has a gate electrode connected to the write word line WWL.

The read transistor RTr is, for example, a field-effect type NMOS transistor. The read transistor RTr has one electrode connected to the bit line BL. The read transistor RTr has the other electrode connected to the read word line RWL. The one and the other electrodes of the read transistor RTr function as a source electrode or a drain electrode corresponding to a voltage applied to the read transistor RTr. The read transistor RTr has a gate electrode connected to the storage node SN.

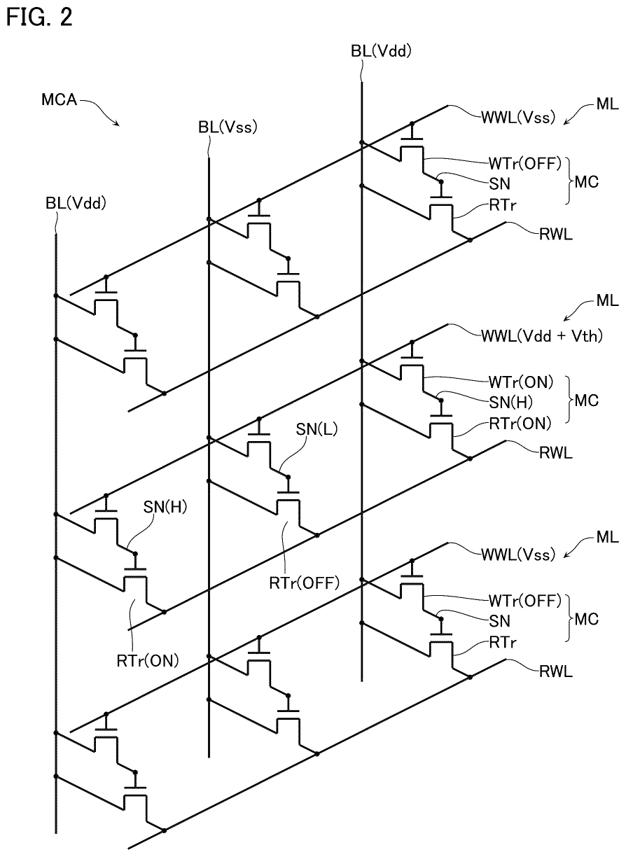

FIG. 2 is a schematic circuit diagram for describing a write operation of the semiconductor memory device according to the first embodiment.

In the write operation, for example, a voltage having a magnitude of a sum of a power supply voltage Vdd and a threshold voltage Vth of the write transistor WTr is applied to a write word line WWL that is a target of the write operation and a ground voltage Vss is applied to the other write word lines WWL among the plurality of write word lines WWL. Further, the power supply voltage Vdd or the ground voltage Vss is applied to bit lines BL that are target of the write operation among the plurality of bit lines BL corresponding to data to be written.

This turns a state of the storage node SN to an “H” state or an “L” state corresponding to the voltage of the bit line BL. The read transistor RTr connected to the storage node SN in the “H” state turns ON, and the read transistor RTr connected to the storage node SN in the “L” state turns OFF.

In the write operation, all the bit lines BL in the memory cell array MCA may be the target of the write operation, or a part (for example, one) of the bit lines BL may be the target of the write operation.

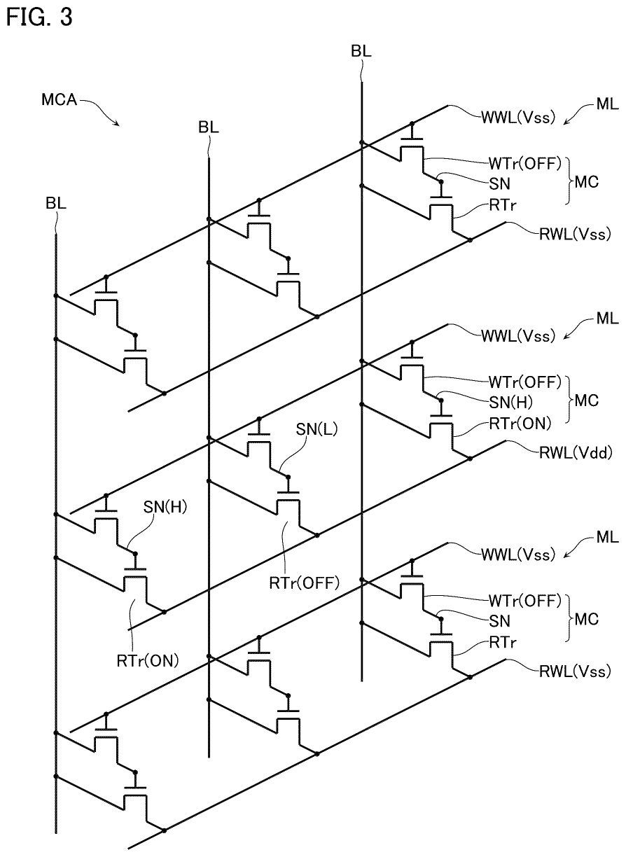

FIG. 3 is a schematic circuit diagram for describing a read operation of the semiconductor memory device according to the first embodiment.

In the read operation, for example, the power supply voltage Vdd is applied to a read word line RWL that is a target of the read operation and the ground voltage Vss is applied to the other read word lines RWL among the plurality of read word lines RWL. Accordingly, a current flows to the bit lines BL or the bit lines BL are charged corresponding to the states of the storage nodes SN. By reading this by a sense amplifier circuit, data stored in the memory cell MC can be obtained.

In the read operation, all the bit lines BL in the memory cell array MCA may be the target of the read operation, or a part (for example, one) of the bit lines BL may be the target of the read operation.

### Structure

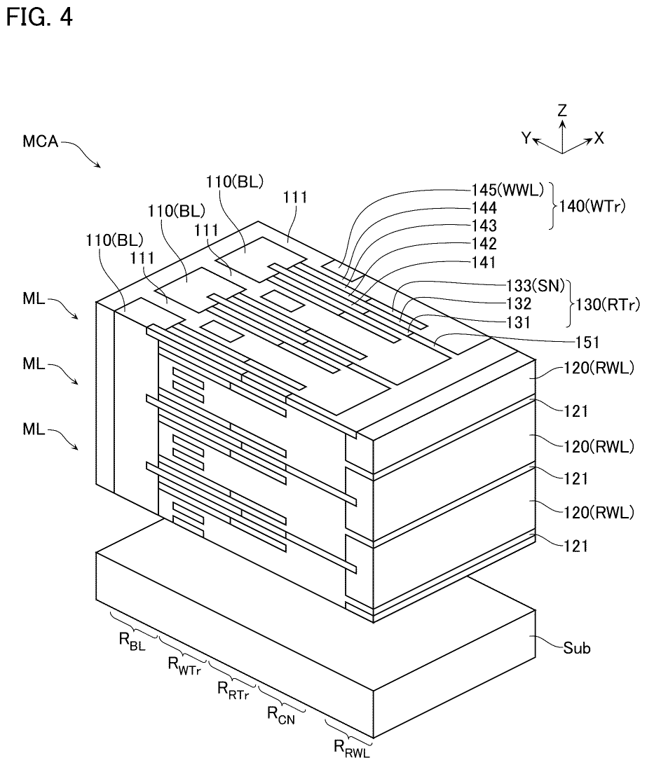

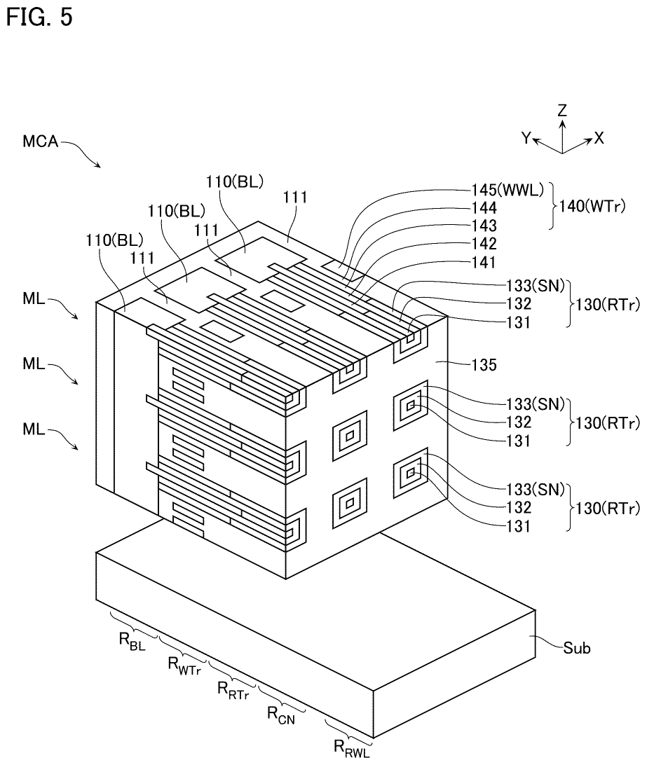

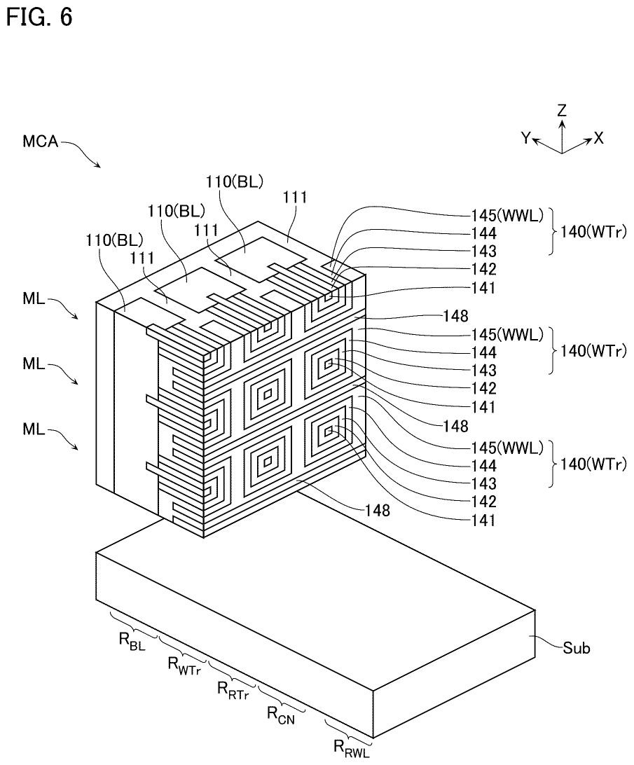

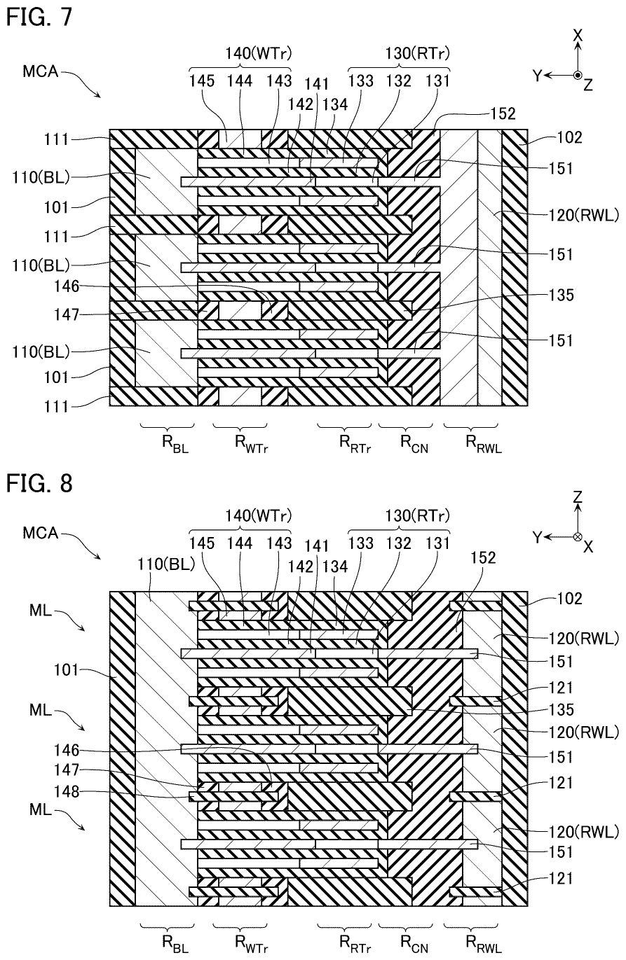

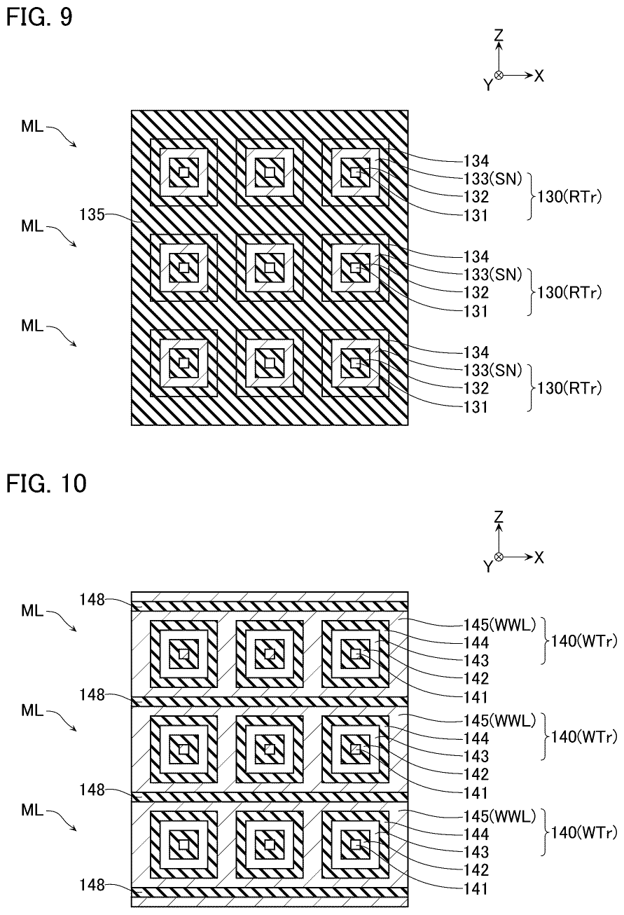

FIG. 4 to FIG. 6 are schematic perspective views illustrating the configuration of a part of the semiconductor memory device according to the first embodiment. In FIG. 5, a part of the configuration illustrated in FIG. 4 is omitted. In FIG. 6, a part of the configuration illustrated in FIG. 5 is omitted. FIG. 7 to FIG. 10 are schematic cross-sectional views illustrating the configuration of a part of the semiconductor memory device. FIG. 7 corresponds to the XY cross-sectional surface illustrated in FIG. 4. FIG. 8 corresponds to the YZ cross-sectional surface illustrated in FIG. 4. FIG. 9 corresponds to the XZ cross-sectional surface illustrated in FIG. 5. FIG. 10 corresponds to the XZ cross-sectional surface illustrated in FIG. 6.

FIG. 4 illustrates a part of a semiconductor substrate Sub and a memory cell array MCA disposed above the semiconductor substrate Sub.

The semiconductor substrate Sub is, for example, a semiconductor substrate of silicon (Si) or the like containing P-type impurities, such as boron (B). On an upper surface of the semiconductor substrate Sub, an insulating layer and an electrode layer, which are not illustrated in FIG. 4, are provided. The upper surface of the semiconductor substrate Sub, and the insulating layer and the electrode layer (not illustrated in FIG. 4) constitute a control circuit for controlling the semiconductor memory device. For example, in a region immediately below the memory cell array MCA, the sense amplifier circuit is disposed. The sense amplifier circuit is electrically connected to the bit lines BL. The sense amplifier circuit can read data stored in the selected memory cell MC by detecting a voltage variation or a current of the bit line BL in the read operation.

The memory cell array MCA includes a bit line region R_{BL}, a write transistor region R_{WTr}, a read transistor region R_{RTr}, a connection electrode region R_{CN}, and a read word line region R_{RWL}, which are arranged in this order in the Y-direction. The memory cell array MCA includes a plurality of memory layers ML arranged in the Z-direction.

The bit line region R_{BL} includes a plurality of wirings 110 extending in the Z-direction and arranged in the X-direction, and insulating layers 111 disposed between the plurality of wirings 110. Each of the plurality of wirings 110 function as the bit line BL. The plurality of wirings 110 include, for example, a barrier conductive film of titanium nitride (TiN) or the like and a conductive member of tungsten (W) or the like. The insulating layer 111 contains, for example, silicon oxide (SiO). As illustrated in FIG. 7 and FIG. 8, on a side surface of the wiring 110 on one side (opposite side of the read word line region R_{RWL}) in the Y-direction, an insulating layer 101 of silicon oxide (SiO) or the like is disposed.

The read word line region R_{RWL} includes a plurality of wirings 120 extending in the X-direction and arranged in the Z-direction corresponding to the plurality of memory layers ML, and insulating layers 121 disposed between the plurality of wirings 120. The plurality of wirings 120 function as, for example, the read word lines RWL. The plurality of wirings 120 include, for example, a barrier conductive film of titanium nitride (TiN) or the like and a conductive member of tungsten (W) or the like. The insulating layer 121 contains, for example, silicon oxide (SiO). As illustrated in FIG. 7 and FIG. 8, on a side surface of the wiring 120 on one side (opposite side of the bit line region R_{BL}) in the Y-direction, an insulating layer 102 of silicon oxide (SiO) or the like is disposed.

The read transistor region R_{RTr} includes, for example, as illustrated in FIG. 5 and FIG. 9, a plurality of transistor structures 130 and a plurality of insulating layers 134 (FIG. 9) arranged in the X-direction corresponding to the plurality of wirings 110 and arranged in the Z-direction corresponding to the plurality of memory layers ML. In a region between these configurations, an insulating layer 135 of silicon oxynitride (SiON) or the like is disposed.

Each of the plurality of transistor structures 130 includes a semiconductor member 131 extending in the Y-direction, an insulating layer 132 disposed on an upper surface, a lower surface, and both side surfaces in the X-direction of the semiconductor member 131, and a facing electrode 133 disposed on an upper surface, a lower surface, and both side surfaces in the X-direction of the insulating layer 132.

The semiconductor member 131 functions as a channel region of the read transistor RTr. The semiconductor member 131 contains, for example, single-crystal silicon (Si).

The insulating layer 132 functions as, for example, a gate insulating film of the read transistor RTr. The insulating layer 132 contains, for example, silicon oxide (SiO). The insulating layer 132 extends in the Y-direction along the upper surface, the lower surface, and both side surfaces in the X-direction of the semiconductor member 131.

The facing electrode 133 functions as, for example, the gate electrode of the read transistor RTr and the storage node SN. The facing electrode 133 contains, for example, titanium nitride (TiN). The facing electrode 133 extends in the Y-direction along the upper surface, the lower surface, and both side surfaces in the X-direction of the insulating layer 132. The facing electrode 133 faces the upper surface, the lower surface, and both side surfaces in the X-direction of the semiconductor member 131 via the insulating layer 132.

The respective plurality of insulating layers 134 are disposed on upper surfaces, lower surfaces, and both side surfaces in the X-direction of the plurality of transistor structures 130. The insulating layer 134 contains, for example, silicon oxide (SiO). The insulating layer 134 extends in the Y-direction along the upper surface, the lower surface, and both side surfaces in the X-direction of the transistor structure 130.

For example, as illustrated in FIG. 6, the write transistor region R_{WTr} includes a plurality of connection electrodes 141, a plurality of insulating layers 142, and a plurality of transistor structures 140, which are arranged in the X-direction corresponding to the plurality of wirings 110 and arranged in the Z-direction corresponding to the plurality of memory layers ML.

The connection electrode 141 is connected to the wiring 110 and the semiconductor member 131, and electrically conducts these configurations. The connection electrode 141 contains, for example, single-crystal silicon (Si) containing N-type impurities, such as phosphorus (P).

The respective plurality of insulating layers 142 are disposed on upper surfaces, lower surfaces, and both side surfaces in the X-direction of the plurality of connection electrodes 141. The insulating layer 142 is disposed between the connection electrode 141 and the semiconductor member 143, and electrically insulates these configurations. The insulating layer 142 contains, for example, silicon oxide (SiO). The insulating layer 142 extends in the Y-direction along the upper surface, the lower surface, and both side surfaces in the X-direction of the connection electrode 141. The insulating layer 142 is continuous with the insulating layer 132.

Each of the plurality of transistor structures 140 includes a semiconductor member 143 disposed on an upper surface, a lower surface, and both side surfaces in the X-direction of the insulating layer 142, an insulating layer 144 disposed on an upper surface, a lower surface, and both side surfaces in the X-direction of the semiconductor member 143, and a facing electrode 145 disposed on an upper surface, a lower surface, and both side surfaces in the X-direction of the insulating layer 144.

The semiconductor member 143 functions as a channel region of the write transistor WTr. The semiconductor member 143 extends in the Y-direction along the upper surface, the lower surface, and both side surfaces in the X-direction of the insulating layer 142. The semiconductor member 143 is connected to the wiring 110 and the facing electrode 133.

The semiconductor member 143 may include, for example, an oxide semiconductor. For the oxide semiconductor, a semiconductor material that contains at least one element of indium (In), gallium (Ga), zinc (Zn), aluminum (Al), tin (Sn), or titanium (Ti), and contains oxygen (O) can be used. For example, the oxide semiconductor may contain at least one element of gallium (Ga) or aluminum (Al), and contains indium (In), zinc (Zn), and oxygen (O). Another oxide semiconductor may be used.

Specific examples of the oxide semiconductor may include zinc tin oxide (ZTO), indium gallium zinc oxide (IGZO), indium zinc oxide (IZO), zinc oxide (ZnO), indium oxide (InO), tin oxide (SnO), titanium oxide (TiO), zinc oxynitride (ZnON), magnesium zinc oxide (MgZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), zirconium zinc tin oxide (ZrZnSnO), indium gallium silicon oxide (InGaSiO), indium gallium oxide (IGO), and indium tungsten oxide (IWO). The oxide semiconductor may be amorphous or crystalline.

The insulating layer 144 functions as, for example, a gate insulating film of the write transistor WTr. The insulating layer 144 contains, for example, silicon oxide (SiO). The insulating layer 144 extends in the Y-direction along the upper surface, the lower surface, and both side surfaces in the X-direction of the semiconductor member 143. The insulating layer 144 is continuous with the insulating layer 134.

The facing electrode 145 functions as, for example, the gate electrode of the write transistor WTr. The facing electrode 145 contains, for example, titanium nitride (TiN). The facing electrode 145 extends in the Y-direction along the upper surface, the lower surface, and both side surfaces in the X-direction of the insulating layer 144. The facing electrode 145 faces the upper surface, the lower surface, and both side surfaces in the X-direction of the semiconductor member 143 via the insulating layer 144.

The plurality of facing electrodes 145 arranged in the X-direction are mutually continuous and constitute a wiring extending in the X-direction. In other words, the facing electrode 145 is a part of the wiring extending in the X-direction. This wiring functions as the write word line WWL.

As illustrated in FIG. 7 and FIG. 8, an insulating layer 146 of silicon nitride (SiN) or the like is disposed between the facing electrode 145 and the insulating layer 135, and an insulating layer 147 of silicon nitride (SiN) or the like is disposed between the facing electrode 145 and the wiring 110. An insulating layer 148 of silicon oxide (SiO) or the like is disposed between the two facing electrodes 145 adjacent in the Z-direction.

The connection electrode region R_{CN} includes a plurality of connection electrodes 151 arranged in the X-direction corresponding to the plurality of wirings 110 and arranged in the Z-direction corresponding to the plurality of memory layers ML. The connection electrode 151 is connected to the wiring 120 and the semiconductor member 131, and electrically conducts these configurations. The connection electrode 151 contains, for example, single-crystal silicon (Si) containing N-type impurities, such as phosphorus (P). An insulating layer 152 of silicon nitride (SiN) or the like is disposed in a region between these.

### Manufacturing Method

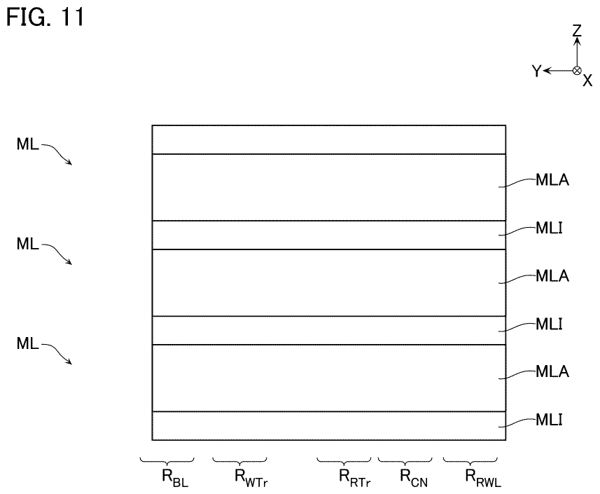

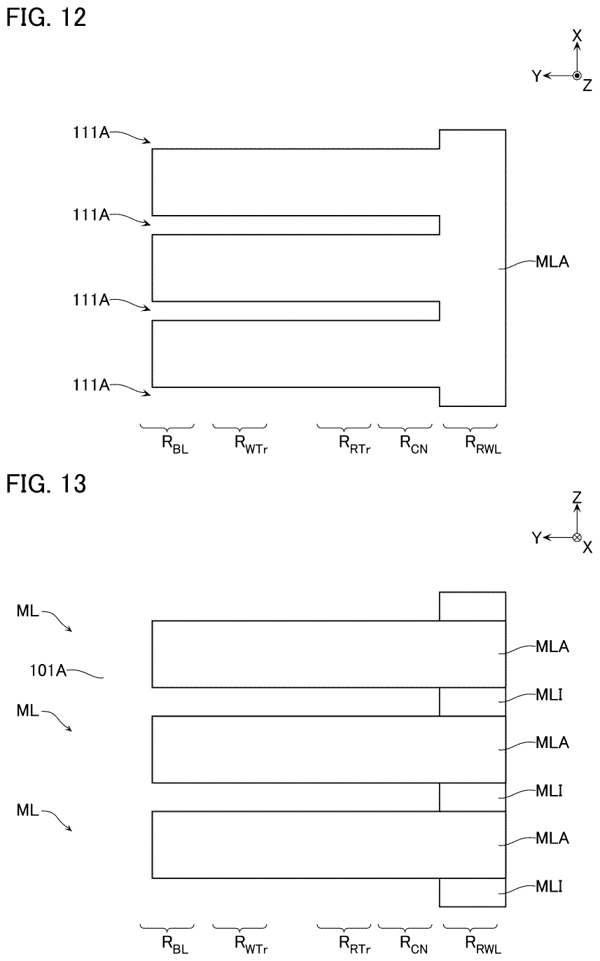

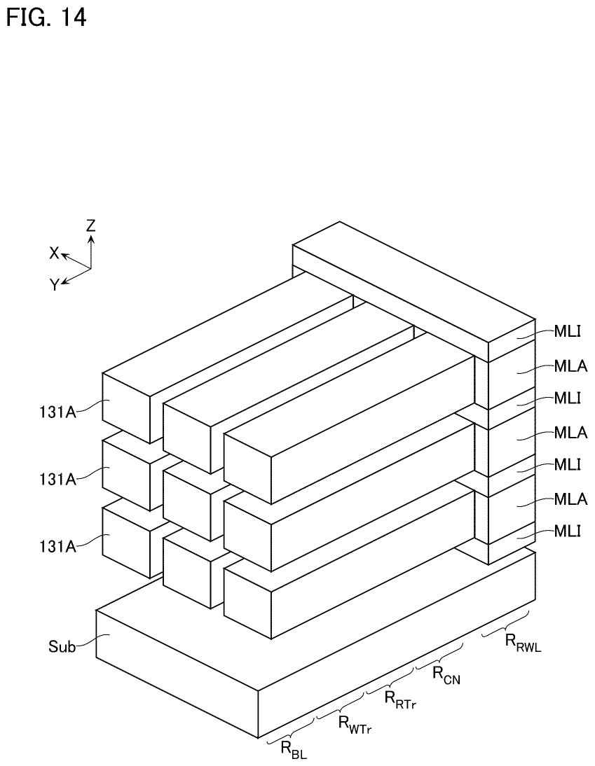

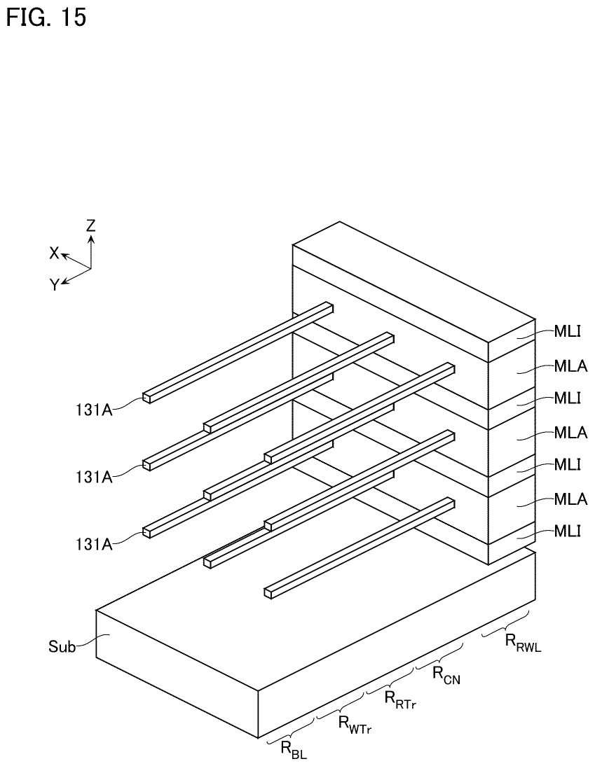

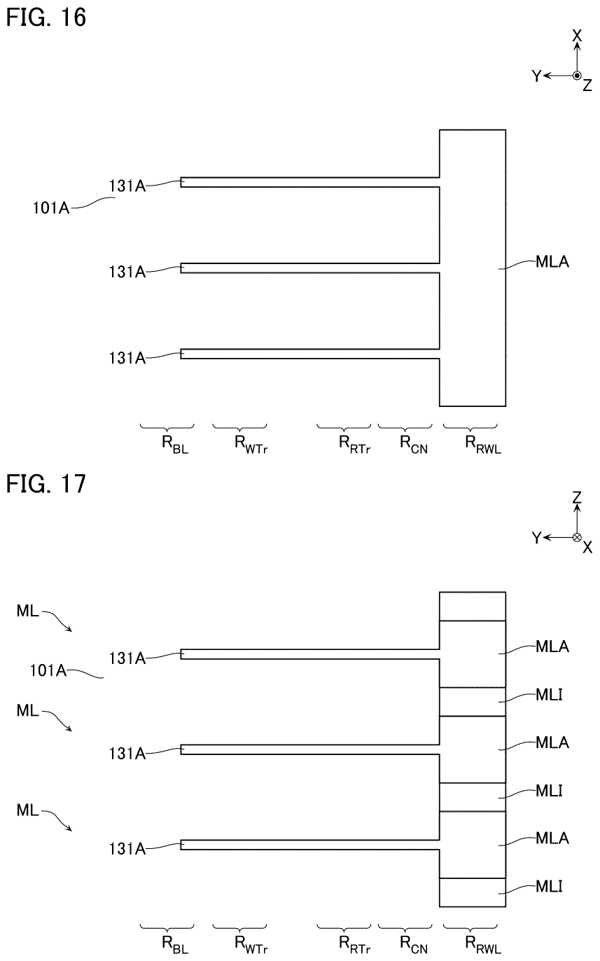

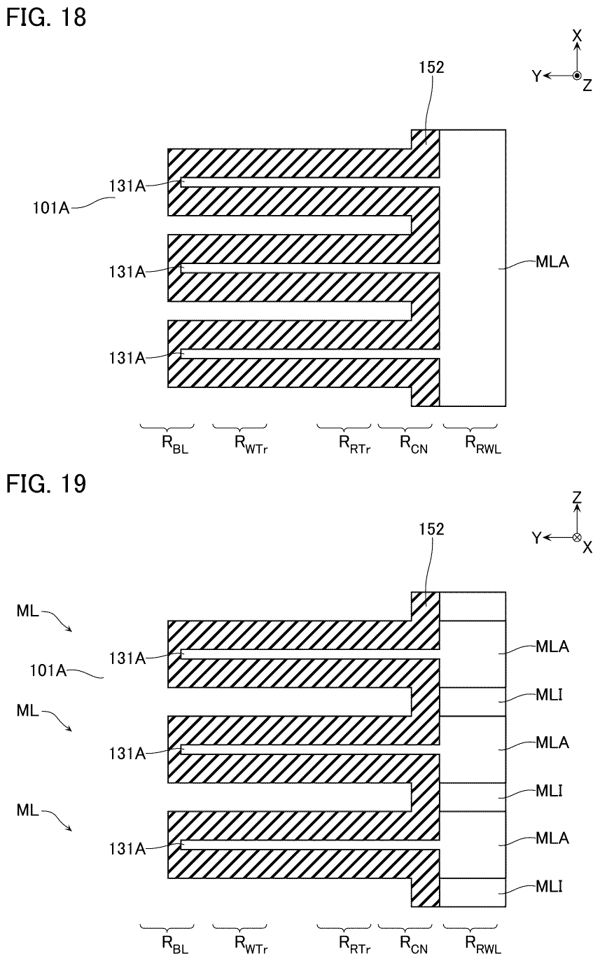

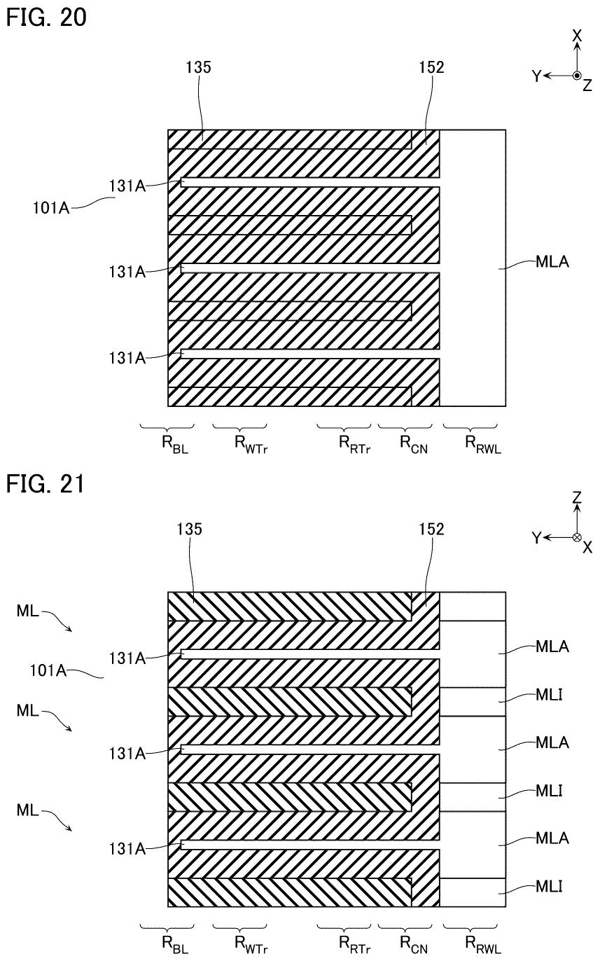

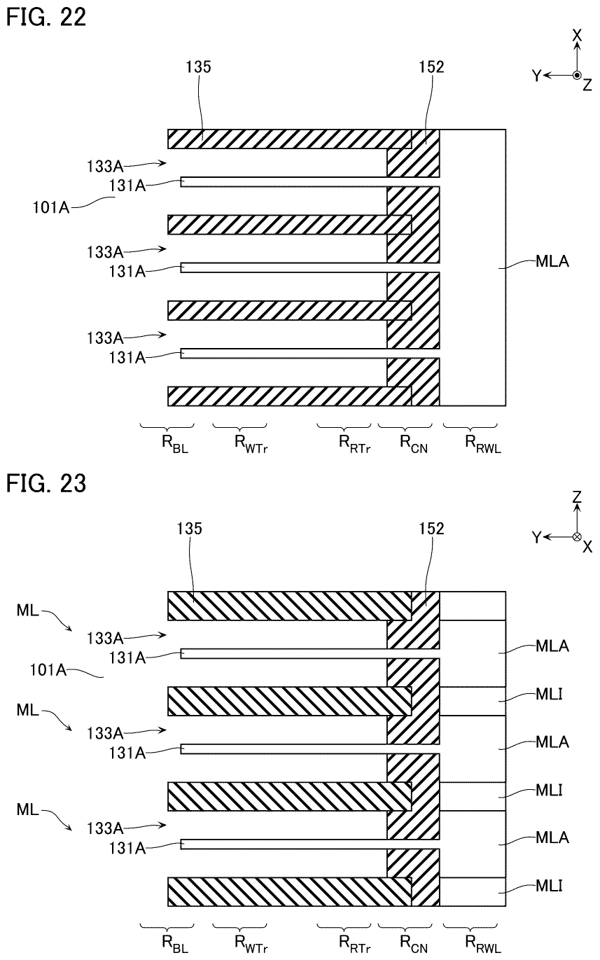

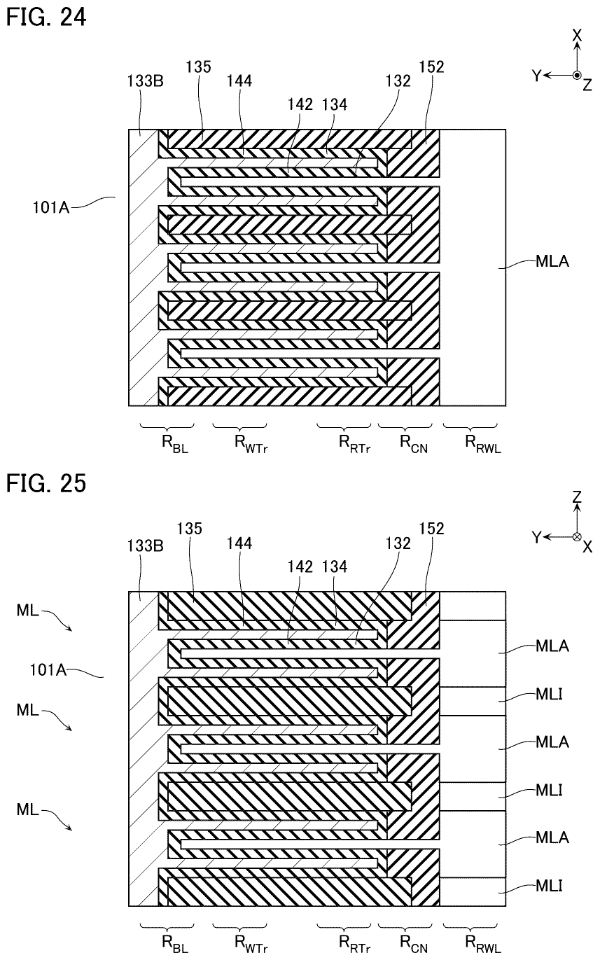

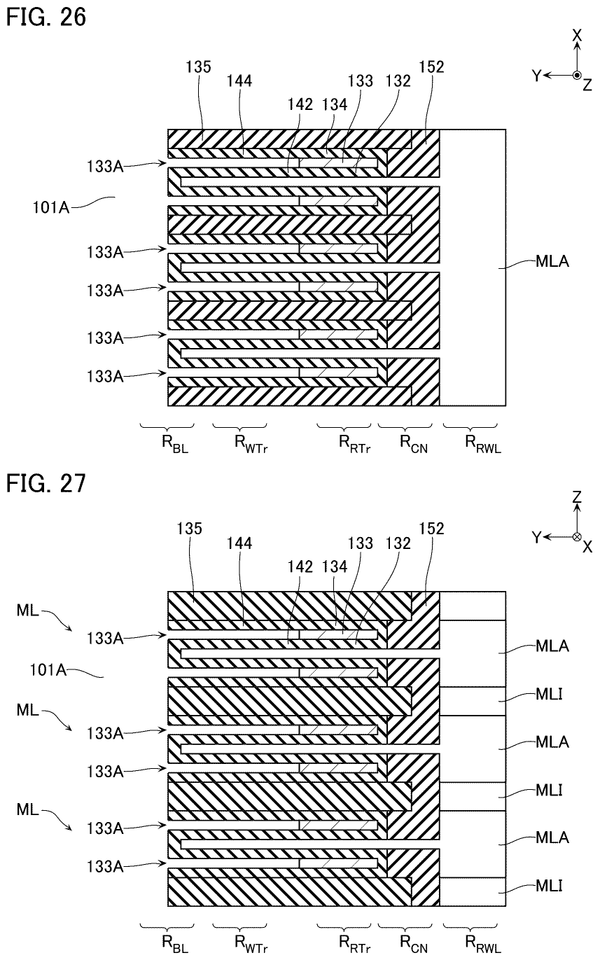

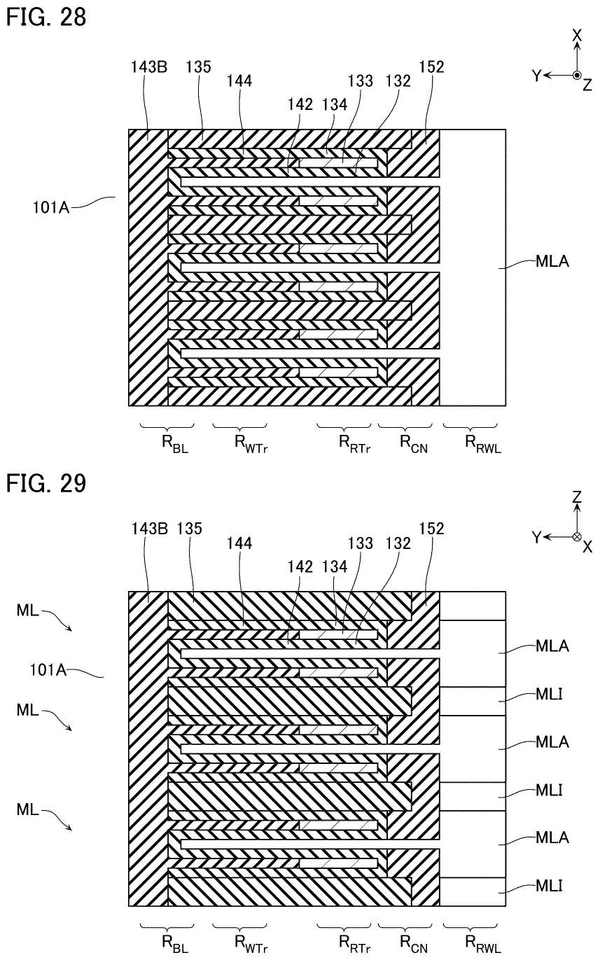

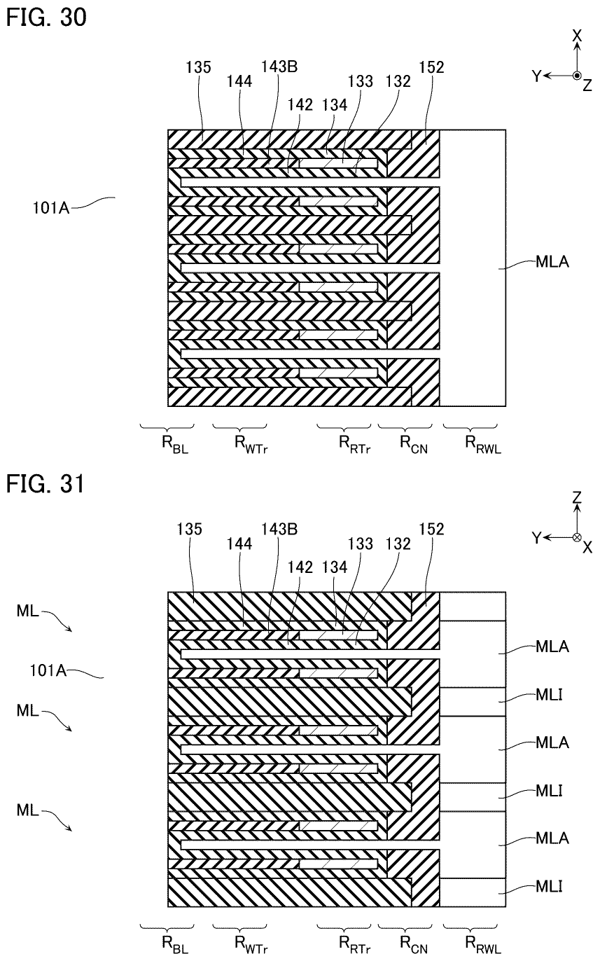

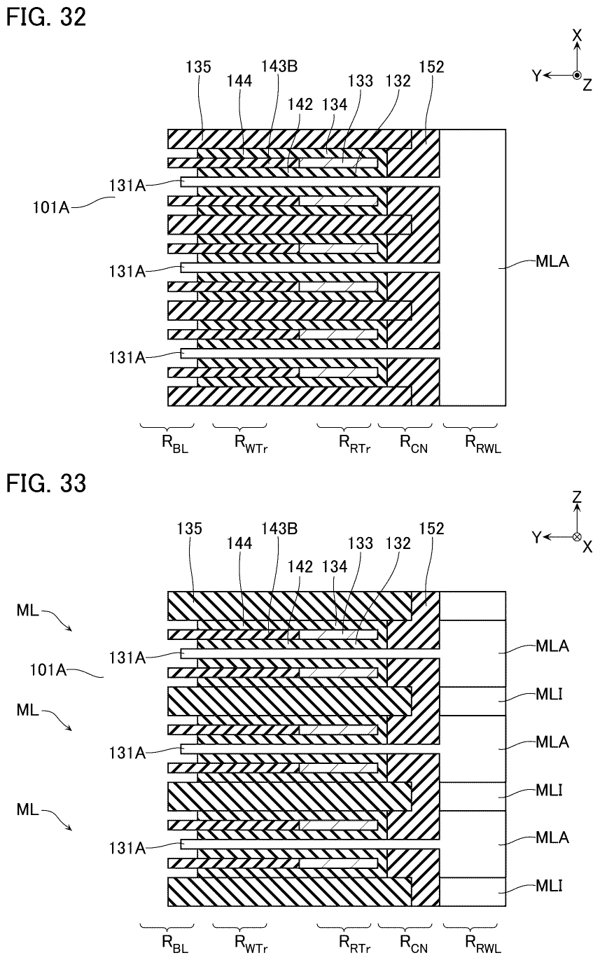

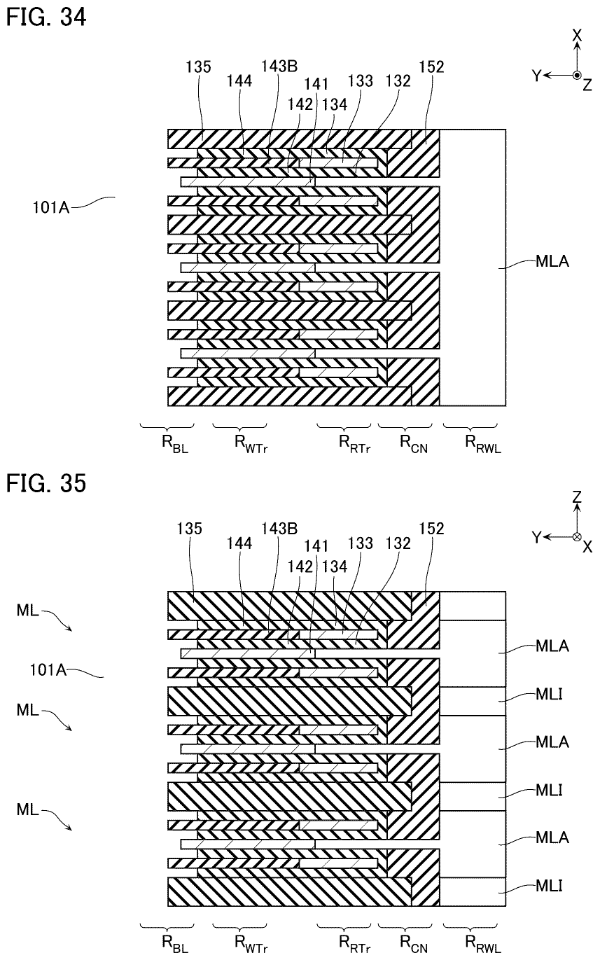

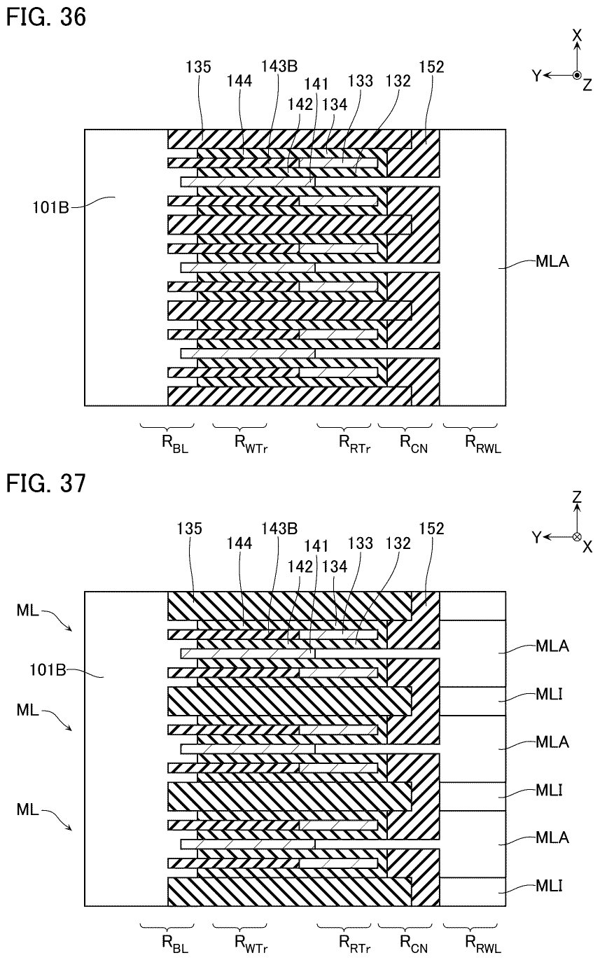

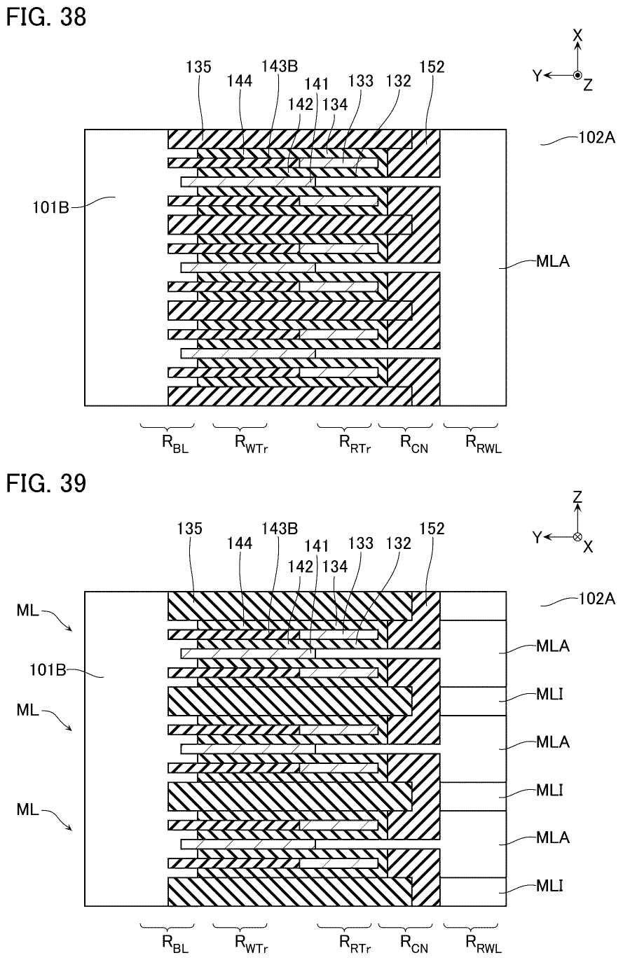

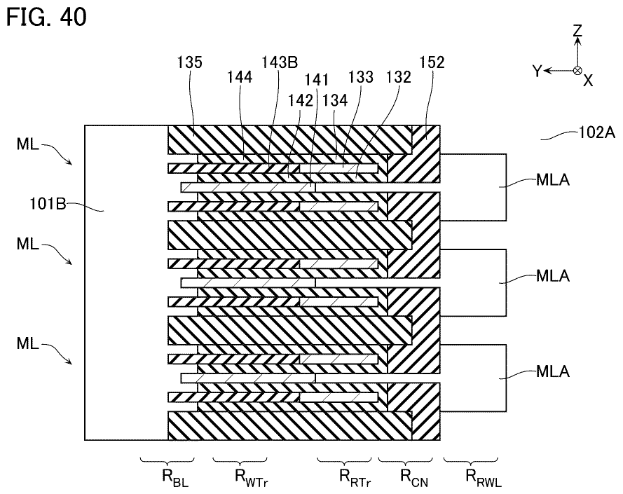

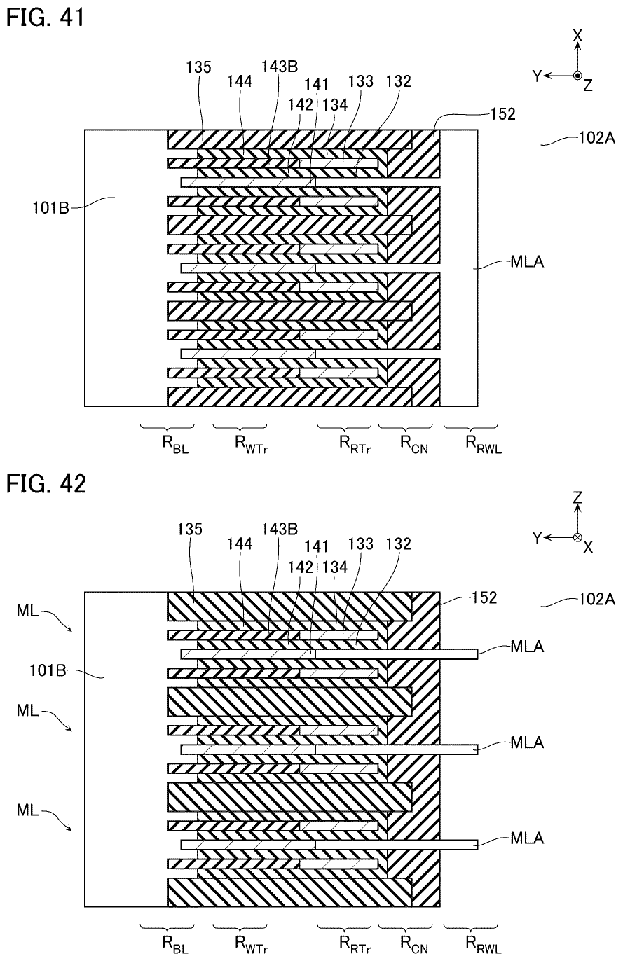

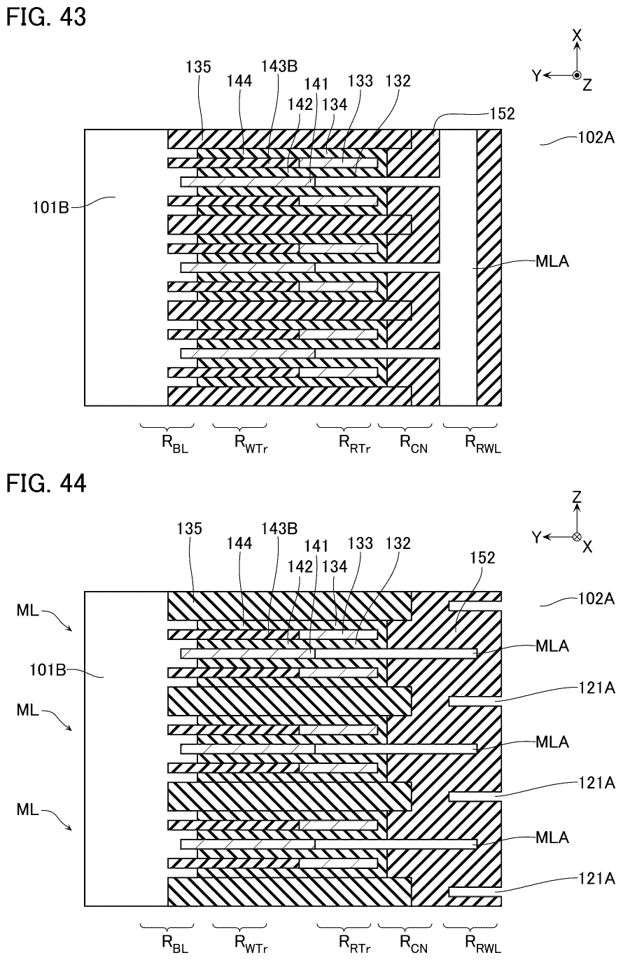

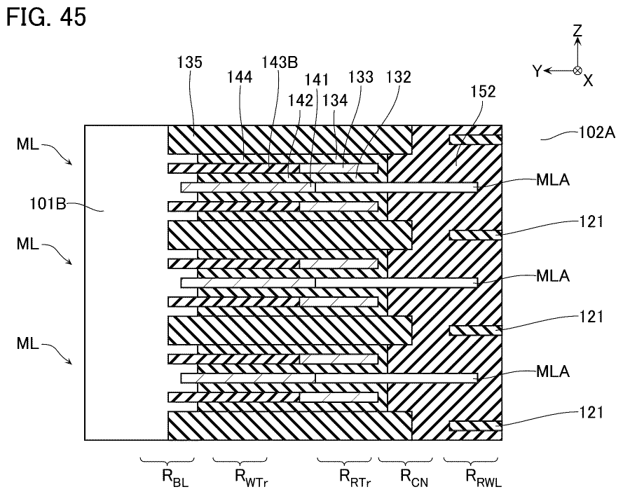

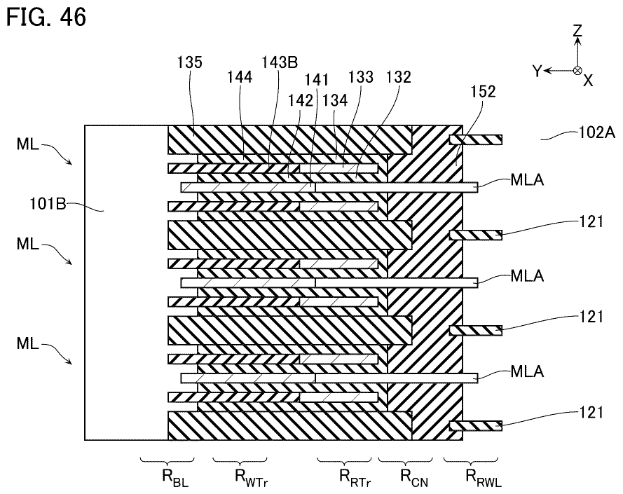

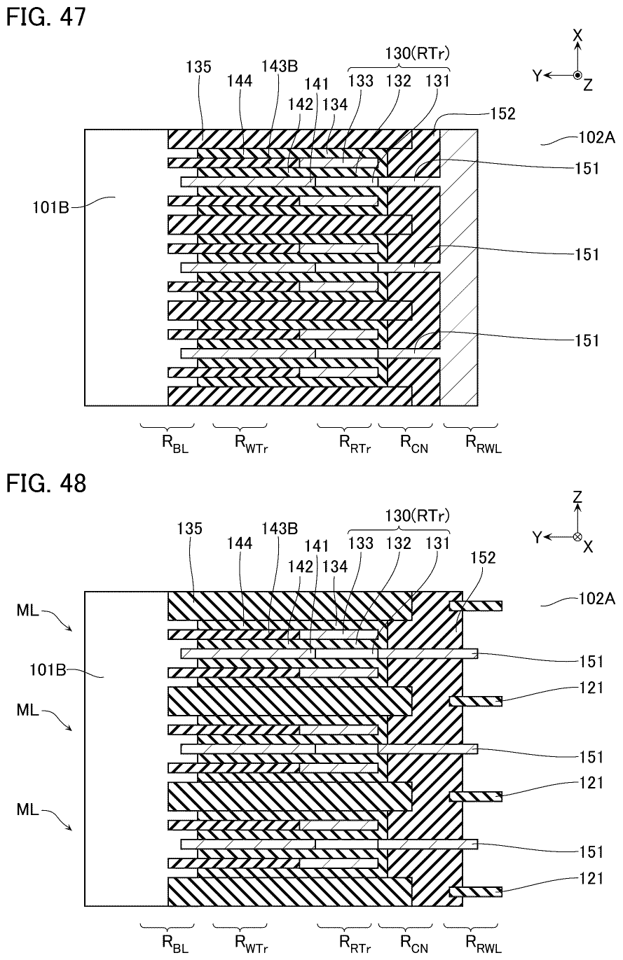

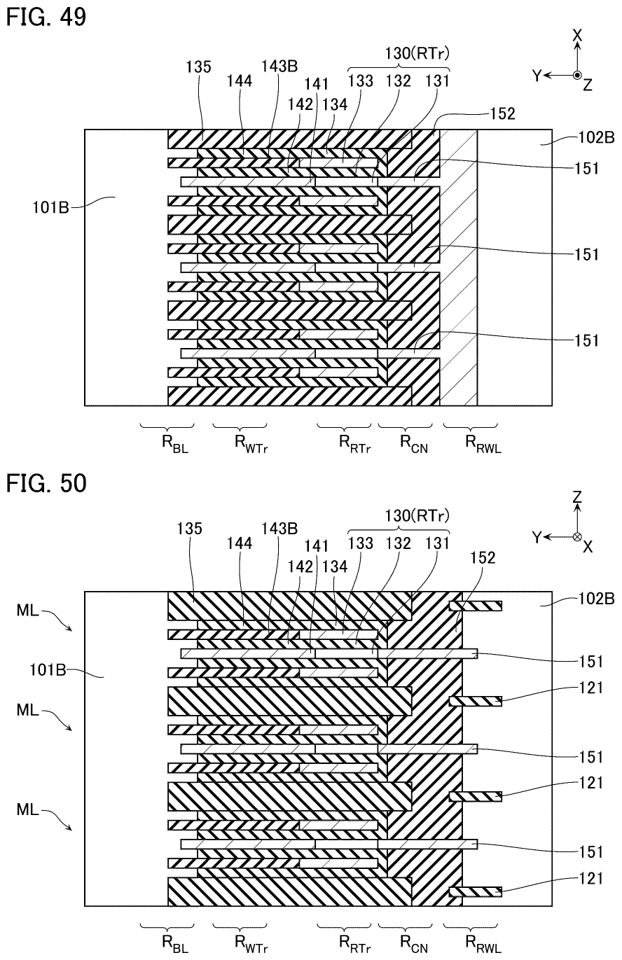

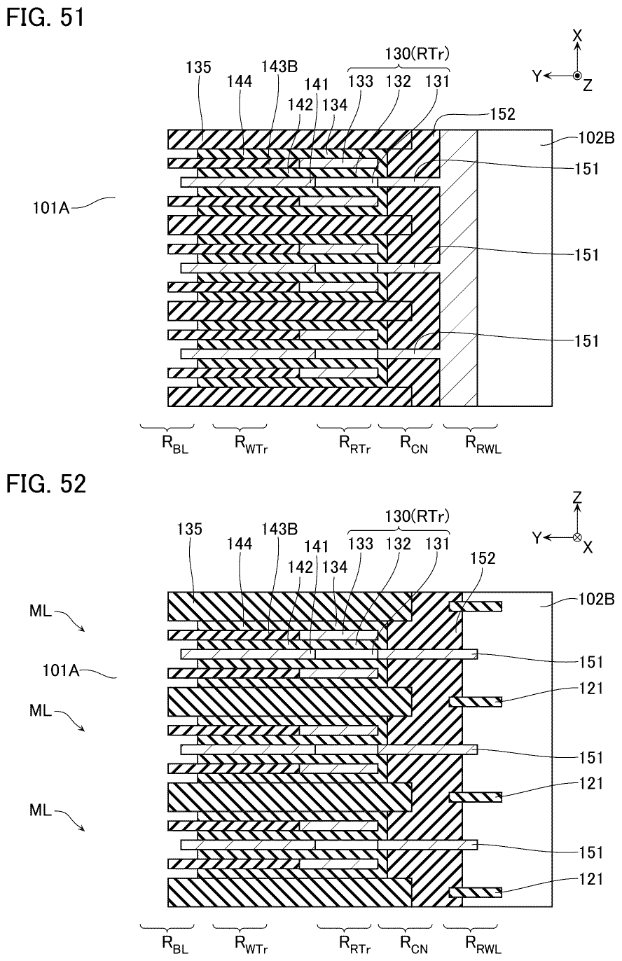

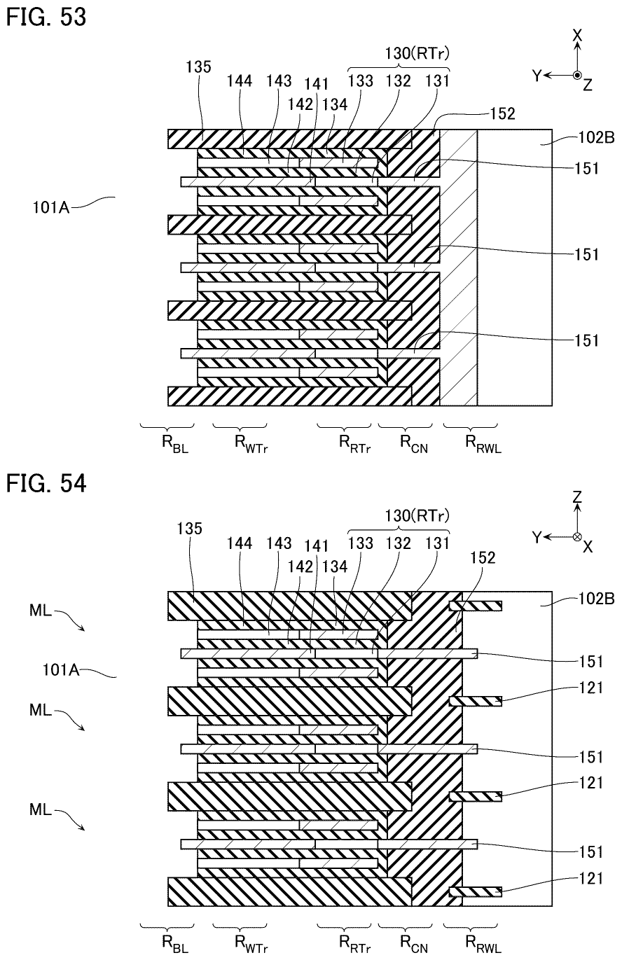

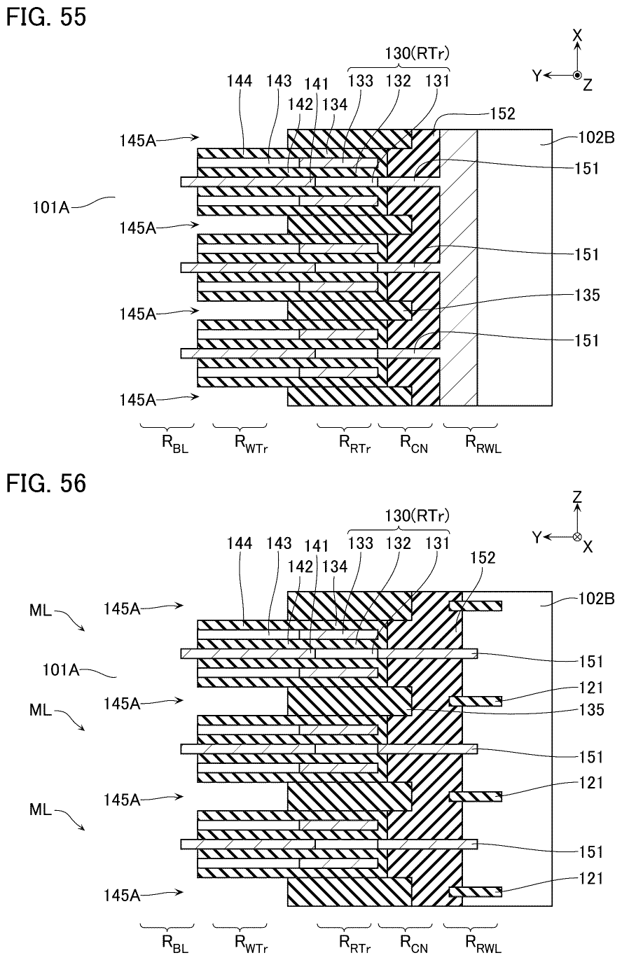

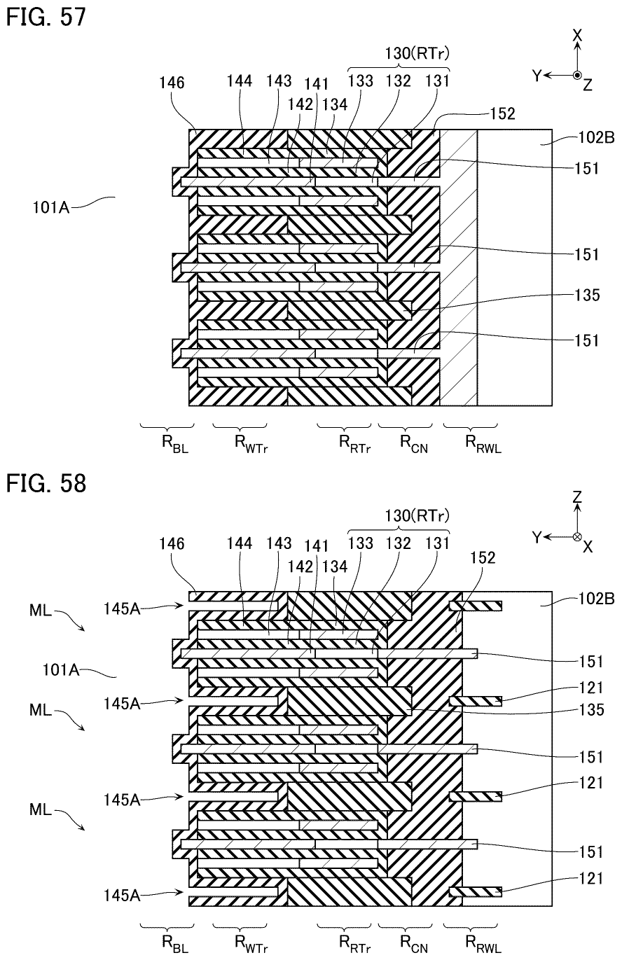

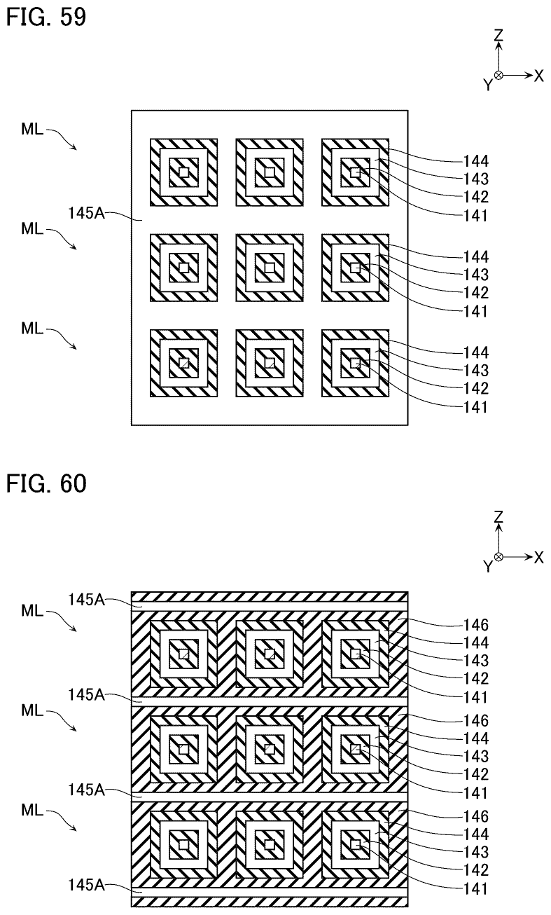

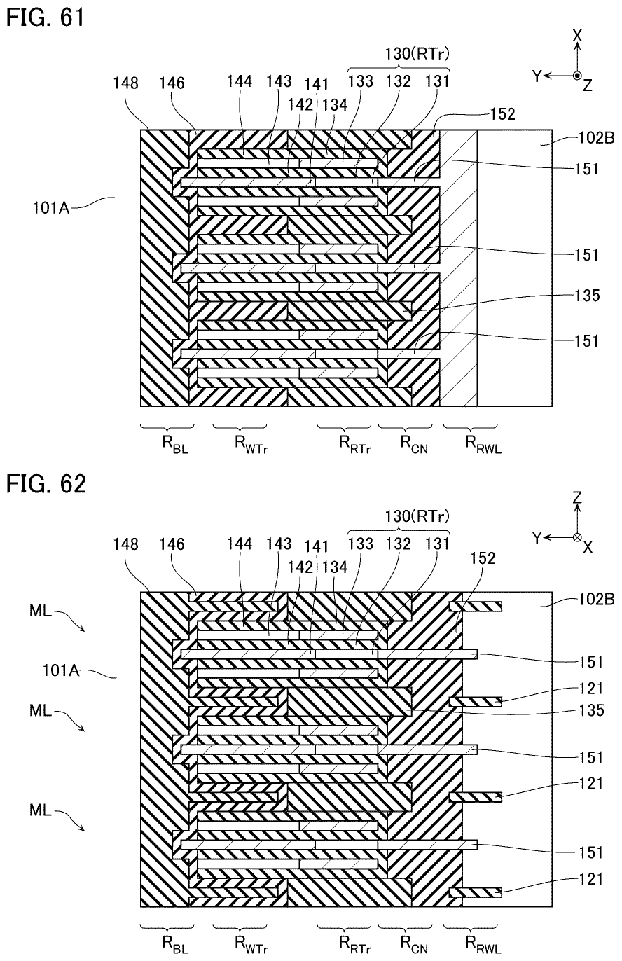

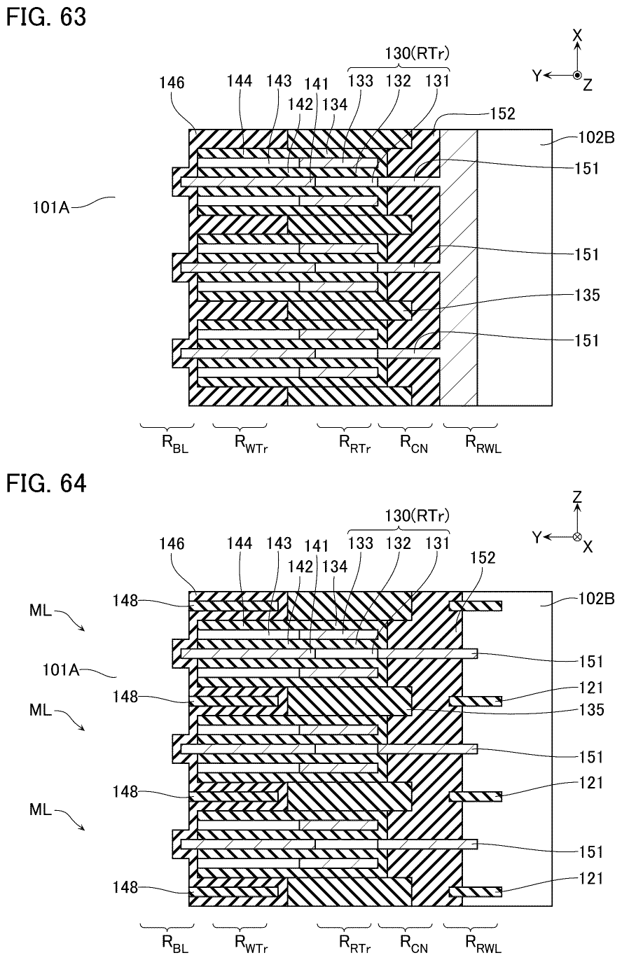

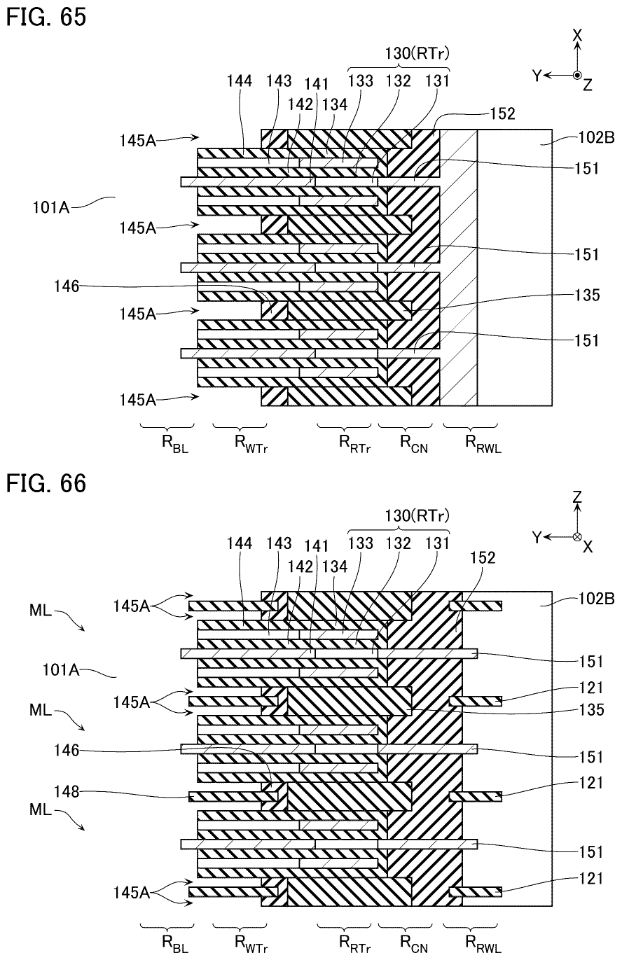

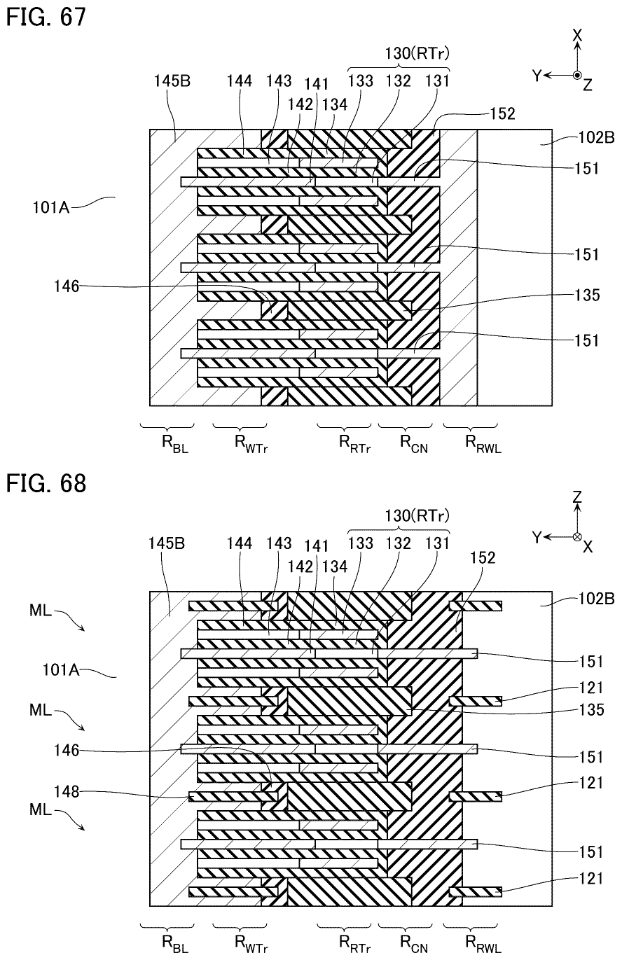

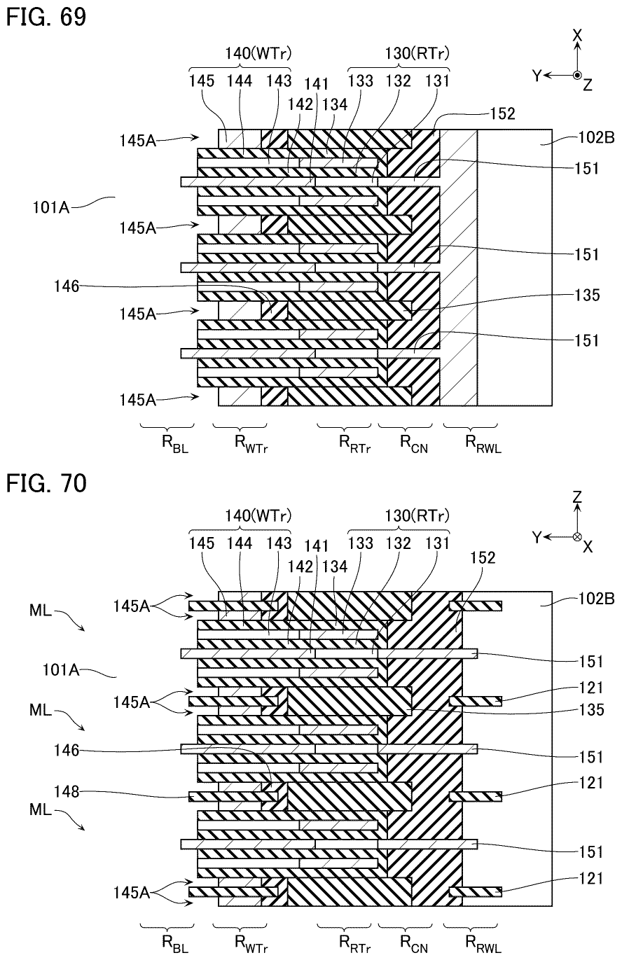

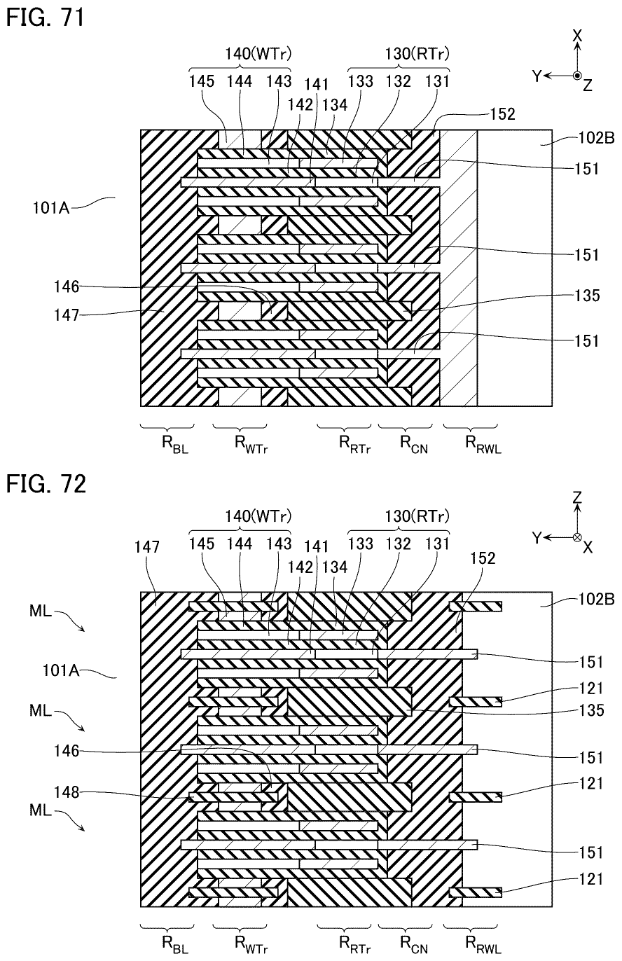

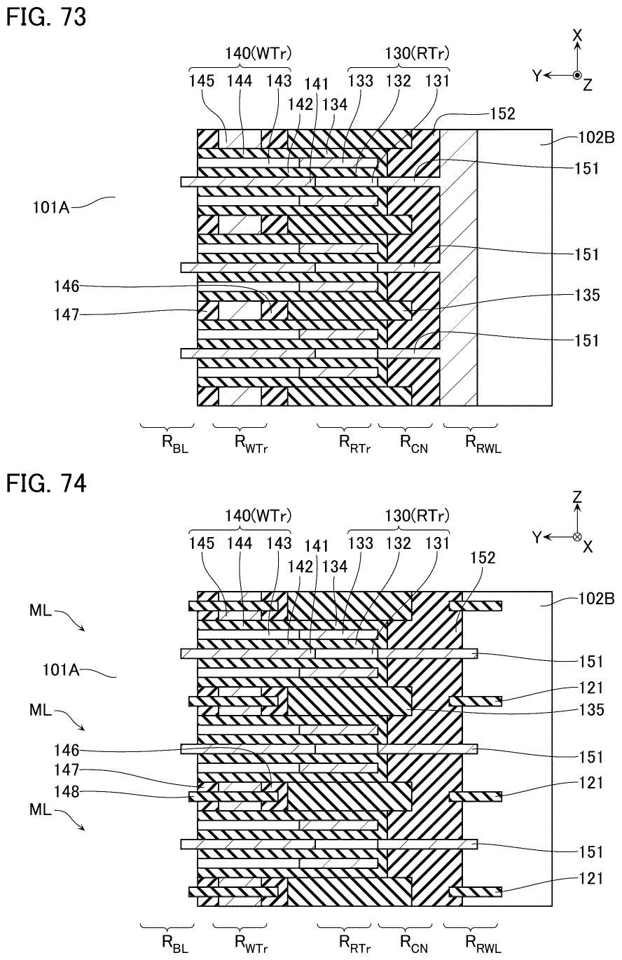

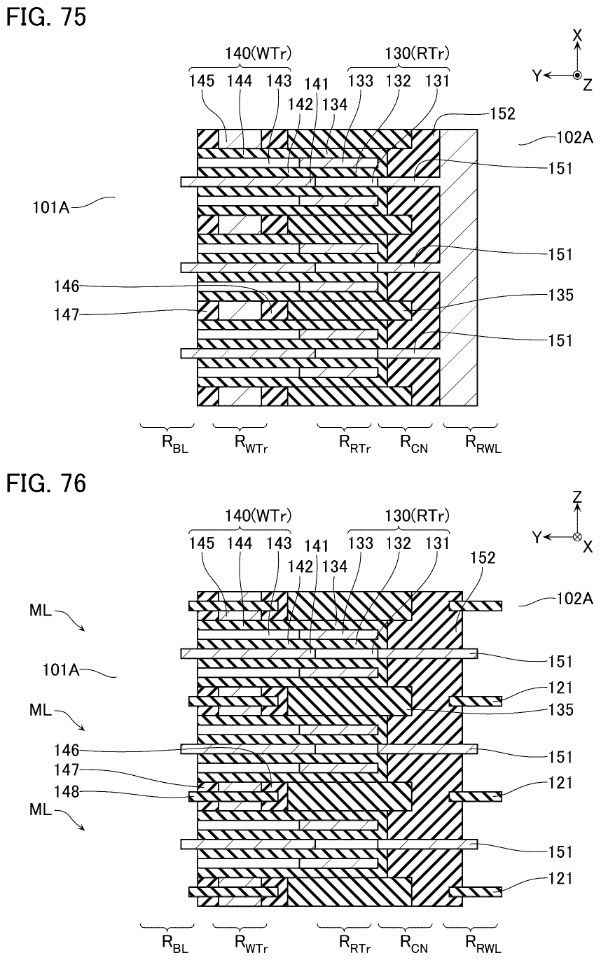

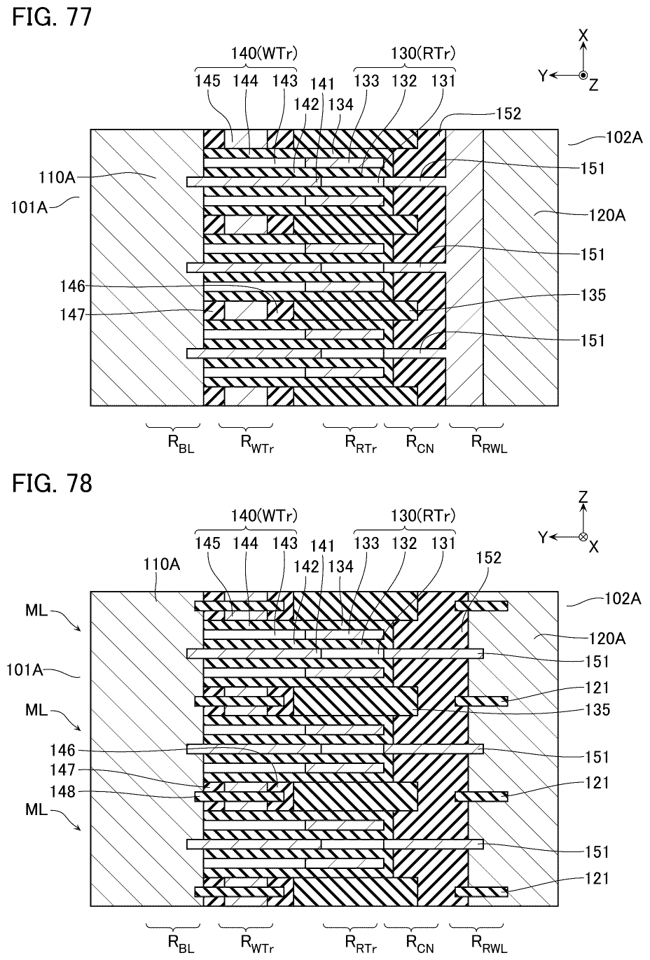

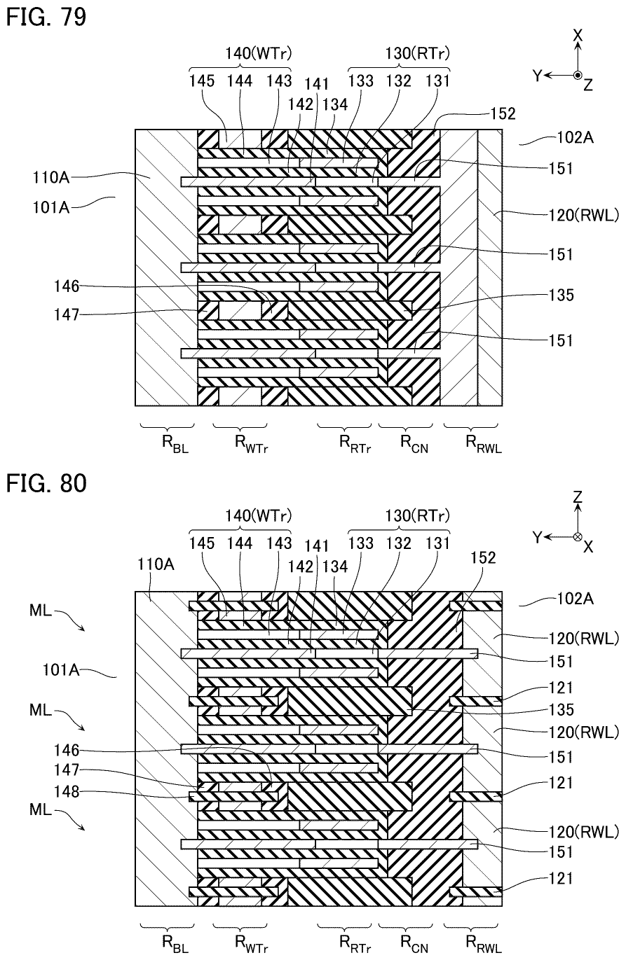

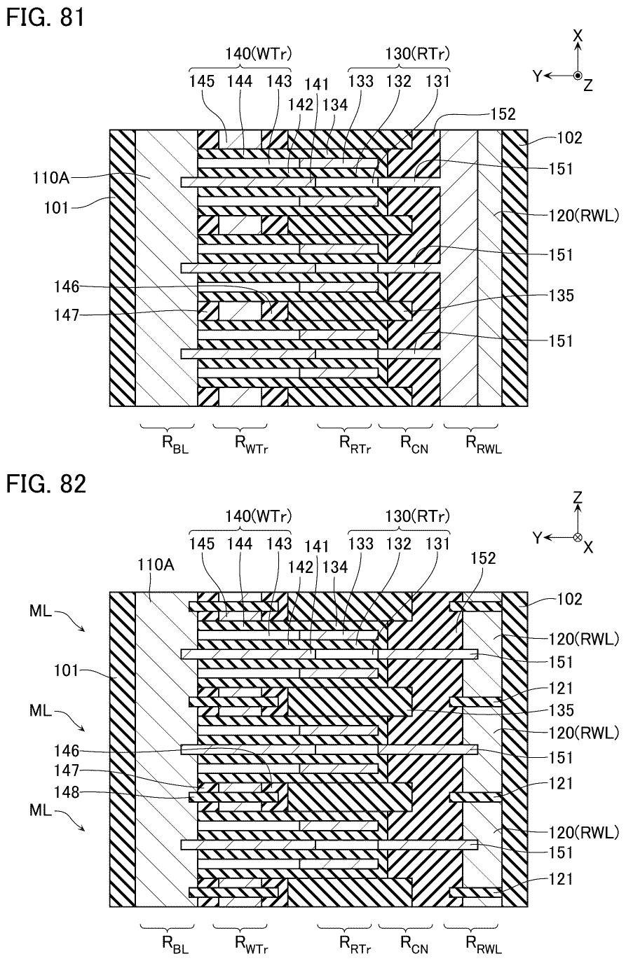

FIG. 11 to FIG. 13, and FIG. 16 to FIG. 82 are schematic cross-sectional views for describing a manufacturing method of the semiconductor memory device according to the first embodiment. FIG. 12, FIG. 16, FIG. 18, FIG. 20, FIG. 22, FIG. 24, FIG. 26, FIG. 28, FIG. 30, FIG. 32, FIG. 34, FIG. 36, FIG. 38, FIG. 41, FIG. 43, FIG. 47, FIG. 49, FIG. 51, FIG. 53, FIG. 55, FIG. 57, FIG. 61, FIG. 63, FIG. 65, FIG. 67, FIG. 69, FIG. 71, FIG. 73, FIG. 75, FIG. 77, FIG. 79, and FIG. 81 illustrate cross-sectional surfaces corresponding to FIG. 7. FIG. 11, FIG. 13, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 40, FIG. 42, FIG. 44, FIG. 45, FIG. 46, FIG. 48, FIG. 50, FIG. 52, FIG. 54, FIG. 56, FIG. 58, FIG. 62, FIG. 64, FIG. 66, FIG. 68, FIG. 70, FIG. 72, FIG. 74, FIG. 76, FIG. 78, FIG. 80, and FIG. 82 illustrate cross-sectional surfaces corresponding to FIG. 8. FIG. 59 and FIG. 60 illustrate cross-sectional surfaces corresponding to FIG. 10. FIG. 14 and FIG. 15 are schematic perspective views for describing the manufacturing method of the semiconductor memory device according to the first embodiment.

In the manufacturing method, for example, as illustrated in FIG. 11, a plurality of semiconductor layers MLA and a plurality of sacrifice layers MLI are alternately formed. The semiconductor layer MLA contains, for example, single-crystal silicon (Si). The sacrifice layer MLI contains, for example, single-crystal silicon germanium (SiGe). This process is performed by, for example, an epitaxial growth method.

Next, for example, as illustrated in FIG. 12, at a plurality of positions in the Y-direction corresponding to the plurality of insulating layers 111 (FIG. 7), trenches 111A that penetrate the plurality of semiconductor layers MLA and the plurality of sacrifice layers MLI to extend in the Z-direction and extend in the Y-direction across the bit line region R_{BL}, the write transistor region R_{WTr}, the read transistor region R_{RTr}, and the connection electrode region R_{CN} are formed. This process is performed by, for example, Reactive Ion Etching (RIE).

Next, although not illustrated in FIG. 12, sacrifice layers are formed inside the plurality of trenches 111A. This process is performed by, for example, Chemical Vapor Deposition (CVD).

Next, as illustrated in FIG. 13, at a position in the Y-direction corresponding to the insulating layer 101 (FIG. 7 and FIG. 8), a trench 101A that penetrates the plurality of semiconductor layers MLA and the plurality of sacrifice layers MLI to extend in the Z-direction and extends in the X-direction is formed. This process is performed by, for example, RIE.

Portions of the plurality of sacrifice layers MLI provided in the bit line region R_{BL}, the write transistor region R_{WTr}, the read transistor region R_{RTr}, and the connection electrode region R_{CN} are removed via the trench 101A. This process is performed by, for example, wet etching.

Next, sacrifice layers (not illustrated) formed inside the plurality of trenches 111A (FIG. 12) are removed. This process is performed by, for example, wet etching.

Thus, as illustrated in FIG. 14, a plurality of semiconductor portions 131A that are arranged in the X-direction and the Z-direction and extend in the Y-direction across the write transistor region R_{WTr}, the read transistor region R_{RTr}, and the connection electrode region R_{CN} are formed.

Next, as illustrated in FIG. 15 to FIG. 17, widths of the plurality of semiconductor portions 131A in the X-direction and the Z-direction are reduced. This process is performed by, for example, wet etching.

Next, as illustrated in FIG. 18 and FIG. 19, a part of the insulating layer 152 is formed on upper surfaces, lower surfaces, both side surfaces in the X-direction, and end portions on one side (trench 101A side) in the Y-direction of the plurality of semiconductor portions 131A and side surfaces of the semiconductor layers MLA and the sacrifice layers MLI in the Y-direction. This process is performed by, for example, CVD. In this process, spaces between the two semiconductor portions 131A adjacent in the X-direction and spaces between the two semiconductor portions 131A adjacent in the Z-direction are not filled.

Next, as illustrated in FIG. 20 and FIG. 21, the insulating layers 135 are formed in remaining spaces in the write transistor region R_{WTr}, the read transistor region R_{RTr}, and the connection electrode region R_{CN}. This process is performed by, for example, CVD. In this process, the spaces between the two semiconductor portions 131A adjacent in the X-direction and the spaces between the two semiconductor portions 131A adjacent in the Z-direction are filled.

Next, as illustrated in FIG. 22 and FIG. 23, in the insulating layer 152, a portion provided in the write transistor region R_{WTr} and the read transistor region R_{RTr} is removed. This process is performed by, for example, wet etching. In this process, openings 133A are formed in the write transistor region R_{WTr} and the read transistor region R_{RTr}. The openings 133A are arranged in the Z-direction and the X-direction corresponding to the plurality of semiconductor portions 131A, and separated by the insulating layer 135.

Next, as illustrated in FIG. 24 and FIG. 25, an insulating layer is formed on the upper surfaces, the lower surfaces, both side surfaces in the X-direction, and the end portions on one side (trench 101A side) in the Y-direction of the semiconductor portions 131A, on upper surfaces, lower surfaces, both side surfaces in the X-direction, and side surfaces on a trench 101A side in the Y-direction of the insulating layers 135, and on exposed surfaces to the openings 133A of the insulating layer 152. In portions formed on the upper surface, the lower surface, and both side surfaces in the X-direction of the semiconductor portion 131A of this insulating layer, a portion in the read transistor region R_{RTr} is the insulating layer 132, and a portion in the write transistor region R_{WTr} is the insulating layer 142. In portions formed on the upper surface, the lower surface, and both side surfaces in the X-direction of the insulating layer 135 of this insulating layer, a portion in the read transistor region R_{RTr} is the insulating layer 134, and a portion in the write transistor region R_{WTr} is the insulating layer 144. A conductive layer 133B is formed inside the openings 133A. The openings 133A are filled with the conductive layer 133B. This process is performed by, for example, CVD.

Next, as illustrated in FIG. 26 and FIG. 27, in the insulating layer 144 and the conductive layer 133B, a portion provided on side surfaces of the insulating layers 135 on the trench 101A side in the Y-direction is removed. In the conductive layer 133B, portions provided in write transistor region R_{WTr} are removed. Through this process, a plurality of facing electrodes 133 are formed. This process is performed by, for example, wet etching.

Next, as illustrated in FIG. 28 and FIG. 29, a sacrifice layer 143B of silicon nitride or the like is formed inside the openings 133A and formed on an inner wall surface of the trench 101A. The openings 133A are filled with the sacrifice layer 143B. The trench 101A is not filled with the sacrifice layer 143B. This process is performed by, for example, CVD.

Next, as illustrated in FIG. 30 and FIG. 31, in the sacrifice layer 143B, a portion provided on the inner wall surface of the trench 101A is removed. This process is performed by, for example, wet etching.

Next, as illustrated in FIG. 32 and FIG. 33, the insulating layers 142, 144 are partially removed to expose the end portions of the semiconductor portions 131A on one side (trench 101A side) in the Y-direction. This process is performed by, for example, wet etching.

Next, as illustrated in FIG. 34 and FIG. 35, the connection electrodes 141 are formed. In this process, N-type impurities, such as phosphorus (P), are implanted into the semiconductor portion 131A from the end portion on one side (trench 101A side) in the Y-direction. The region in which the impurities are diffused of the semiconductor portion 131A becomes the connection electrode 141. This process is performed by, for example, Gas Phase Doping (GPD).

Next, as illustrated in FIG. 36 and FIG. 37, a sacrifice layer 101B containing carbon (C) or the like is formed inside the trench 101A. This process is performed by, for example, CVD.

Next, as illustrated in FIG. 38 and FIG. 39, at a position corresponding to the insulating layer 102 (FIG. 7 and FIG. 8), a trench 102A that penetrates the plurality of semiconductor layers MLA and the plurality of sacrifice layers MLI to extend in the Z-direction and extends in the X-direction is formed. This process is performed by, for example, RIE.

Next, as illustrated in FIG. 40, the plurality of sacrifice layers MLI are removed. This process is performed by, for example, wet etching.

Next, as illustrated in FIG. 41 and FIG. 42, in the plurality of semiconductor layers MLA, widths of portions provided in the read word line region R_{RWL} in the Z-direction are reduced. This process is performed by, for example, wet etching.

Next, as illustrated in FIG. 43 and FIG. 44, the other part of the insulating layer 152 is formed on a side surface of the insulating layer 152 on one side (trench 102A side) in the Y-direction, upper surfaces, lower surfaces, and end portions on one side (trench 102A side) in the Y-direction of the semiconductor layers MLA. This process is performed by, for example, CVD. In this process, spaces between the two semiconductor layers MLA adjacent in the Z-direction are not filled with the insulating layer 152. Thus, a plurality of openings 121A are formed at positions corresponding to the plurality of insulating layers 121 (FIG. 8).

Next, as illustrated in FIG. 45, a plurality of insulating layers 121 are formed inside the plurality of openings 121A. This process is performed by, for example, CVD and wet etching.

Next, as illustrated in FIG. 46, the insulating layer 152 is partially removed to expose the end portions of the plurality of semiconductor layers MLA on one side (trench 102A side) in the Y-direction. This process is performed by, for example, wet etching.

Next, as illustrated in FIG. 47 and FIG. 48, the connection electrodes 151 are formed. In this process, N-type impurities, such as phosphorus (P), are implanted into the semiconductor layers MLA from the end portion on one side in the Y-direction (trench 102A side). The region in which the impurities are diffused of the semiconductor layer MLA becomes the connection electrode 151. A region between the connection electrode 141 and the connection electrode 151 of the semiconductor layer MLA becomes the semiconductor member 131. This process is performed by, for example, GPD.

Next, as illustrated in FIG. 49 and FIG. 50, a sacrifice layer 102B containing carbon (C) or the like is formed inside the trench 102A. This process is performed by, for example, CVD.

Next, as illustrated in FIG. 51 and FIG. 52, the sacrifice layer 101B is removed. This process is performed by, for example, wet etching.

Next, as illustrated in FIG. 53 and FIG. 54, the sacrifice layers 143B are removed and the semiconductor member 143 are formed. This process is performed by, for example, wet etching and Atomic Layer Deposition (ALD).

Next, as illustrated in FIG. 55 and FIG. 56, the insulating layers 135 are partially removed to form openings 145A at positions corresponding to the facing electrode 145 and the insulating layers 146, 147. This process is performed by, for example, wet etching.

Next, as illustrated in FIG. 57 and FIG. 58, the insulating layer 146 is formed on upper surfaces, lower surfaces, and both side surfaces in the X-direction of the insulating layers 144, exposed surfaces to the openings 145A of the insulating layers 135, and the inner wall surface of the trench 101A. This process is performed by, for example, CVD.

Here, before executing the process described with reference to FIG. 57 and FIG. 58, as illustrated in FIG. 59, a distance between the two insulating layers 144 adjacent in the X-direction is smaller than a distance between the two insulating layers 144 adjacent in the Z-direction. The process described with reference to FIG. 57 and FIG. 58 is executed, as illustrated in FIG. 60, such that a region between the two insulating layers 144 adjacent in the X-direction is filled with the insulating layer 146, and a region between the two insulating layers 144 adjacent in the Z-direction is not filled with the insulating layer 146.

Next, as illustrated in FIG. 61 and FIG. 62, the insulating layer 148 is formed inside the openings 145A and formed on the inner wall surface of the trench 101A. This process is performed by, for example, CVD.

Next, as illustrated in, FIG. 63 and FIG. 64, the insulating layer 148 is partially removed. In this process, in the insulating layer 148, portions formed inside the openings 145A are remained, and the other portion is removed. This process is performed by, for example, wet etching.

Next, as illustrated in FIG. 65 and FIG. 66, the insulating layer 146 is partially removed. This process is performed by, for example, wet etching.

Next, as illustrated in FIG. 67 and FIG. 68, a conductive layer 145B is formed inside the openings 145A and formed on the inner wall surface of the trench 101A. This process is performed by, for example, CVD.

Next, as illustrated in FIG. 69 and FIG. 70, the conductive layer 145B is partially removed. In this process, portions of the conductive layer 145B provided at positions corresponding to the insulating layers 147 and a portion formed on the inner wall surface of the trench 101A are removed. Through this process, the facing electrodes 145 are formed. This process is performed by, for example, wet etching.

Next, as illustrated in FIG. 71 and FIG. 72, the insulating layer 147 is formed inside the openings 145A and formed on the inner wall surface of the trench 101A. This process is performed by, for example, CVD.

Next, as illustrated in FIG. 73 and FIG. 74, in the insulating layer 147, a portion formed on the inner wall surface of the trench 101A is removed. This process is performed by, for example, wet etching.

Next, as illustrated in, FIG. 75 and FIG. 76, the sacrifice layer 102B is removed. This process is performed by, for example, wet etching.

Next, as illustrated in FIG. 77 and FIG. 78, conductive layers 110A, 120A are formed inside the trenches 101A, 102A. This process is performed by, for example, CVD.

Next, as illustrated in FIG. 79 and FIG. 80, the conductive layers 110A, 120A are partially removed. In this process, end portions of the plurality of insulating layers 121 on one side (trench 102A side) in the Y-direction are exposed to the inside of the trench 102A. Thus, the conductive layer 120A is separated in the Z-direction, and becomes the plurality of wirings 120 arranged in the Z-direction. This process is performed by, for example, wet etching.

Next, as illustrated in FIG. 81 and FIG. 82, the insulating layers 101, 102 are formed inside the trenches 101A, 102A, respectively. This process is performed by, for example, CVD.

Then, the conductive layer 110A is separated in the X-direction by the method of RIE or the like, thereby forming the wirings 110. Further, the insulating layers 111 are formed between the two wirings 110 adjacent in the X-direction, thereby manufacturing the semiconductor memory device described with reference to FIG. 4 to FIG. 10.

### Effect

In this embodiment, as the channel region of the read transistor RTr, the semiconductor member 131 containing single-crystal silicon (Si) is used. As the channel region of the write transistor WTr, the semiconductor member 143 containing the oxide semiconductor is used. With this configuration, since the current of the read transistor RTr in the read operation can be increased, improving the read operation in speed and stability can be attempted. A leakage current through the write transistor WTr can be reduced. Therefore, the number of times of a refresh operation can be decreased.

In this embodiment, to achieve the structure, in the process described with reference to FIG. 11, a plurality of semiconductor layers MLA containing single-crystal silicon (Si) and a plurality of sacrifice layers MLI are alternately formed. Further, this single-crystal silicon contained in the semiconductor layer MLA is used as the channel region of the read transistor RTr. With this method, the single-crystal silicon (Si) can be used as the channel regions of the plurality of read transistors arranged in the Z-direction.

### Second Embodiment

### Circuit Configuration

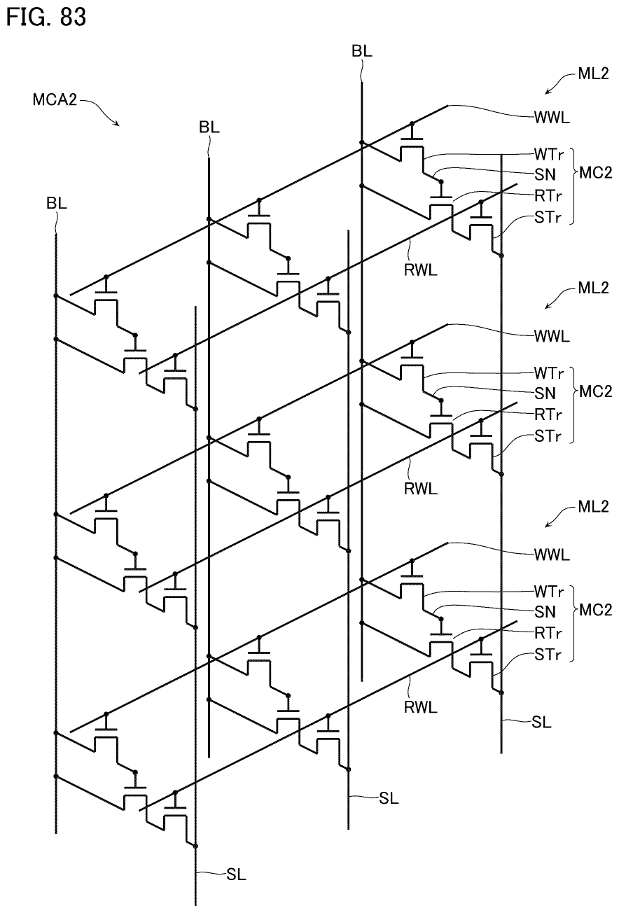

FIG. 83 is a schematic circuit diagram illustrating a configuration of a part of a semiconductor memory device according to a second embodiment. In the following description, the same reference numerals are attached to parts similar to those in the first embodiment, and the explanation is omitted.

As illustrated in FIG. 83, the semiconductor memory device according to the second embodiment includes a memory cell array MCA2. The memory cell array MCA2 includes a plurality of memory layers ML2, and a plurality of bit lines BL and source lines SL connected to these plurality of memory layers ML2.

Each of the memory layers ML2 includes a write word line WWL, a read word line RWL, and a plurality of memory cells MC2 connected to these write word line WWL and read word line RWL. Each of the memory cells MC2 includes a write transistor WTr, a storage node SN, a read transistor RTr, and a select transistor STr.

The memory cell MC2 is basically configured similarly to the memory cell MC.

However, in the memory cell MC2, the other electrode of the read transistor RTr is connected to one electrode of the select transistor STr instead of the read word line RWL.

The select transistor STr is, for example, a field-effect type NMOS transistor. The select transistor STr has the other electrode connected to the source line SL. The one and the other electrodes of the select transistor STr function as a source electrode or a drain electrode corresponding to a voltage applied to the select transistor STr. The select transistor STr has a gate electrode connected to the read word line RWL.

The write operation of the semiconductor memory device according to the second embodiment is executed similarly to the write operation of the semiconductor memory device according to the first embodiment.

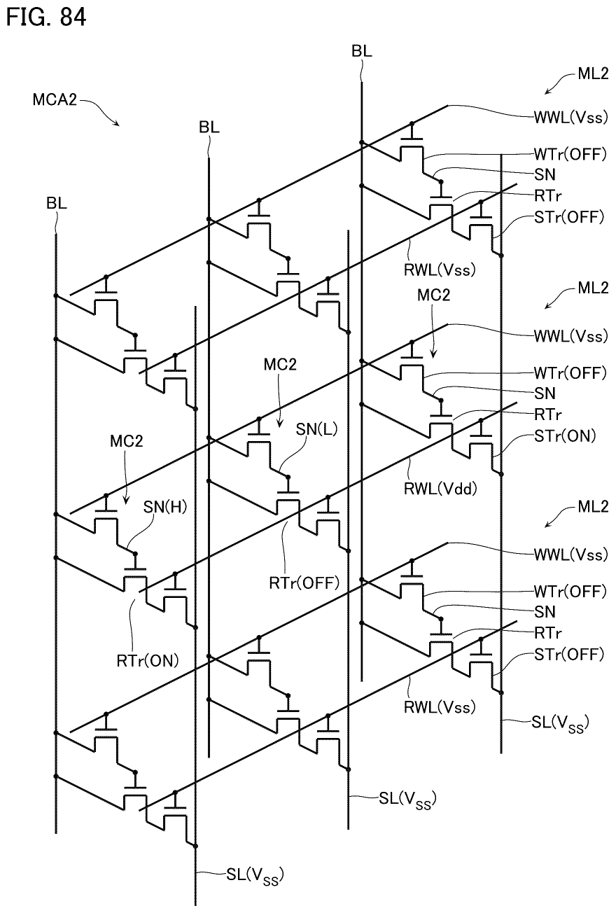

FIG. 84 is a schematic circuit diagram for describing a read operation of the semiconductor memory device according to the second embodiment.

In the read operation, for example, the power supply voltage Vdd is applied to a read word line RWL that is a target of the read operation and the ground voltage Vss is applied to the other read word lines RWL among the plurality of read word lines RWL. The ground voltage Vss is applied to the source line SL. Accordingly, a current flows to the bit lines BL or the bit lines BL are charged corresponding to the states of the storage nodes SN. By reading this by the sense amplifier circuit, data stored in the memory cell MC2 can be obtained.

In the read operation, all the bit lines BL in the memory cell array MCA2 may be the target of the read operation, or a part (for example, one) of the bit lines BL may be the target of the read operation.

Here, in the semiconductor memory device according to the first embodiment, all the read transistors RTr connected to the storage nodes SN in the “H” state can turn ON. Therefore, in the read operation, a leakage current possibly flows from the bit lines BL to the unselected read word lines RWL via the unselected memory cell MC including the storage node SN in the “H” state.

On the other hand, in the semiconductor memory device according to the second embodiment, regardless of the states of the storage nodes SN, the select transistor STr connected to the unselected read word line RWL can be turned OFF. This allows significantly reducing the leakage current.

### Structure

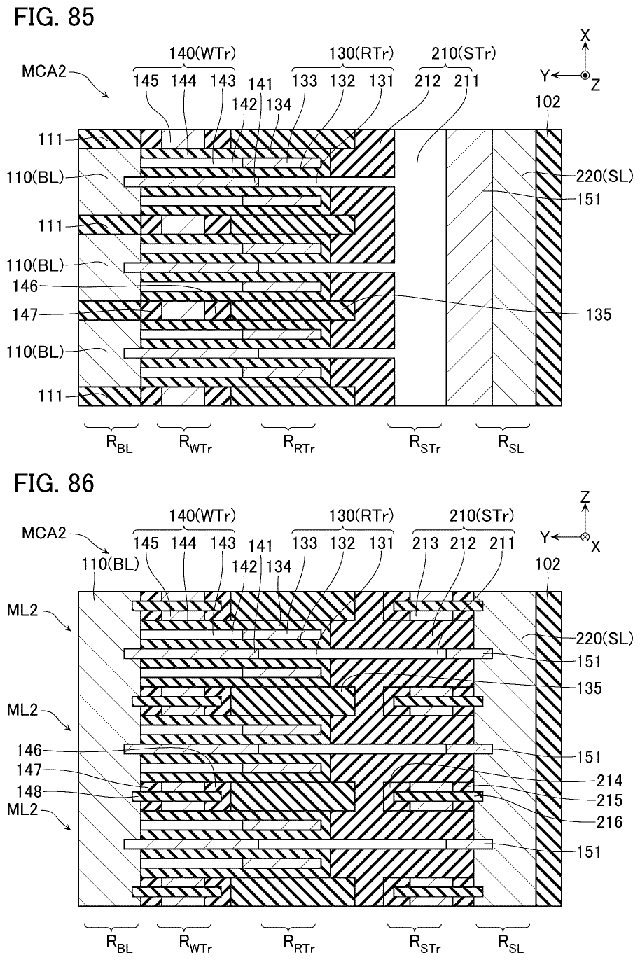

FIG. 85 and FIG. 86 are schematic cross-sectional views illustrating the configuration of a part of the semiconductor memory device according to the second embodiment.

Although not illustrated in FIG. 85 and FIG. 86, the semiconductor memory device according to the second embodiment includes, similarly to the semiconductor memory device according to the first embodiment, the semiconductor substrate Sub.

The semiconductor memory device according to the second embodiment includes a memory cell array MCA2 instead of the memory cell array MCA. The memory cell array MCA2 includes a bit line region R_{BL}, a write transistor region R_{WTr}, a read transistor region R_{RTr}, a select transistor region R_{STr}, and a source line region R_{SL}, which are arranged in this order in the Y-direction. The memory cell array MCA2 includes a plurality of memory layers ML2 arranged in the Z-direction.

Structures of the bit line region R_{BL}, the write transistor region R_{WTr}, and the read transistor region R_{RTr} of the memory cell array MCA2 are similar to the structures of the bit line region R_{BL}, the write transistor region R_{WTr}, and the read transistor region R_{RTr} of the memory cell array MCA.

The source line region R_{SL} includes a wiring 220 extending in the Z-direction and the X-direction. The wiring 220 functions as the source line SL. The wiring 220 includes, for example, a barrier conductive film of titanium nitride (TiN) or the like and a conductive member of tungsten (W) or the like. On a side surface of the wiring 220 on one side (opposite side of the bit line region R_{BL}) in the Y-direction, an insulating layer 102 of silicon oxide (SiO) or the like is disposed.

The select transistor region R_{STr} includes a plurality of transistor structures 210 arranged in the X-direction corresponding to the plurality of wirings 110 and arranged in the Z-direction corresponding to the plurality of memory layers ML2.

Each of the plurality of transistor structures 210 includes a semiconductor member 211 extending in the Y-direction, an insulating layer 212 disposed on an upper surface and a lower surface of the semiconductor member 211, and a facing electrode 213 disposed on an upper surface and a lower surface of the insulating layer 212.

The semiconductor member 211 functions as a channel region of the select transistor STr. The semiconductor member 211 contains, for example, single-crystal silicon (Si). The semiconductor member 211 is continuous with the semiconductor member 131. The semiconductor member 211 is connected to the wiring 220 via the connection electrode 151.

The insulating layer 212 functions as, for example, a gate insulating film of the select transistor STr. The insulating layer 212 contains, for example, silicon oxide (SiO). The insulating layer 212 extends in the Y-direction along the upper surface and the lower surface of the semiconductor member 211.

The facing electrode 213 functions as, for example, the gate electrode of the select transistor STr. The facing electrode 213 contains, for example, titanium nitride (TiN). The facing electrode 213 extends in the Y-direction along the upper surface and the lower surface of the insulating layer 212. The facing electrode 213 faces the upper surface and the lower surface of the semiconductor member 211 via the insulating layer 212.

The facing electrodes 213 in the plurality of transistor structures 210 arranged in the X-direction are mutually continuous, and constitute a wiring extending in the X-direction. This wiring functions as the read word line RWL.

As illustrated in FIG. 85 and FIG. 86, an insulating layer 214 of silicon nitride (SiN) or the like is disposed between the facing electrode 213 and the insulating layer 135, and an insulating layer 215 of silicon nitride (SiN) or the like is disposed between the facing electrode 213 and the source line region R_{SL}. An insulating layer 216 of silicon oxide (SiO) or the like is disposed between the two facing electrodes 213 adjacent in the Z-direction.

### Manufacturing Method

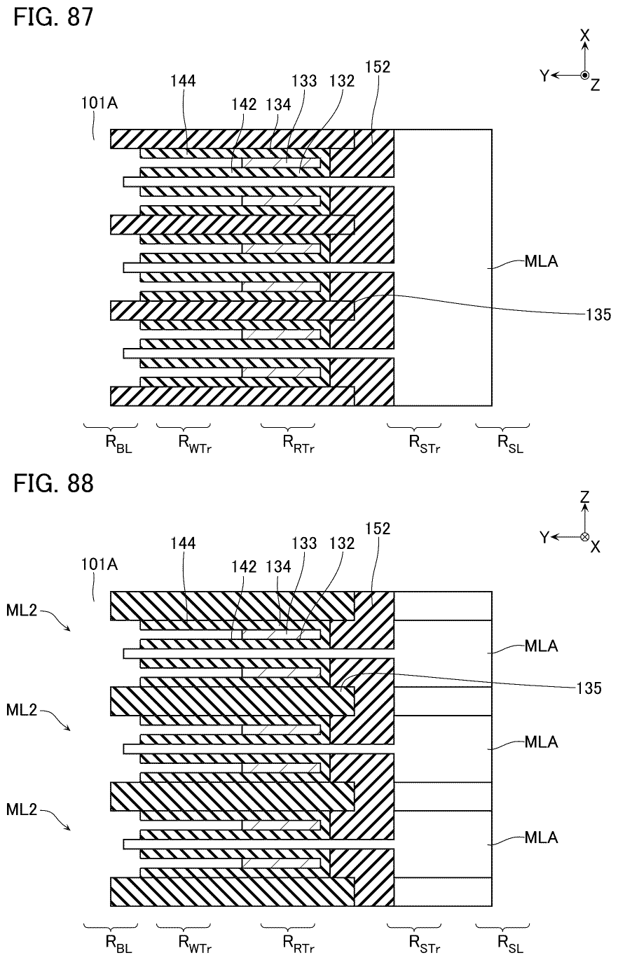

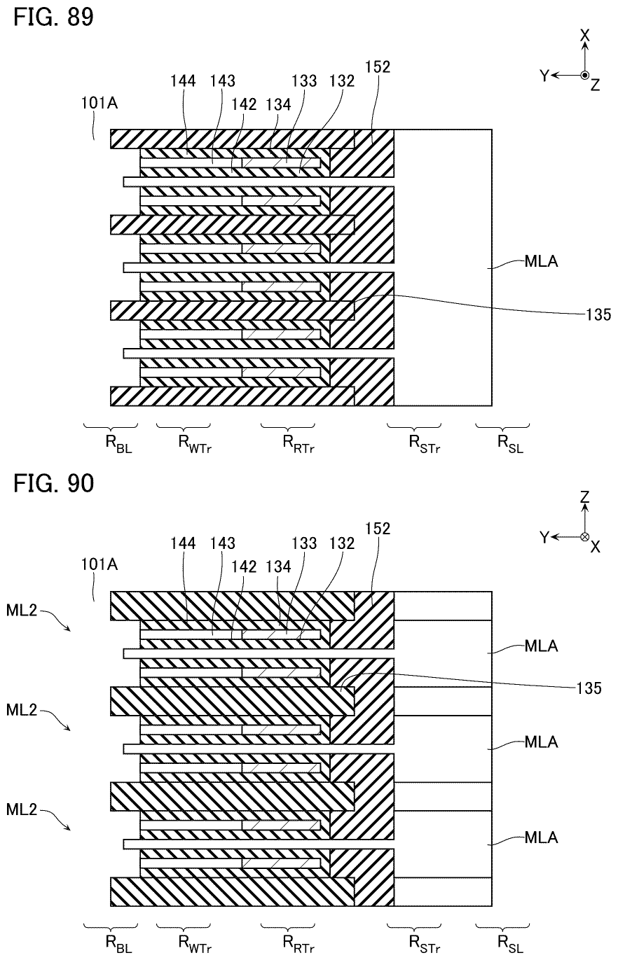

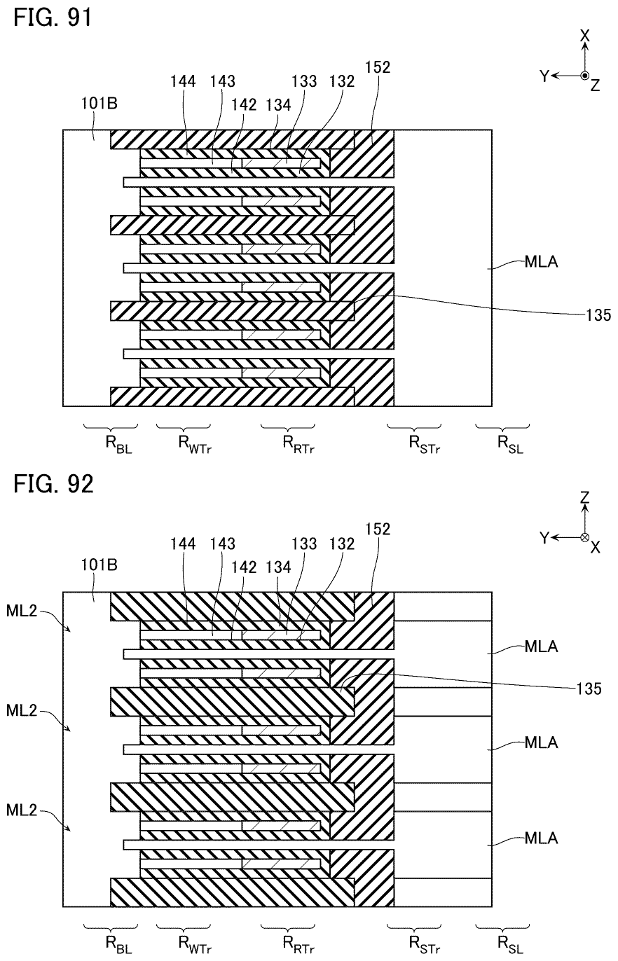

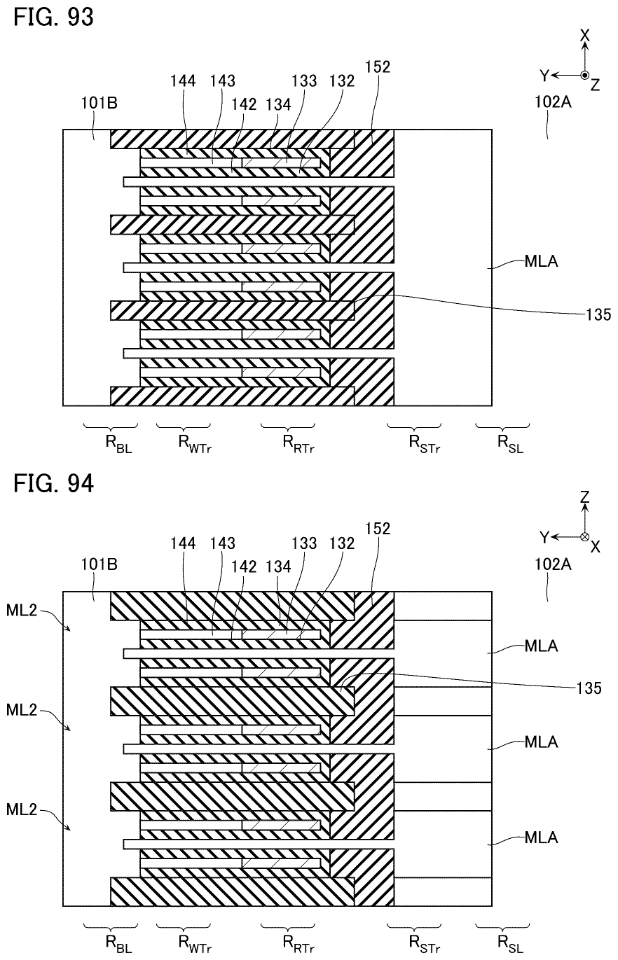

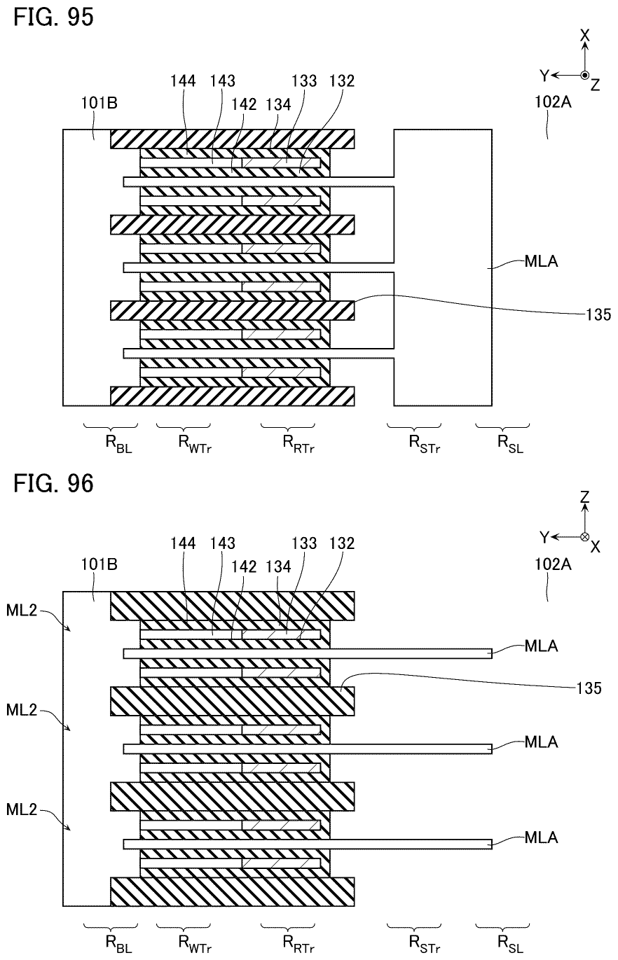

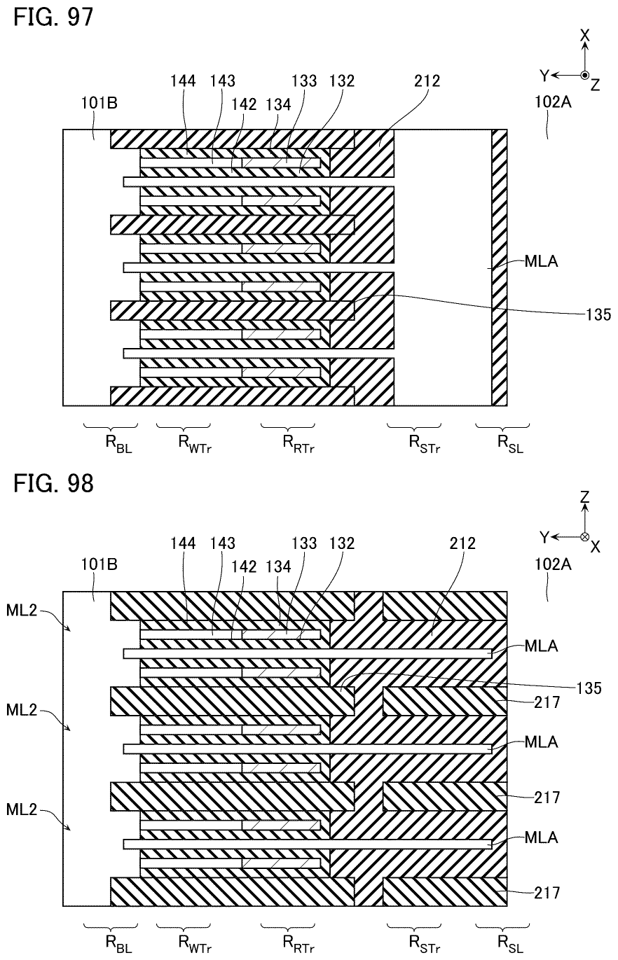

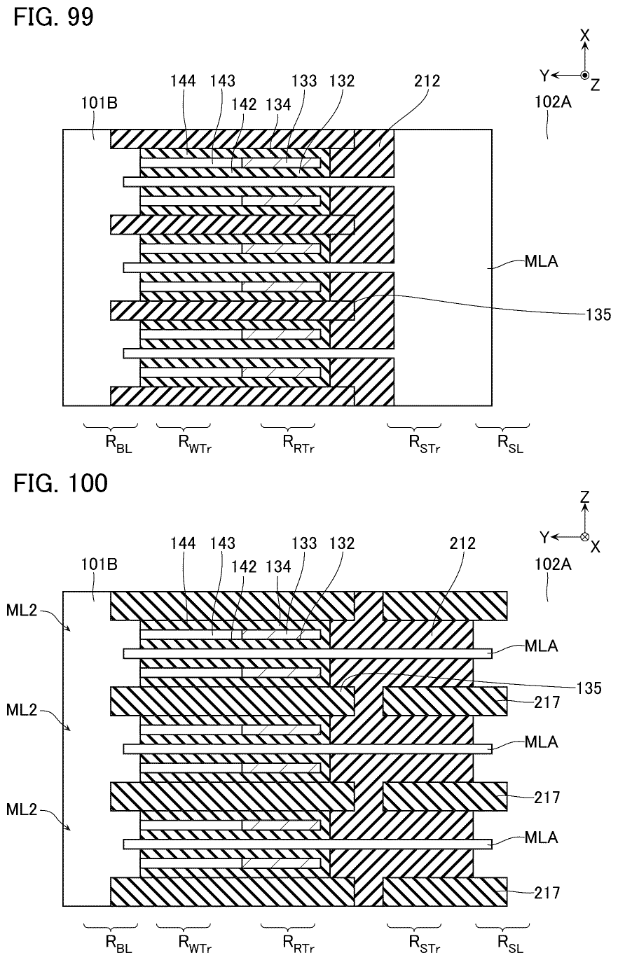

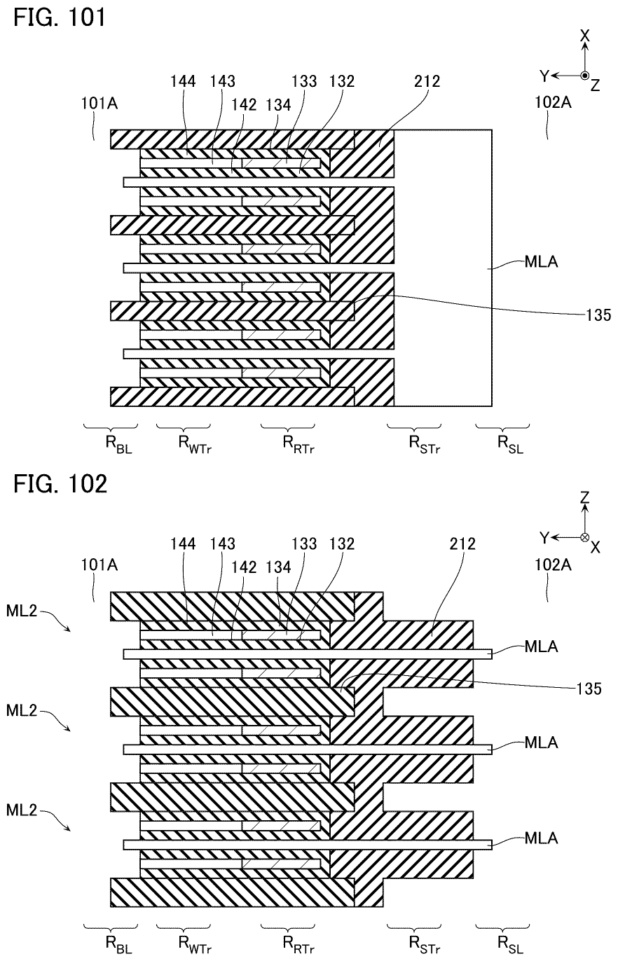

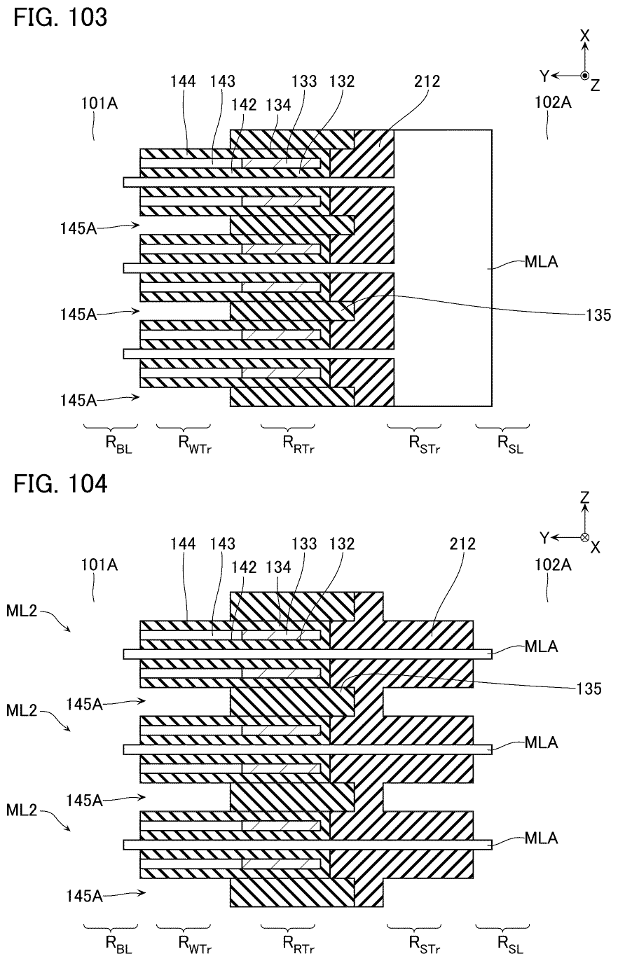

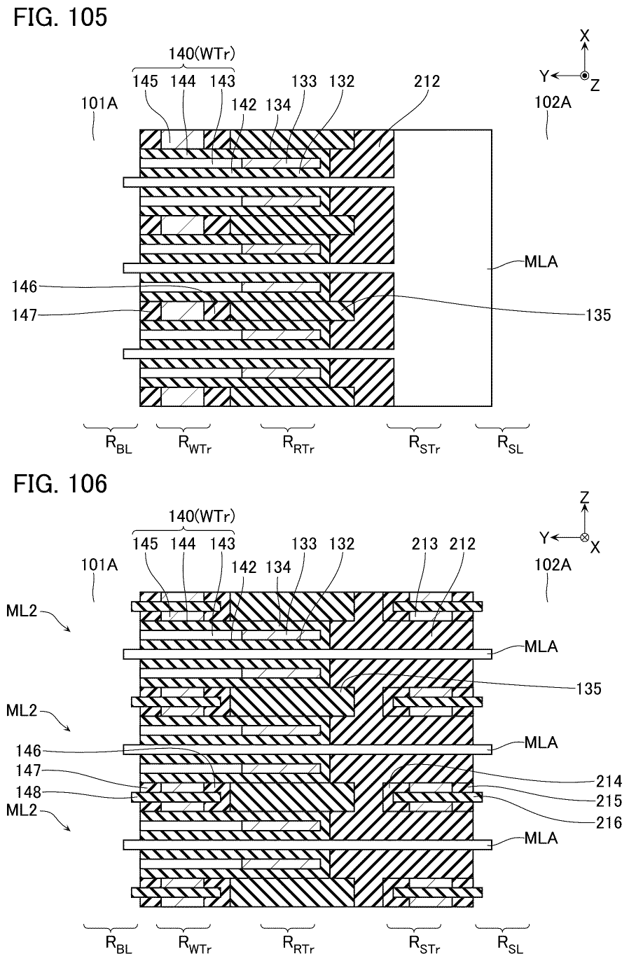

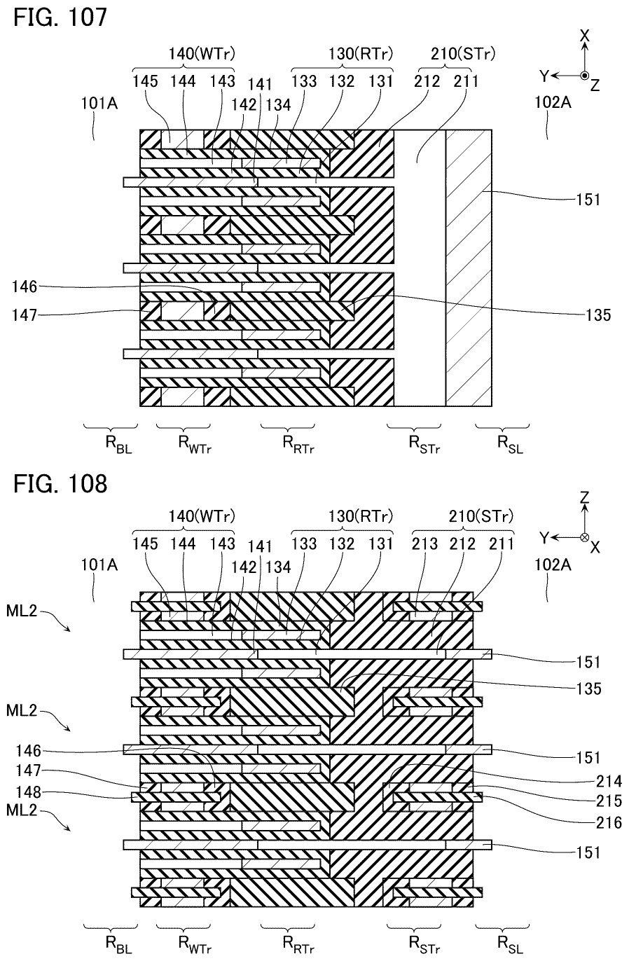

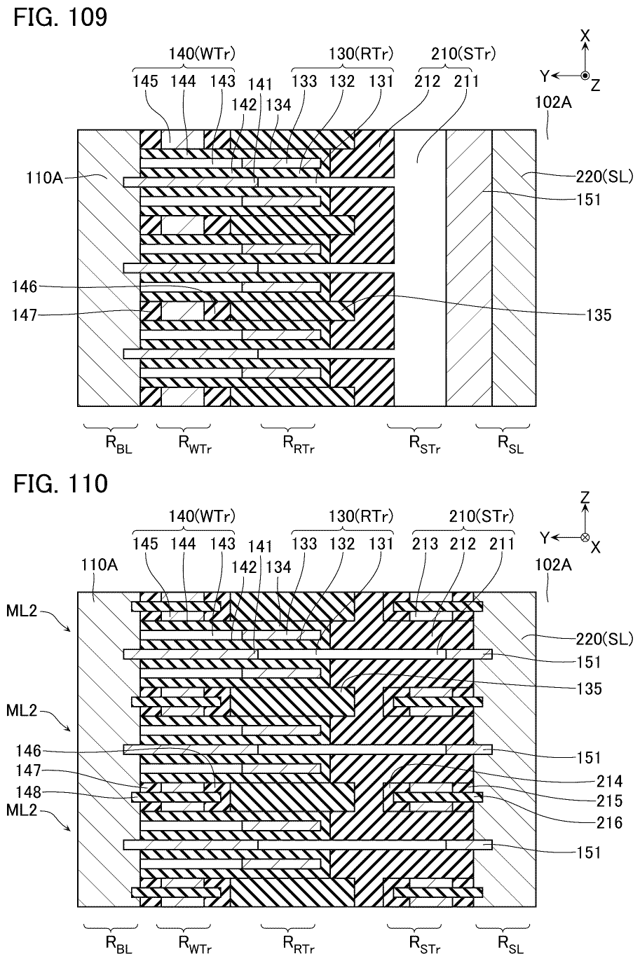

FIG. 87 to FIG. 110 are schematic cross-sectional views for describing a manufacturing method of the semiconductor memory device according to the second embodiment. FIG. 87, FIG. 89, FIG. 91, FIG. 93, FIG. 95, FIG. 97, FIG. 99, FIG. 101, FIG. 103, FIG. 105, FIG. 107, and FIG. 109 illustrate cross-sectional surfaces corresponding to FIG. 85. FIG. 88, FIG. 90, FIG. 92, FIG. 94, FIG. 96, FIG. 98, FIG. 100, FIG. 102, FIG. 104, FIG. 106, FIG. 108, and FIG. 110 illustrate cross-sectional surfaces corresponding to FIG. 86.

In the manufacture of the semiconductor memory device according to the second embodiment, in the manufacturing process of the semiconductor memory device according to the first embodiment, the processes up to the process described with reference to FIG. 32 and FIG. 33 are executed.

Next, as illustrated in FIG. 87 and FIG. 88, the sacrifice layers 143B are removed. This process is performed by, for example, wet etching.

Next, as illustrated in FIG. 89 and FIG. 90, the semiconductor members 143 are formed. This process is performed by, for example, ALD.

Next, as illustrated in FIG. 91 and FIG. 92, the sacrifice layer 101B containing carbon (C) or the like is formed inside the trench 101A. This process is performed by, for example, CVD.

Next, as illustrated in FIG. 93 and FIG. 94, the trench 102A is formed at the position corresponding to the insulating layer 102 (FIG. 7 and FIG. 8). This process is performed by, for example, RIE.

Next, in the manufacturing process of the semiconductor memory device according to the first embodiment, the process described with reference to FIG. 40 and the process described with reference to FIG. 41 and FIG. 42 are executed.

Next, as illustrated in FIG. 95 and FIG. 96, the insulating layer 152 is removed. This process is performed by, for example, wet etching.

Next, as illustrated in FIG. 97 and FIG. 98, the insulating layer 212 is formed on parts of upper surfaces, parts of lower surfaces, both side surfaces in the X-direction, and side surfaces on one side (trench 102A side) in the Y-direction of the insulating layers 135, side surfaces of the insulating layers 132, 134 on one side (trench 102A side) in the Y-direction, and upper surfaces, lower surfaces, side surfaces on one side (trench 102A side) in the Y-direction, and the other exposed surfaces of the semiconductor layers MLA. A sacrifice layer 217 of silicon nitride or the like is formed in a region in which the insulating layer 212 is not formed between the two semiconductor layers MLA adjacent in the Z-direction. This process is performed by, for example, CVD.

Next, as illustrated in FIG. 99 and FIG. 100, the insulating layer 212 is partially removed to expose end portions of the semiconductor layers MLA on one side (trench 102A side) in the Y-direction. This process is performed by, for example, wet etching.

Next, as illustrated in FIG. 101 and FIG. 102, the sacrifice layers 101B, 217 are removed. This process is performed by, for example, wet etching.

Next, as illustrated in FIG. 103 and FIG. 104, the insulating layer 135 is partially removed to form the openings 145A at positions corresponding to the facing electrodes 145 and the insulating layers 146, 147. This process is performed by, for example, wet etching.

Next, in the manufacturing process of the semiconductor memory device according to the first embodiment, the processes from the process described with reference to FIG. 57 and FIG. 58 to the process described with reference to FIG. 73 and FIG. 74 are executed. Accordingly, as illustrated in FIG. 105 and FIG. 106, the facing electrodes 145, 213 and the insulating layers 146, 147, 148, 214, 215, 216 are formed.

Next, as illustrated in FIG. 107 and FIG. 108, the connection electrodes 141, 151 are formed. In this process, N-type impurities, such as phosphorus (P), are implanted into the semiconductor layers MLA from the end portions on one side and the other side in the Y-direction. The regions in which the impurities are diffused of the semiconductor layer MLA becomes the connection electrodes 141, 151. A region between the connection electrode 141 and the connection electrode 151 of the semiconductor layer MLA becomes the semiconductor members 131, 211. This process is performed by, for example, GPD.

Next, as illustrated in FIG. 109 and FIG. 110, a conductive layer 110A is formed inside the trench 101A. The wiring 220 is formed inside the trench 102A. This process is performed by, for example, CVD.

Then, in the manufacturing process of the semiconductor memory device according to the first embodiment, the processes following the process described with reference to FIG. 81 and FIG. 82 are executed, thereby manufacturing the semiconductor memory device described with reference to FIG. 85 and FIG. 86.

### Modification of Semiconductor Memory Device According to Second Embodiment

The facing electrode 213 of the semiconductor memory device according to the second embodiment may face not only the upper surface and the lower surface of the semiconductor member 211 but also side surfaces of the semiconductor member 211 in the X-direction.

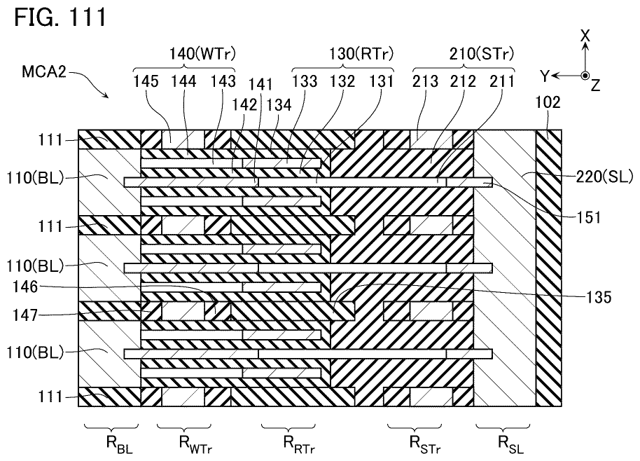

FIG. 111 is a schematic cross-sectional view illustrating a configuration of a part of the modification of the semiconductor memory device according to the second embodiment. The semiconductor memory device illustrated in FIG. 111 is basically configured similarly to the semiconductor memory device according to the second embodiment. However, in the semiconductor memory device illustrated in FIG. 111, the insulating layer 212 is disposed on not only the upper surface and the lower surface of the semiconductor member 211, but also both side surfaces of the semiconductor member 211 in the X-direction. The facing electrode 213 is disposed on not only the upper surface and the lower surface of the insulating layer 212, but also both side surfaces of the insulating layer 212 in the X-direction. The facing electrode 213 faces not only the upper surface and the lower surface of the semiconductor member 211, but also the side surface of the semiconductor member 211 in the X-direction.

When manufacturing this structure, for example, it is considered to form a plurality of trenches in the select transistor region R_{STr} and the source line region R_{SL} after executing the process described with reference to FIG. 36 and FIG. 37. These plurality of trenches are formed at a plurality of positions in the X-direction corresponding to the plurality of insulating layers 111 (FIG. 7), penetrate the plurality of semiconductor layers MLA and the plurality of sacrifice layers MLI to extend in the Z-direction, and extend in the Y-direction across the select transistor region R_{STr} and the source line region R_{SL}. Next, a sacrifice layer is formed inside the trenches. Next, the process described with reference to FIG. 38 and FIG. 39 is performed. Then, in the manufacturing process of the semiconductor memory device according to the second embodiment, the processes following the process described with reference to FIG. 40 are executed.

### Third Embodiment

### Structure

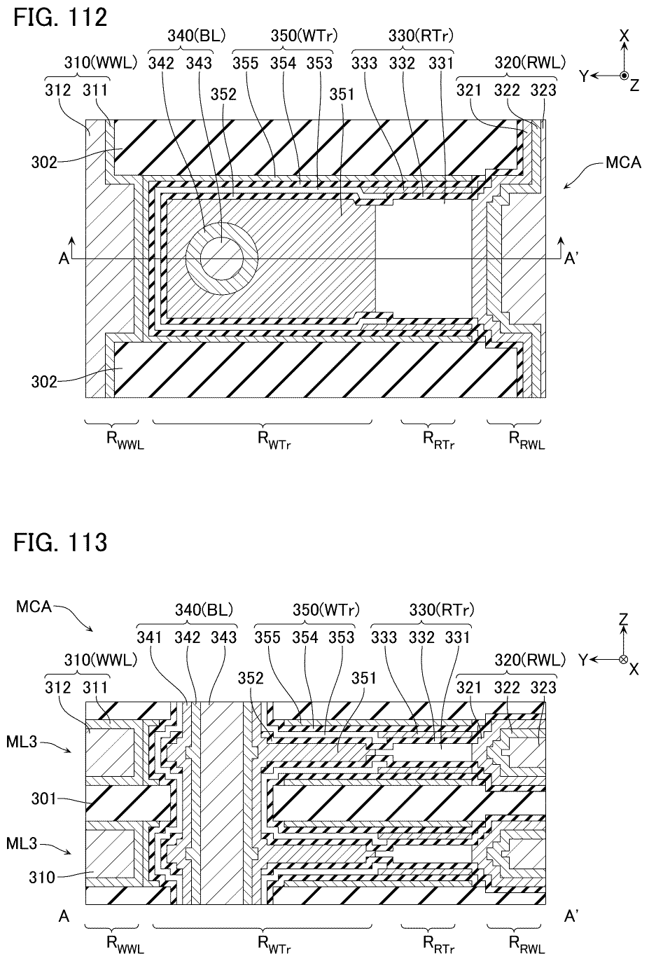

FIG. 112 and FIG. 113 are schematic cross-sectional views illustrating the configuration of a part of the semiconductor memory device according to the third embodiment. FIG. 112 corresponds to the XY cross-sectional surface. FIG. 113 corresponds to the YZ cross-sectional surface of the structure illustrated in FIG. 112 taken along the line A-A′ when viewed along the arrow direction.

A memory cell array MCA according to the third embodiment includes a write word line region R_{WWL}, a write transistor region R_{WTr}, a read transistor region R_{RTr}, and a read word line region R_{RWL} arranged in the Y-direction in this order.

The memory cell array MCA according to the third embodiment includes a plurality of memory layers ML3 and a plurality of insulating layers 301 alternately arranged in the Z-direction. The insulating layer 301 contains silicon oxide (SiO) or the like. Between the write word line region R_{WWL} and the read word line region R_{RWL}, a plurality of insulating layers 302 extending in the Z-direction and the Y-direction and separating the plurality of memory layers ML3 and the plurality of insulating layers 301 alternately arranged in the Z-direction in the X-direction are provided. The insulating layer 302 contains silicon oxide (SiO) or the like.

The write word line region R_{WWL} includes a plurality of wirings 310 that extend in the X-direction and are arranged in the Z-direction corresponding to the plurality of memory layers ML3, and the insulating layers 301 provided between these wirings 310. The plurality of wirings 310 function as, for example, the write word lines WWL. The plurality of wirings 310 include, for example, a barrier conductive film 311 of titanium nitride (TiN) or the like and a conductive member 312 of tungsten (W) or the like. The insulating layer 301 contains, for example, silicon oxide (SiO).

The read word line region R_{RWL} includes a plurality of wirings 320 that extend in the X-direction and are arranged in the Z-direction corresponding to the plurality of memory layers ML3, and the insulating layers 301 provided between these wirings 320. The plurality of wirings 320 function as, for example, the read word lines R_{RWL}. The plurality of wirings 320 include, for example, a conductive oxide film 321, a barrier conductive film 322 of titanium nitride (TiN) or the like, and a conductive member 323 of tungsten (W) or the like. The conductive oxide film 321 may contain, for example, indium tin oxide (ITO), indium zinc oxide (IZO), ruthenium oxide (RuO), iridium oxide (IrO), or another conductive material containing oxygen.

The read transistor region R_{RTr} includes a plurality of transistor structures 330 arranged in the X-direction alternately with the plurality of insulating layers 302 arranged in the X-direction and arranged in the Z-direction corresponding to the plurality of memory layers ML3.

Each of the plurality of transistor structures 330 includes a semiconductor member 331 extending in the Y-direction, an insulating layer 332 provided on an upper surface, a lower surface, and both side surfaces in the X-direction of the semiconductor member 331, and a facing electrode 333 provided on an upper surface, a lower surface, and both side surfaces in the X-direction of the insulating layer 332. In this embodiment, an upper surface, a lower surface, and both side surfaces in the X-direction of the transistor structure 330 are covered with an insulating layer 354 and a facing electrode 355 described later.

The semiconductor member 331 functions as a channel region of the read transistor RTr. The semiconductor member 331 may include, for example, an oxide semiconductor. The oxide semiconductor may include materials exemplified as materials of the semiconductor member 143.

The insulating layer 332 functions as, for example, a gate insulating film of the read transistor RTr. The insulating layer 332 contains, for example, silicon oxide (SiO). The insulating layer 332 extends in the Y-direction along the upper surface, the lower surface, and both side surfaces in the X-direction of the semiconductor member 331.

The facing electrode 333 functions as, for example, the gate electrode of the read transistor RTr and the storage node SN. The facing electrode 333 contains, for example, titanium nitride (TiN). The facing electrode 333 extends in the Y-direction along the upper surface, the lower surface, and both side surfaces in the X-direction of the insulating layer 332. The facing electrode 333 faces the upper surface, the lower surface, and both side surfaces in the X-direction of the semiconductor member 331 via the insulating layer 332.

The write transistor region R_{WTr} includes a plurality of wirings 340 that are arranged in the X-direction alternately with the plurality of insulating layers 302 arranged in the X-direction and penetrate the plurality of memory layers ML3 to extend in the Z-direction. The write transistor region R_{WTr} includes a plurality of connection electrodes 351, a plurality of insulating layers 352, and a plurality of transistor structures 350 that are arranged in the X-direction corresponding to these plurality of wirings 340 and arranged in the Z-direction corresponding to the plurality of memory layers ML3.

Each of the plurality of wirings 340 is formed in an approximately columnar shape. The plurality of wirings 340 function as, for example, the bit lines BL. The plurality of wirings 340 include, for example, a conductive oxide film 341, a barrier conductive film 342 of titanium nitride (TiN) or the like, and a conductive member 343 of tungsten (W) or the like. The conductive oxide film 341 may contain, for example, indium tin oxide (ITO), indium zinc oxide (IZO), ruthenium oxide (RuO), iridium oxide (IrO), or another conductive material containing oxygen. In the illustrated example, the barrier conductive film 342 covers an outer peripheral surface of the conductive member 343. The conductive oxide film 341 covers an outer peripheral surface of the barrier conductive film 342.

The connection electrode 351 is connected to the wiring 340 and the semiconductor member 331, and electrically connects these configurations. The connection electrode 351 covers an outer peripheral surface of the wiring 340 over the whole circumference, and is connected to the outer peripheral surface of the wiring 340 over the whole circumference. The connection electrode 351 is in contact with a surface of the semiconductor member 331 on a write word line region R_{WWL} side in the Y-direction. The connection electrode 351 may contain, for example, indium tin oxide (ITO), indium zinc oxide (IZO), ruthenium oxide (RuO), iridium oxide (IrO), or another conductive material containing oxygen.

In this embodiment, the connection electrode 351 is continuous with the conductive oxide film 341 in the wiring 340, and contains a material similar to that of the conductive oxide film 341. The connection electrode 351 is simultaneously formed, for example, at the formation of the conductive oxide film 341.

Each of the plurality of insulating layers 352 is provided on an upper surface, a lower surface, both side surfaces in the X-direction, and a surface on the write word line region R_{WWL} side in the Y-direction of the plurality of connection electrodes 351. The insulating layer 352 is provided between the connection electrode 351 and the semiconductor member 353 to electrically insulate these configurations from one another. The insulating layer 352 contains, for example, silicon oxide (SiO). The insulating layer 352 extends in the Y-direction along the upper surface, the lower surface, and both side surfaces in the X-direction of the connection electrode 351.

In this embodiment, the insulating layer 352 is continuous with the insulating layer 332, and contains a material similar to that of the insulating layer 332. The insulating layer 352 is simultaneously formed, for example, at the formation of the insulating layer 332.

Each of the plurality of transistor structures 350 includes a semiconductor member 353 provided on an upper surface, a lower surface, both side surfaces in the X-direction, and a surface on the write word line region R_{WWL} side in the Y-direction of the insulating layer 352, the insulating layer 354 provided on an upper surface, a lower surface, both side surfaces in the X-direction, and a surface on the write word line region R_{WWL} side in the Y-direction of the semiconductor member 353, and the facing electrode 355 provided on an upper surface, a lower surface, both side surfaces in the X-direction, and a surface on the write word line region R_{WWL} side in the Y-direction of the insulating layer 354.

The semiconductor member 353 functions as a channel region of the write transistor WTr. The semiconductor member 353 extends in the Y-direction along the upper surface, the lower surface, and both side surfaces in the X-direction of the insulating layer 352. An end portion of the semiconductor member 353 on a wiring 320 side in the Y-direction is connected to the facing electrode 333. The semiconductor member 353 covers the outer peripheral surface of the wiring 340 over the whole circumference at a height position between the memory layers ML3, and is connected to the wiring 340 over the whole circumference.

The semiconductor member 353 may contain, for example, an oxide semiconductor. The oxide semiconductor may include materials exemplified as the materials of the semiconductor member 143.

The insulating layer 354 functions as, for example, a gate insulating film of the write transistor WTr. The insulating layer 354 contains, for example, silicon oxide (SiO). The insulating layer 354 extends in the Y-direction along the upper surface, the lower surface, and both side surfaces in the X-direction of the semiconductor member 353.

The facing electrode 355 functions as, for example, the gate electrode of the write transistor WTr. The facing electrode 355 contains, for example, titanium nitride (TiN). The facing electrode 355 extends in the Y-direction along the upper surface, the lower surface, and both side surfaces in the X-direction of the insulating layer 354. The facing electrode 355 faces the upper surface, the lower surface, and both side surfaces in the X-direction of the semiconductor member 353 via the insulating layer 354.

In this embodiment, the insulating layer 354 and the facing electrode 355 extend in the Y-direction across the write transistor region R_{WTr} and the read transistor region R_{RTr}. Therefore, as described above, the upper surface, the lower surface, and both side surfaces in the X-direction of the transistor structure 330 are covered with the insulating layer 354 and the facing electrode 355. With this structure, by the facing electrode 355 that functions as a shield of the facing electrode 333, occurrence of data interference between two memory cells MC adjacent in the Z-direction can be reduced.

### Manufacturing Method

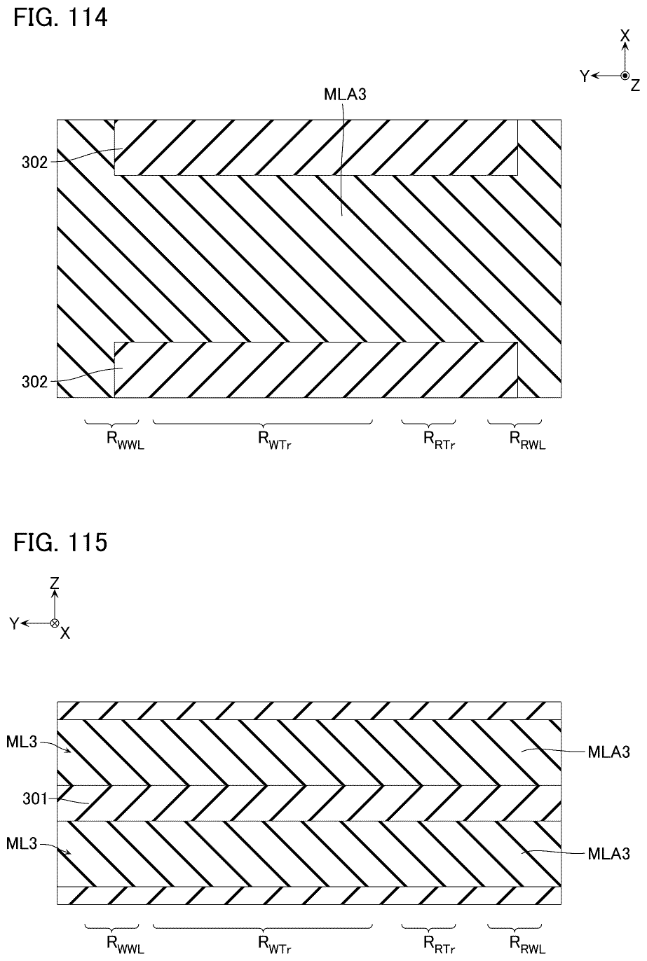

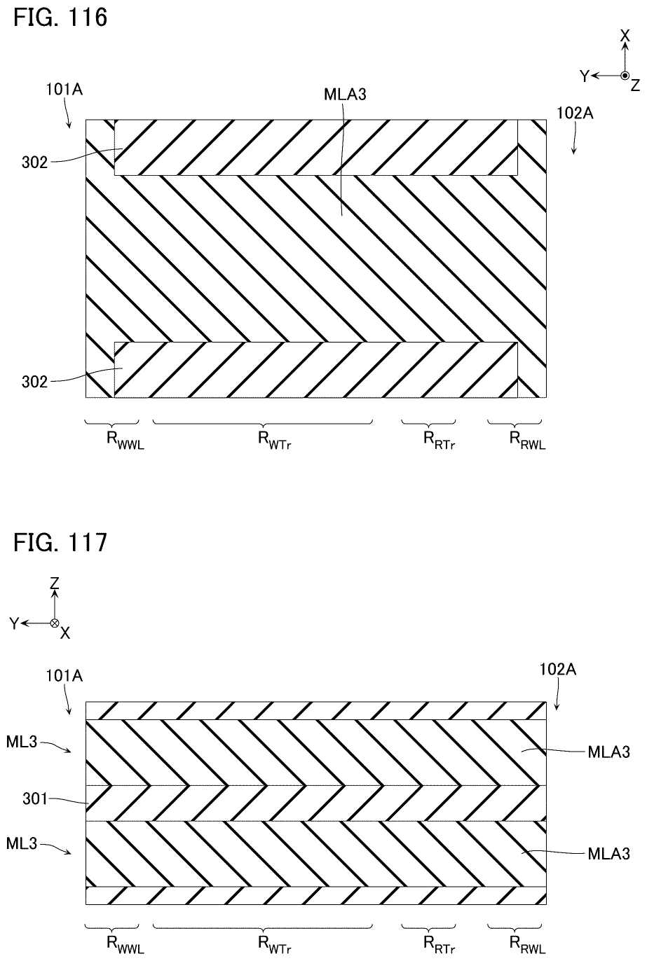

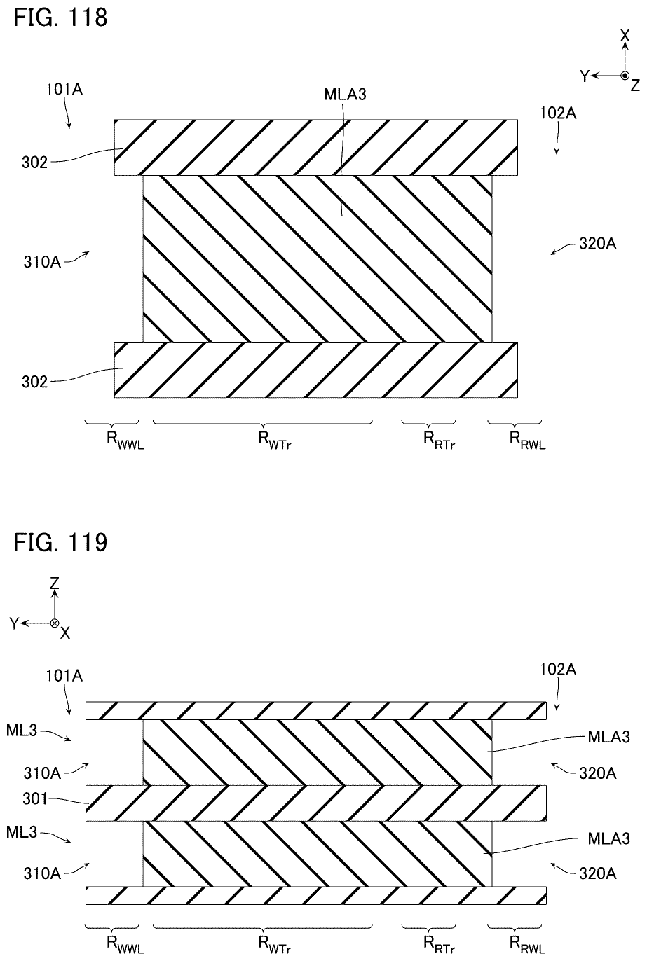

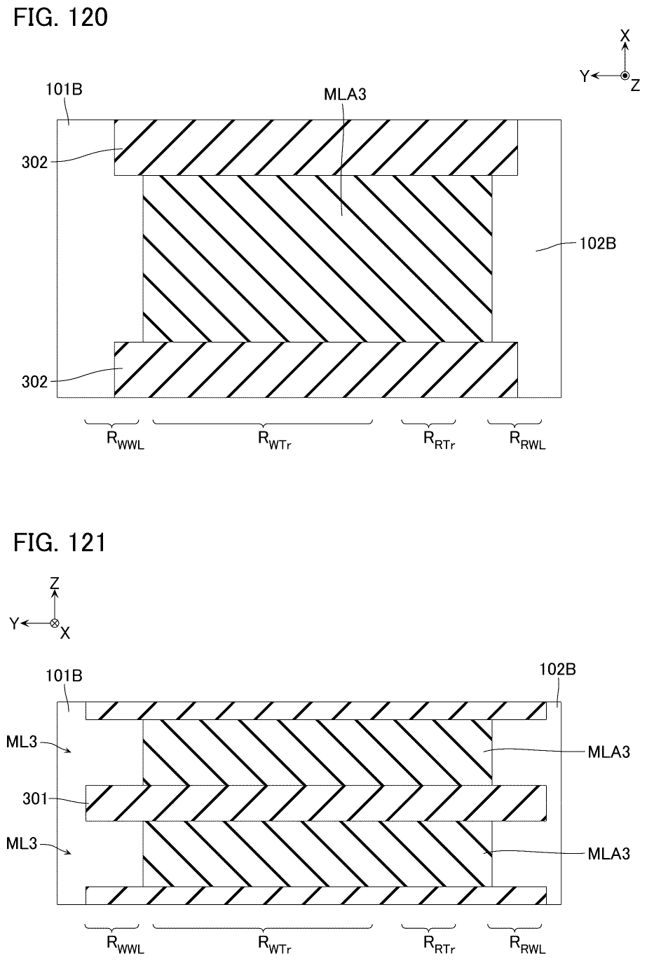

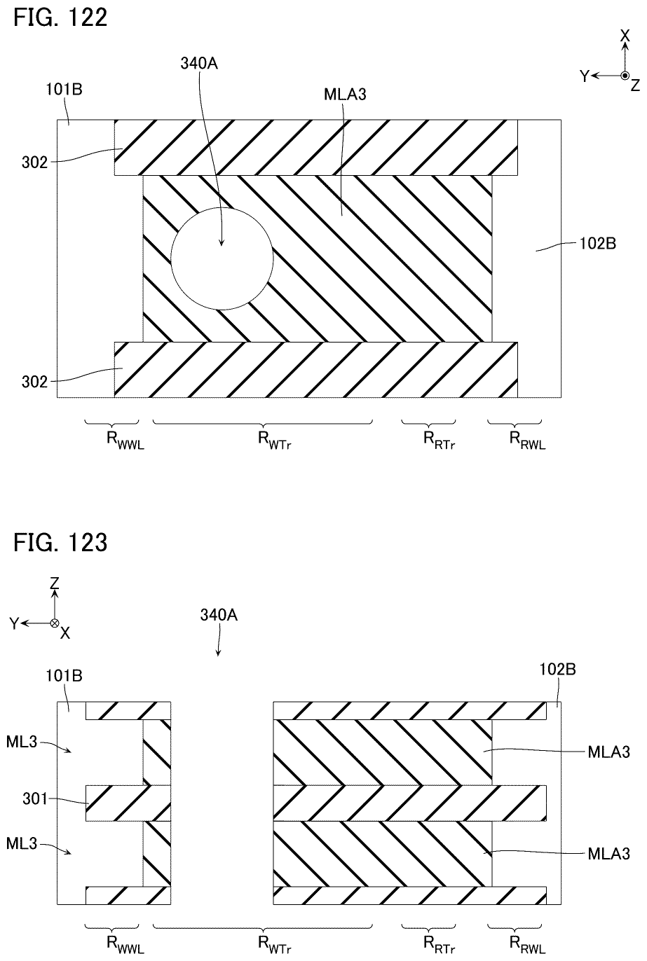

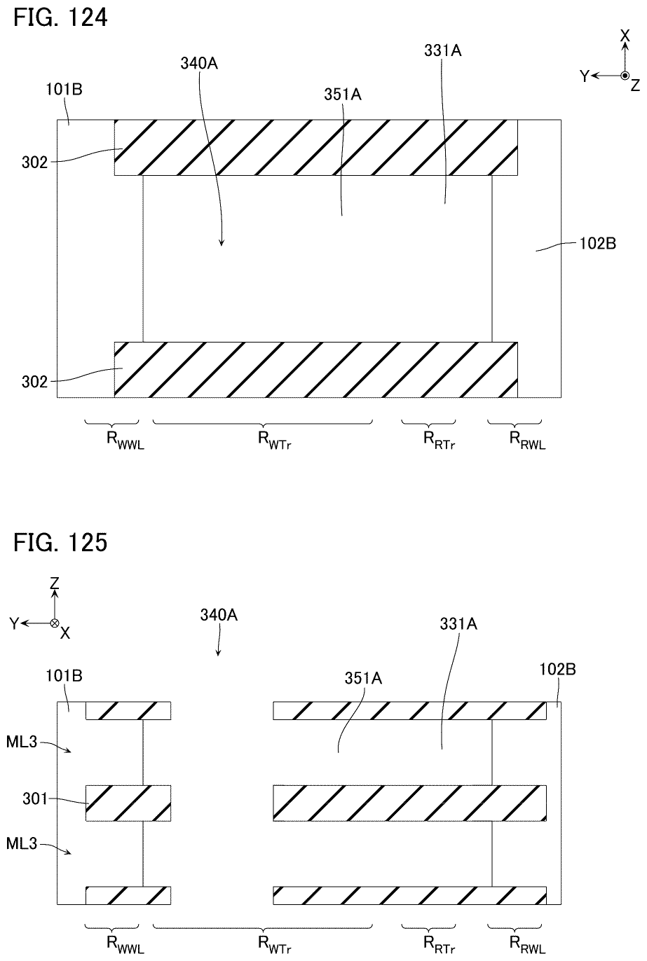

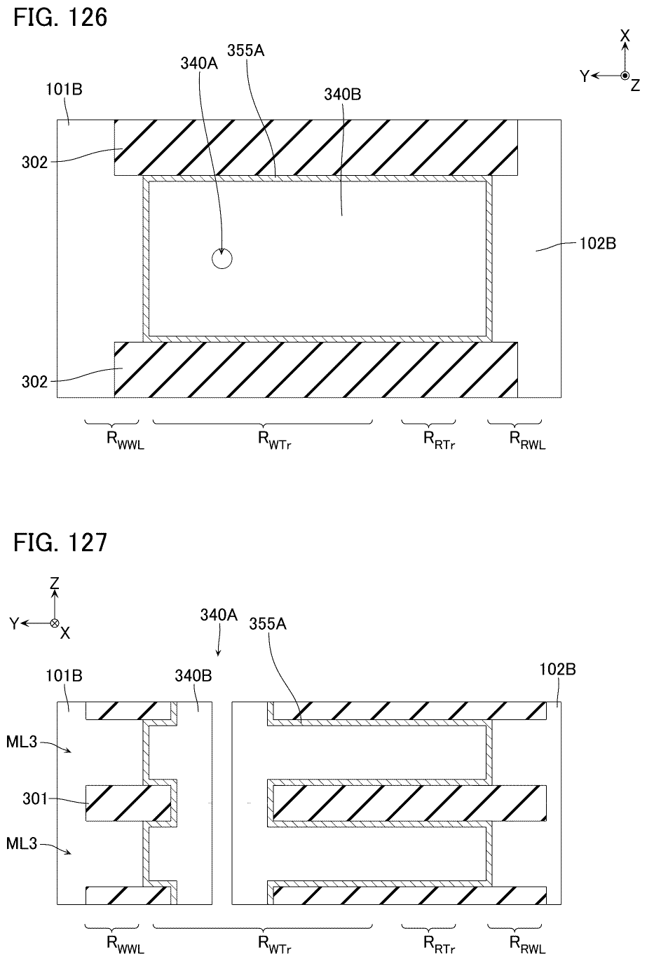

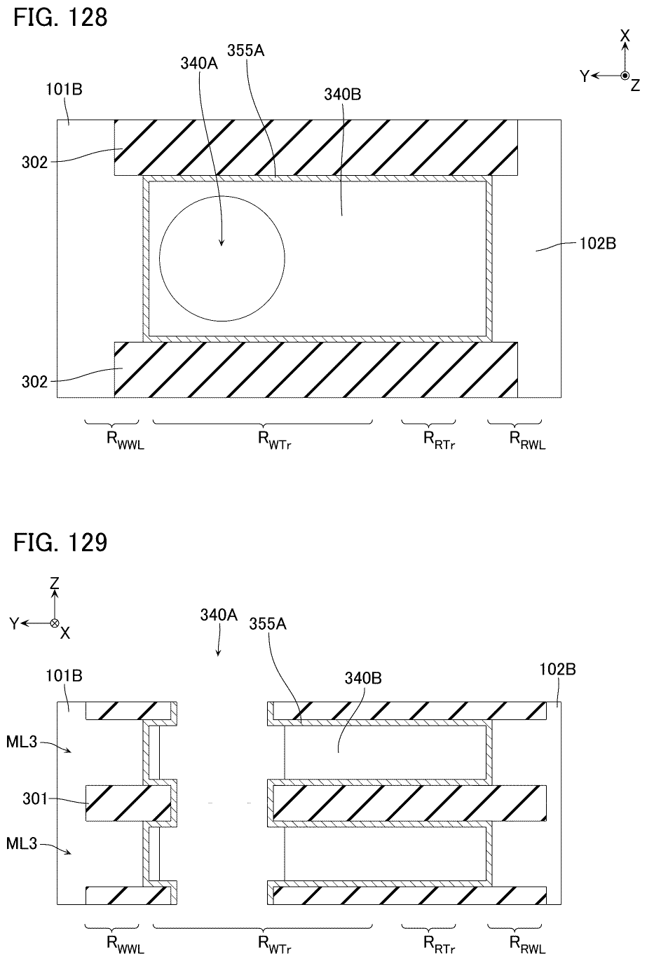

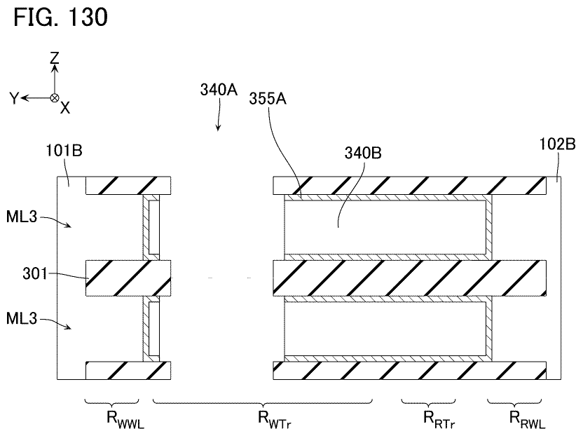

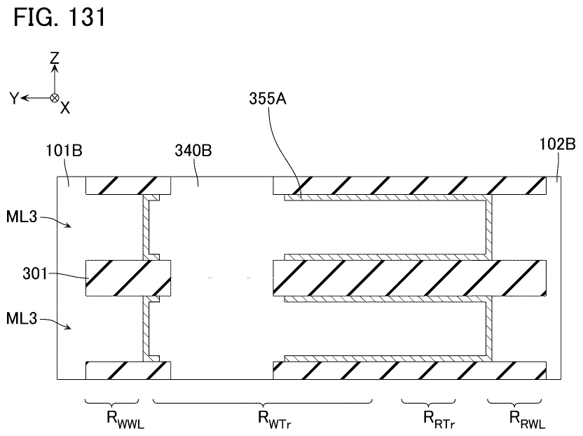

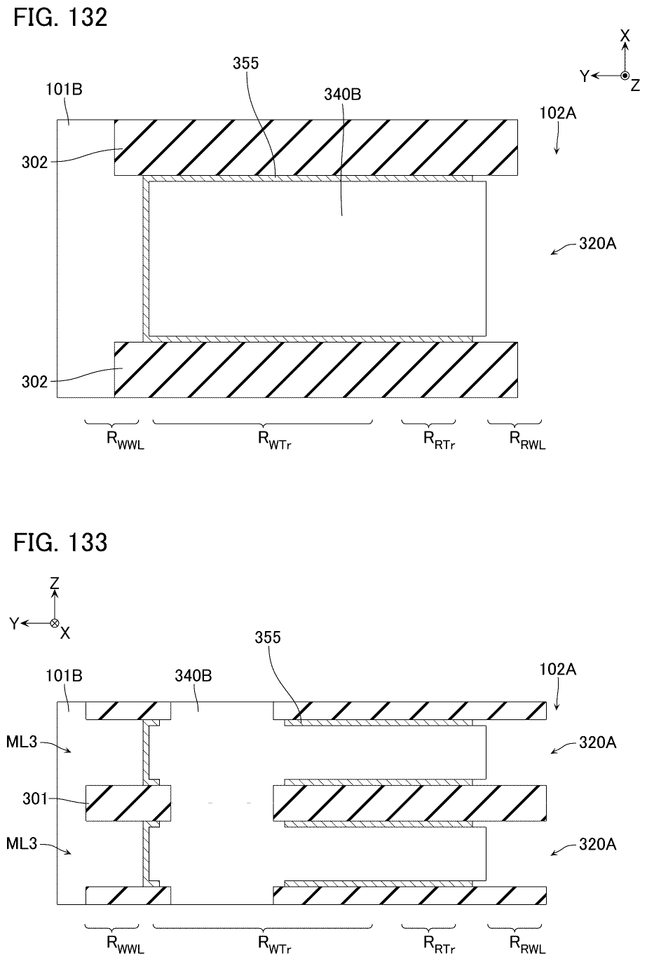

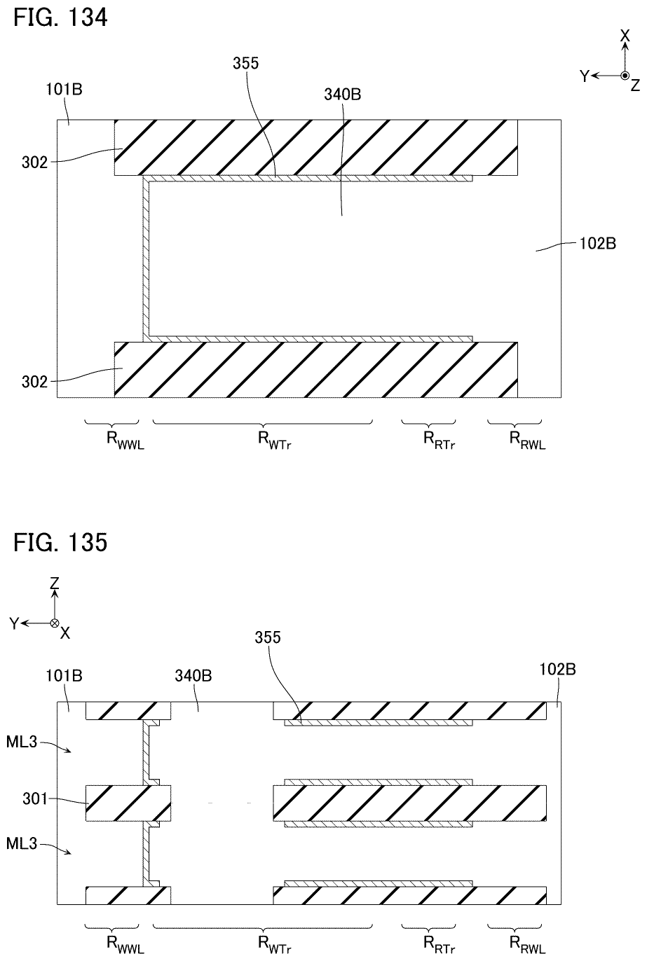

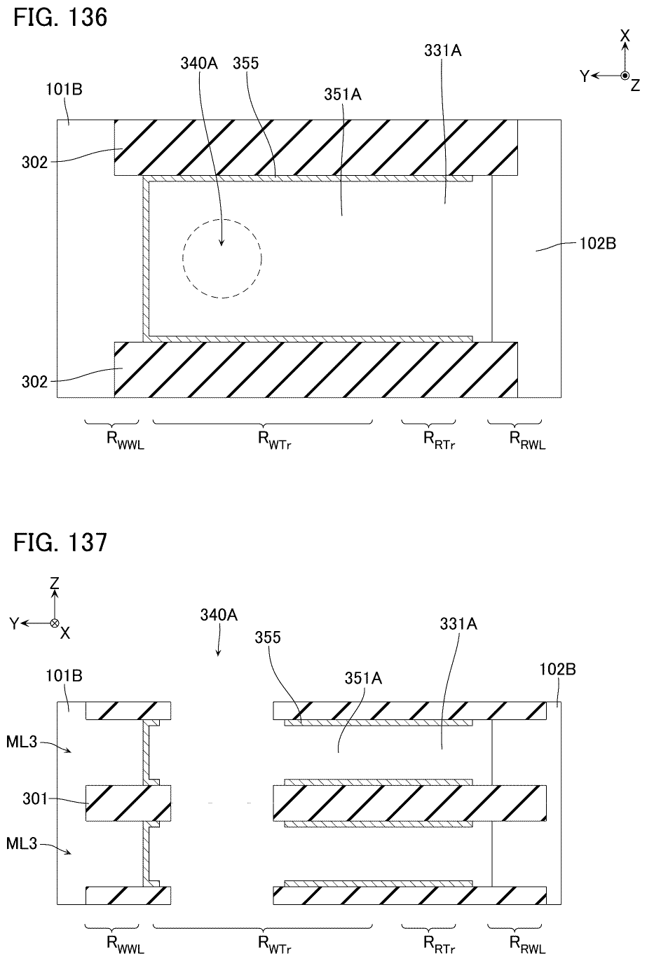

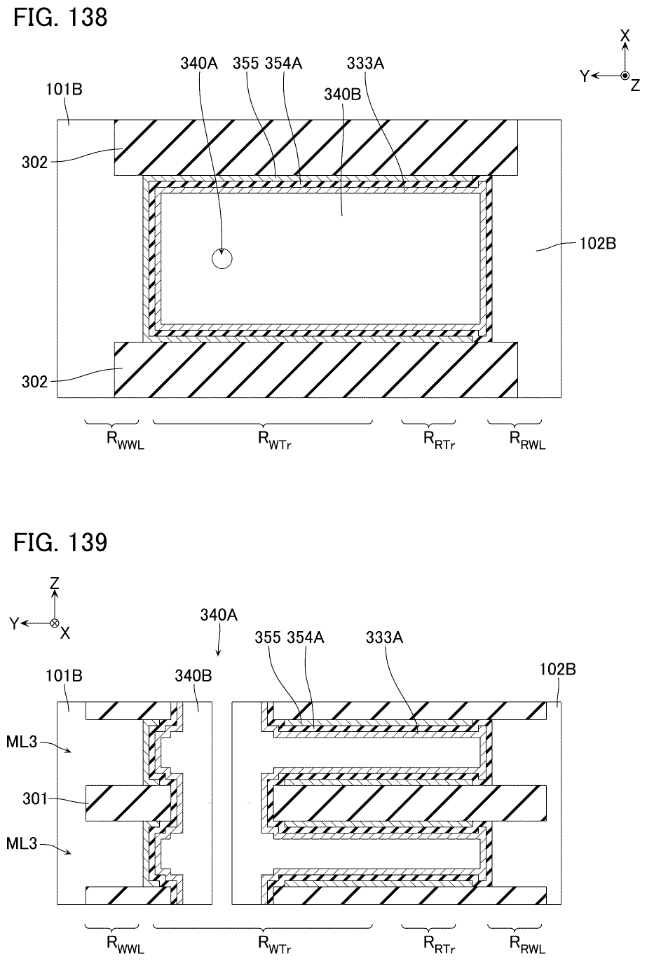

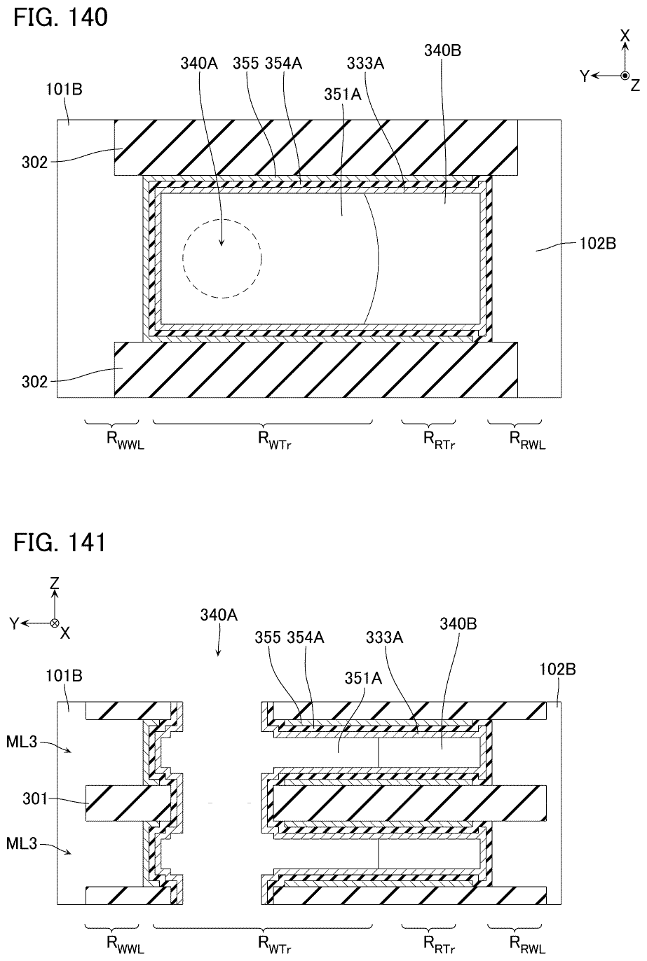

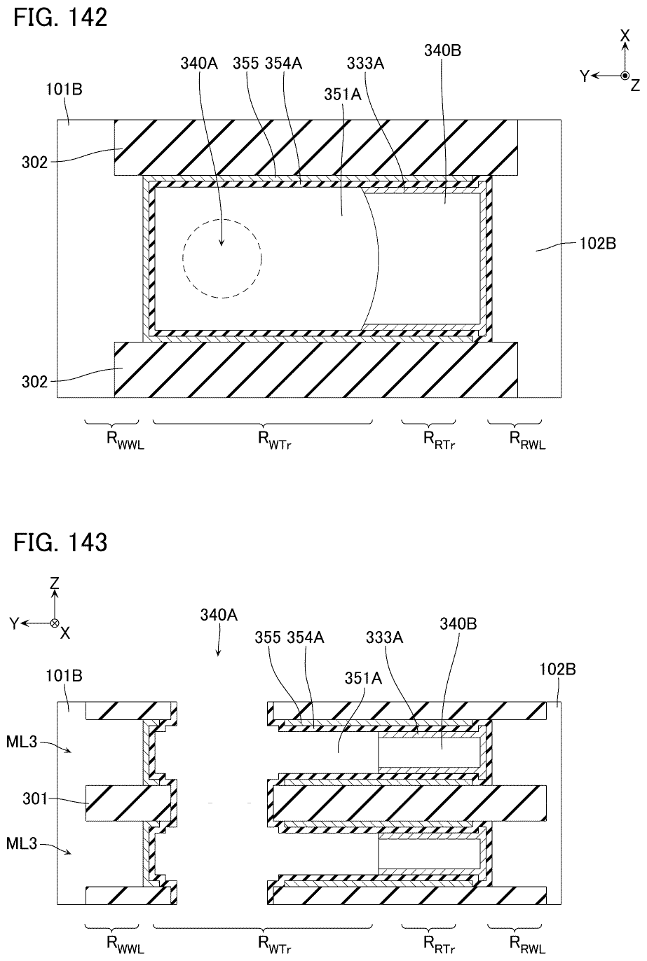

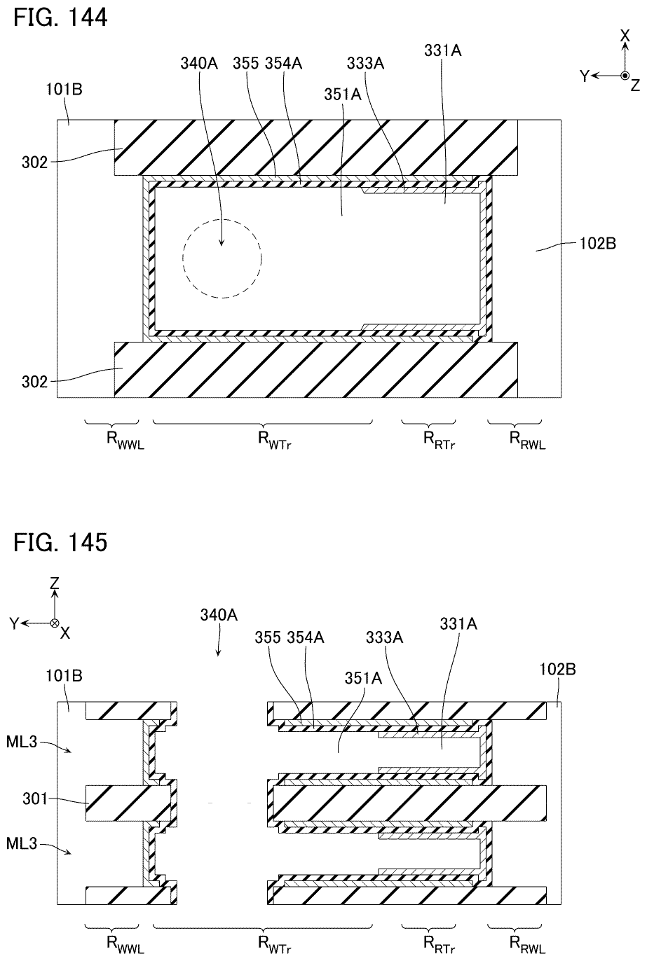

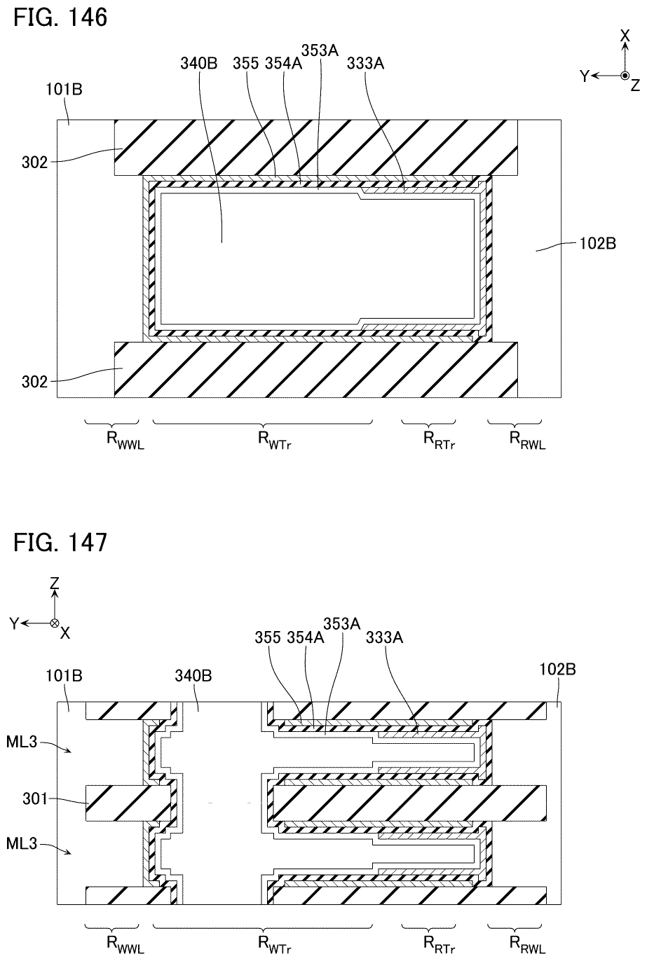

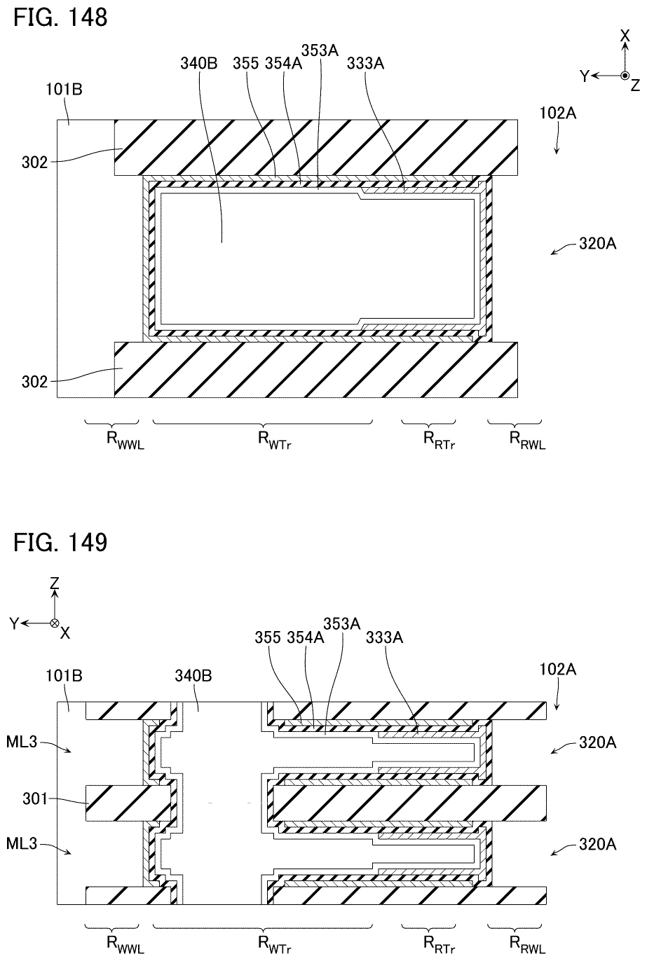

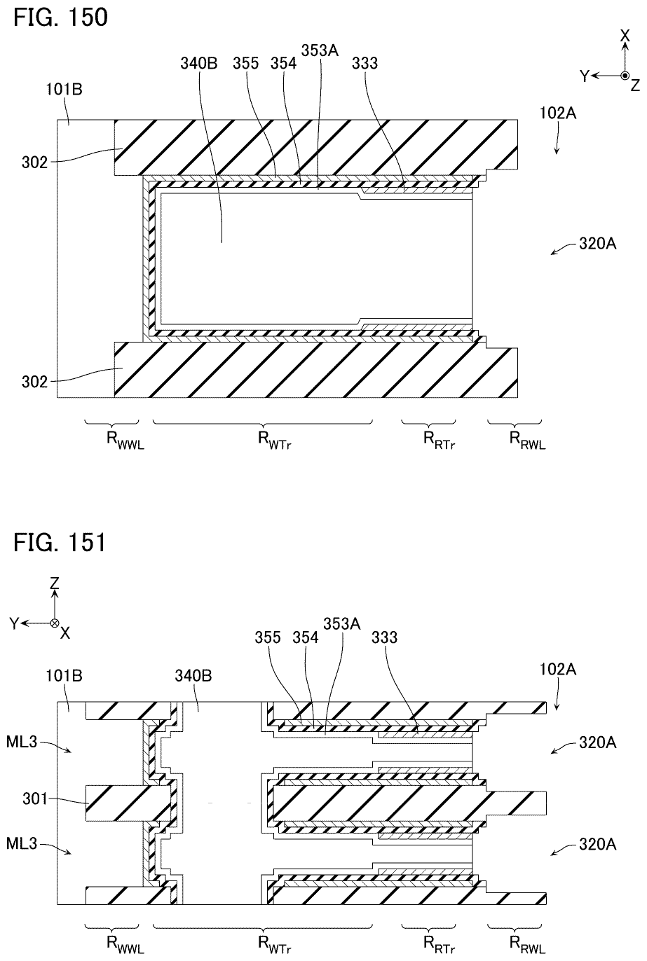

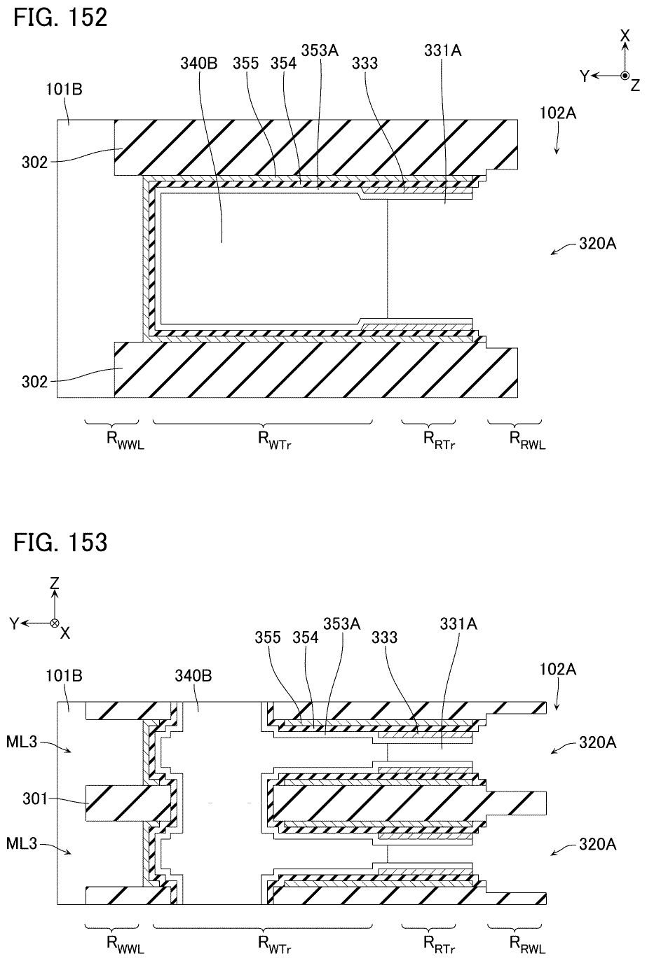

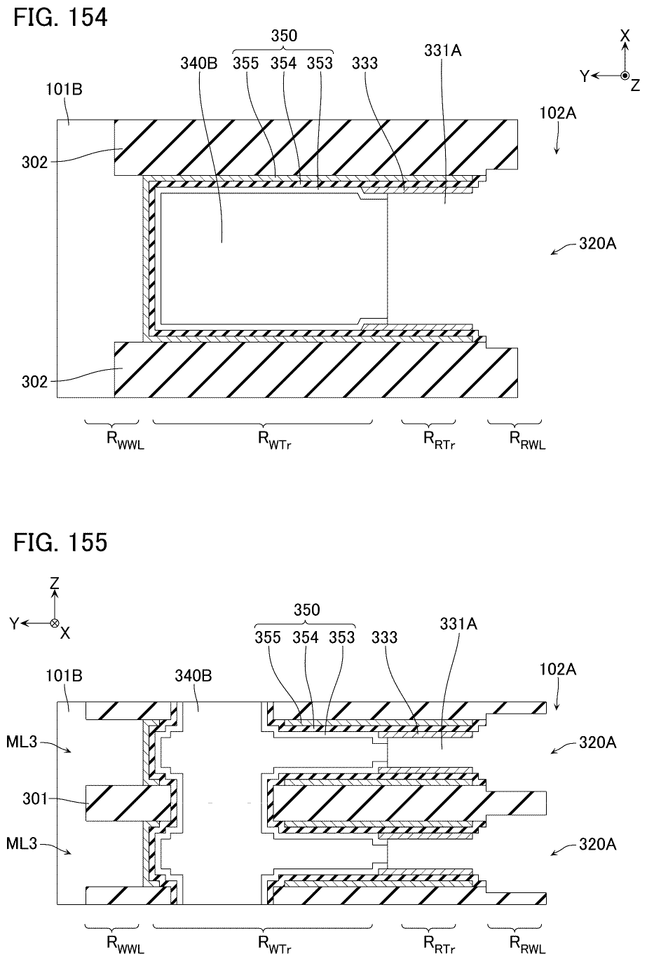

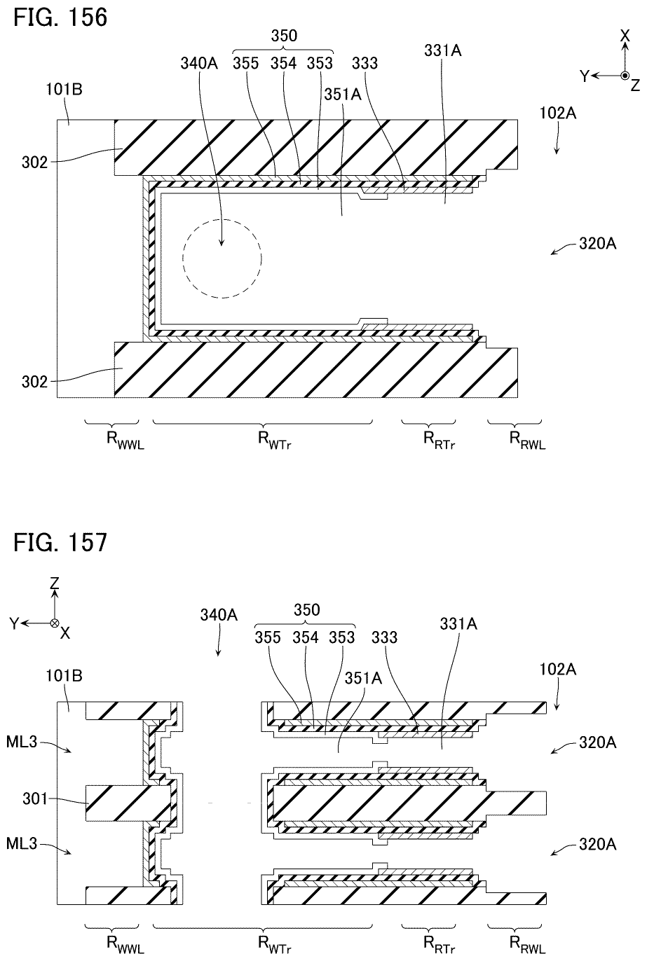

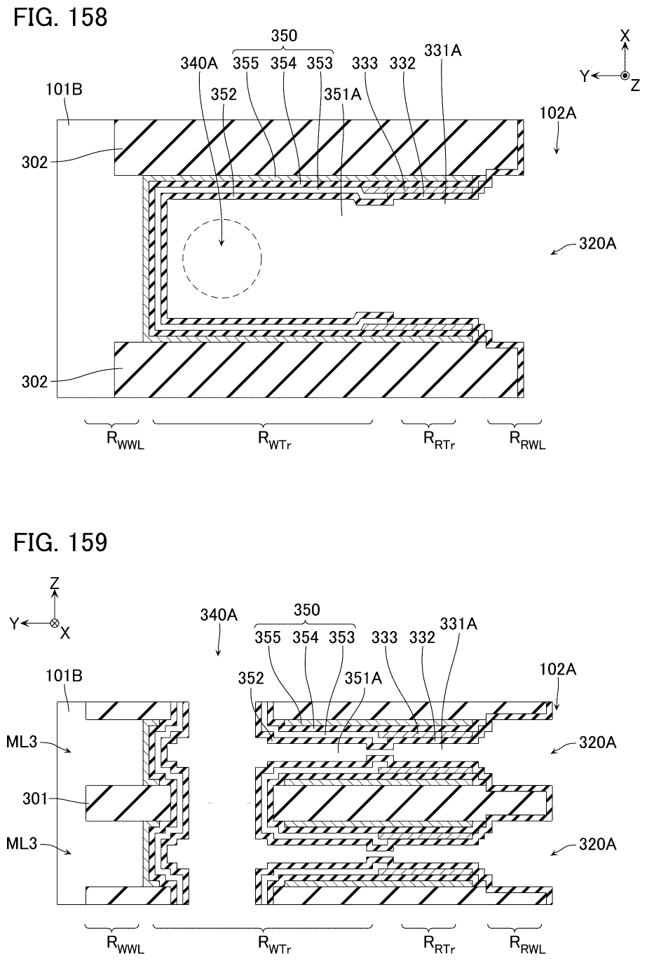

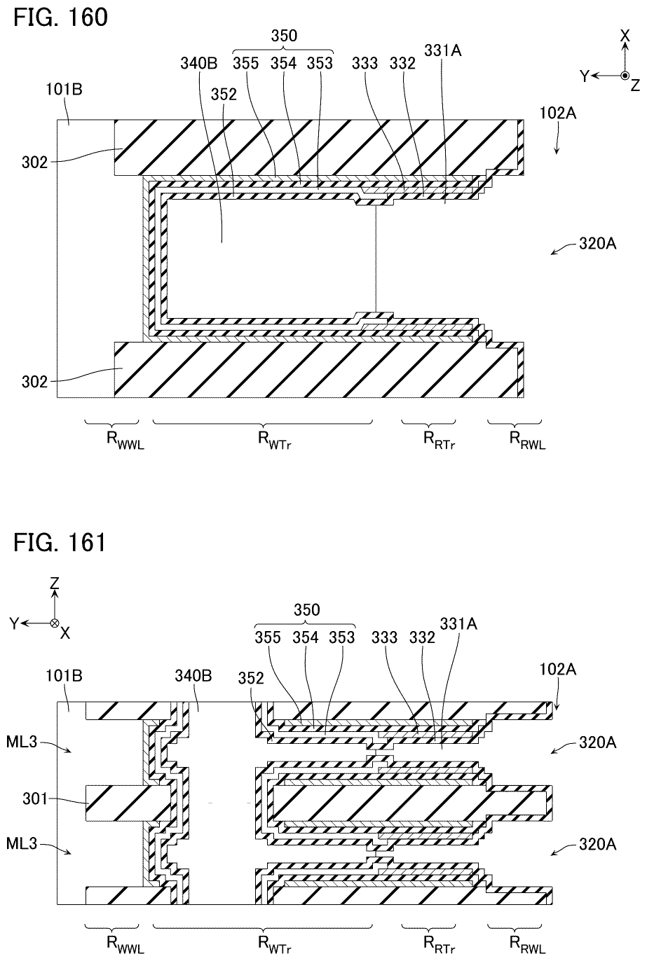

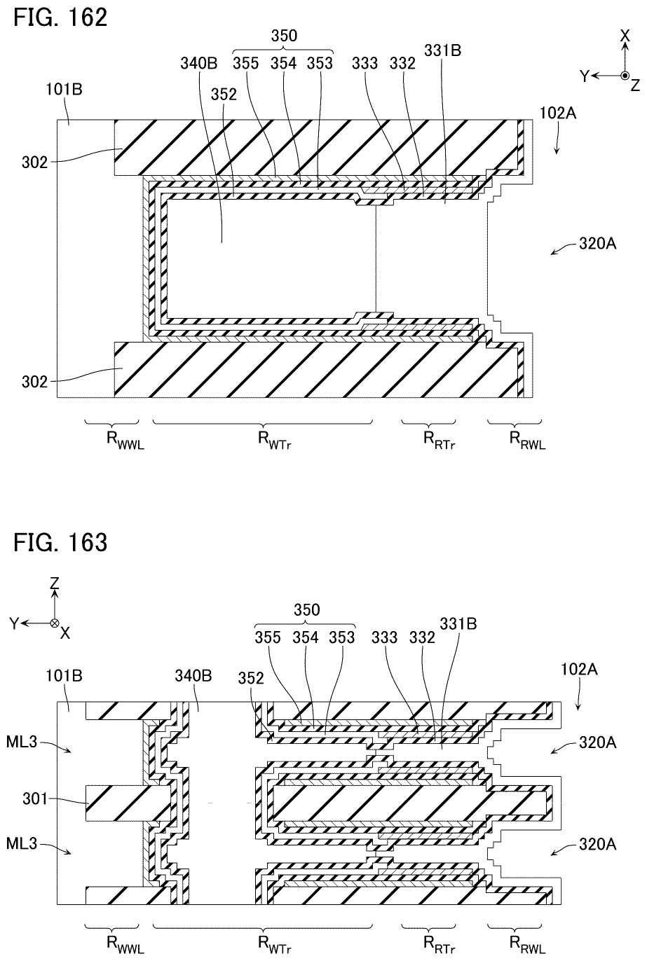

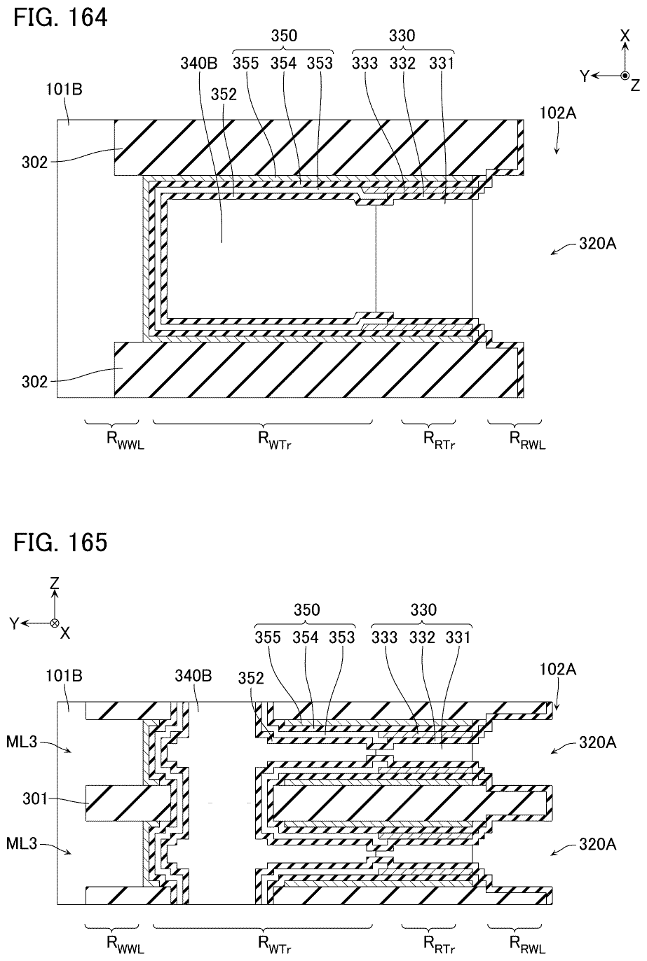

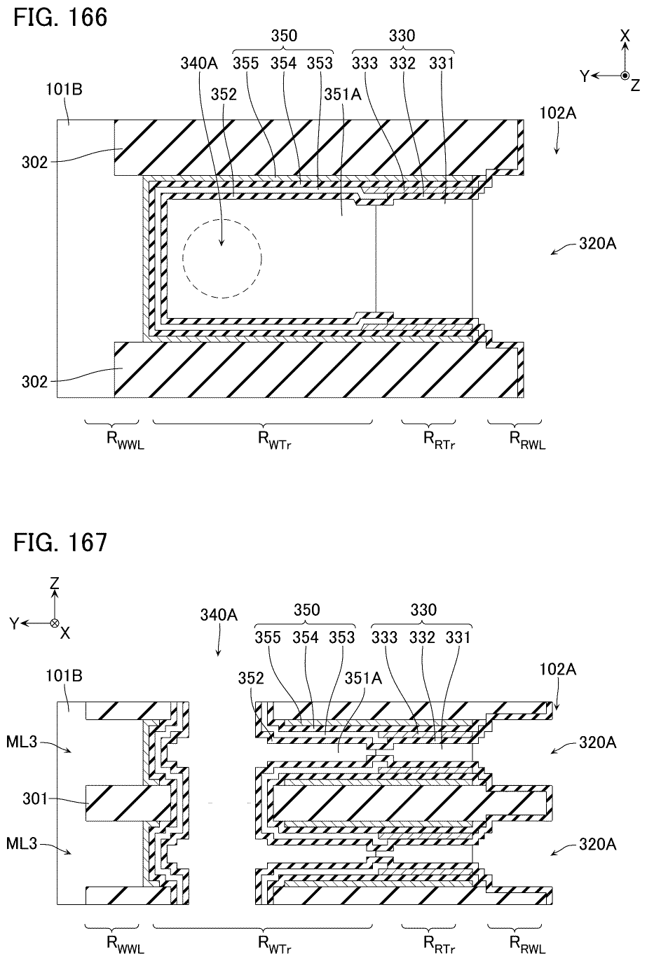

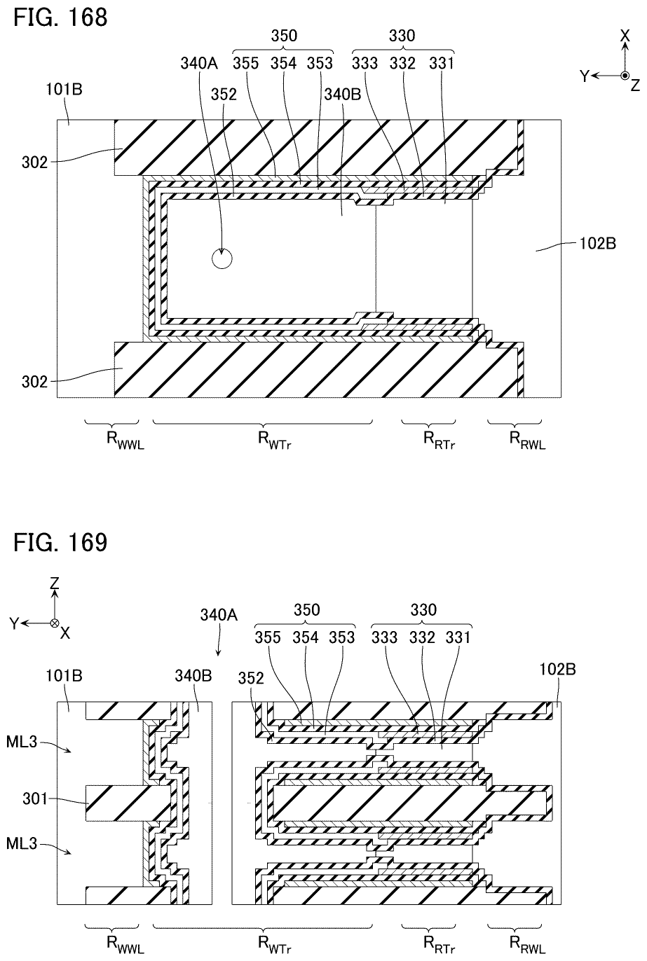

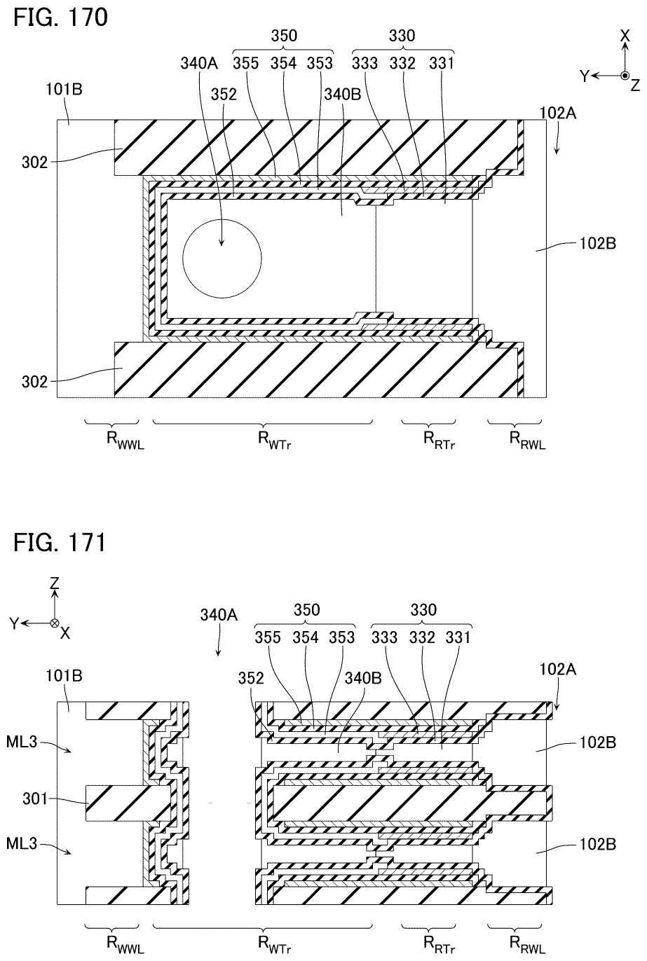

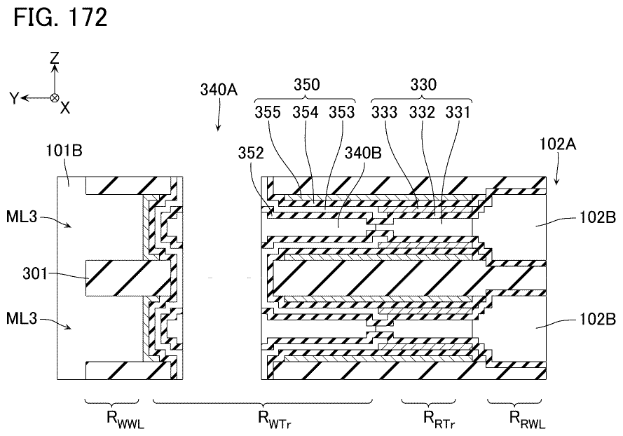

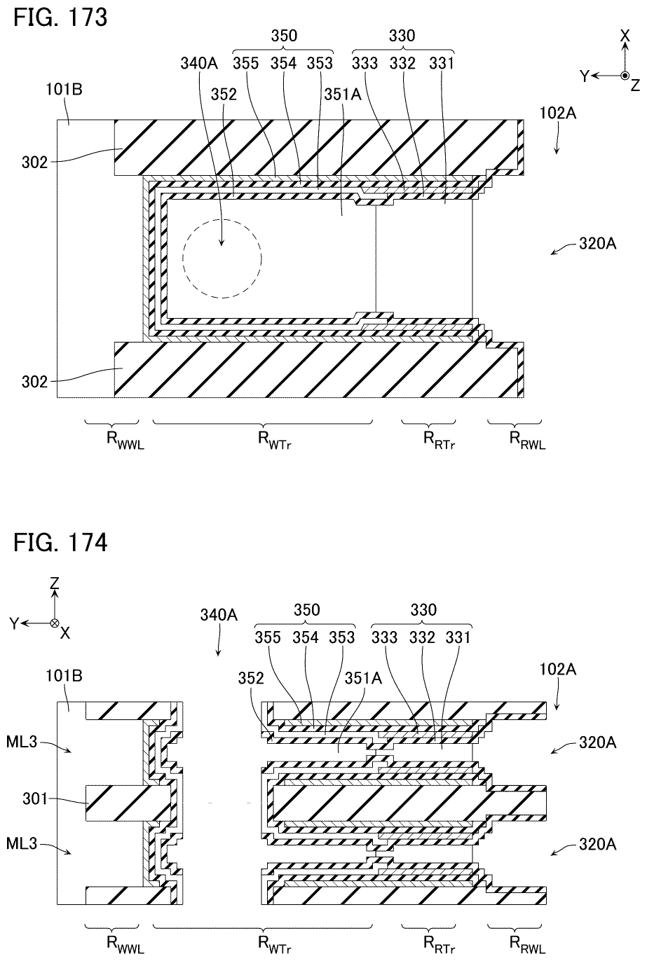

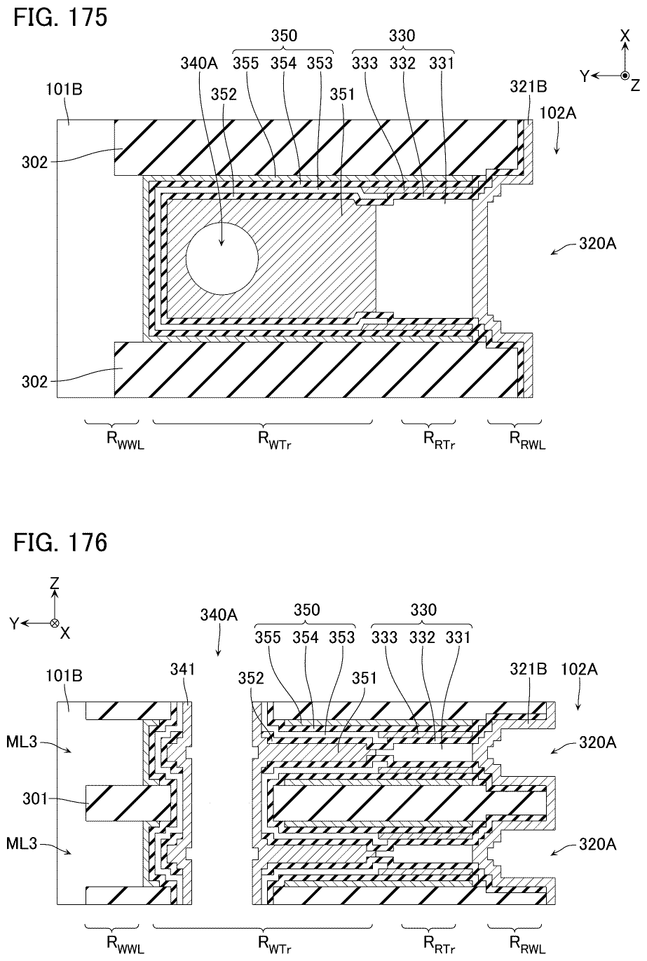

FIG. 114 to FIG. 176 are schematic cross-sectional views for describing a manufacturing method of the semiconductor memory device according to the third embodiment. FIG. 114, FIG. 116, FIG. 118, FIG. 120, FIG. 122, FIG. 124, FIG. 126, FIG. 128, FIG. 132, FIG. 134, FIG. 136, FIG. 138, FIG. 140, FIG. 142, FIG. 144, FIG. 146, FIG. 148, FIG. 150, FIG. 152, FIG. 154, FIG. 156, FIG. 158, FIG. 160, FIG. 162, FIG. 164, FIG. 166, FIG. 168, FIG. 170, FIG. 173, and FIG. 175 illustrate cross-sectional surfaces corresponding to FIG. 112. FIG. 115, FIG. 117, FIG. 119, FIG. 121, FIG. 123, FIG. 125, FIG. 127, FIG. 129, FIG. 130, FIG. 131, FIG. 133, FIG. 135, FIG. 137, FIG. 139, FIG. 141, FIG. 143, FIG. 145, FIG. 147, FIG. 149, FIG. 151, FIG. 153, FIG. 155, FIG. 157, FIG. 159, FIG. 161, FIG. 163, FIG. 165, FIG. 167, FIG. 169, FIG. 171, FIG. 172, FIG. 174, and FIG. 176 illustrate cross-sectional surfaces corresponding to FIG. 113.

In the manufacturing method, for example, as illustrated in FIG. 115, a plurality of insulating layers 301 and a plurality of sacrifice layers MLA3 are alternately formed. The sacrifice layer MLA3 contains, for example, silicon nitride (SiN). This process is performed by, for example, CVD.

Next, for example, as illustrated in FIG. 114, the insulating layers 302 are formed. In this process, for example, openings are formed at positions corresponding to the insulating layers 302. These openings extend in the Z-direction to penetrate the plurality of insulating layers 301 and the plurality of sacrifice layers MLA3 arranged in the Z-direction. This process is performed by, for example, RIE. After forming the openings, the insulating layers 302 are formed. This process is performed by, for example, CVD.

Next, for example, as illustrated in FIG. 116 and FIG. 117, at the proximities of positions corresponding to the wirings 310, 320, trenches 101A, 102A extending in the X-direction and the Z-direction are formed. The trenches 101A, 102A penetrate the plurality of insulating layers 301 and the plurality of sacrifice layers MLA3 arranged in the Z-direction to separate these configurations in the Y-direction. This process is performed by, for example, RIE.

Next, for example, as illustrated in FIG. 118 and FIG. 119, openings 310A, 320A are formed. Inside the openings 310A, 320A, parts of the upper surfaces and parts of the lower surfaces of the insulating layers 301, parts of the side surfaces of the insulating layers 302 in the X-direction, and parts of the side surfaces of the sacrifice layers MLA3 in the Y-direction are exposed. In this process, for example, parts of the sacrifice layers MLA3 are selectively removed via the trenches 101A, 102A. This process is performed by, for example, wet etching.

Next, for example, as illustrated in FIG. 120 and FIG. 121, a sacrifice layer 101B is filled inside the trench 101A and the openings 310A. A sacrifice layer 102B is filled inside the trench 102A and the openings 320A. This process is performed by, for example, CVD.

Next, for example, as illustrated in FIG. 122 and FIG. 123, an opening 340A is formed at a position corresponding to the wiring 340. The opening 340A penetrates the plurality of insulating layers 301 and the plurality of sacrifice layers MLA3 arranged in the Z-direction to extend in the Z-direction. This process is performed by, for example, RIE.

Next, for example, as illustrated in FIG. 124 and FIG. 125, the sacrifice layers MLA3 are removed via the opening 340A. This process is performed by, for example, wet etching. Through this process, openings 351A are formed at positions corresponding to the connection electrodes 351. Openings 331A are formed at positions corresponding to the semiconductor members 331. Parts of the upper surfaces and parts of the lower surfaces of the insulating layers 301, parts of the side surfaces of the insulating layer 302 in the X-direction, and parts of the side surfaces of the sacrifice layers 101B, 102B in the Y-direction are exposed inside the openings 351A, 331A.

Next, for example, as illustrated in FIG. 126 and FIG. 127, a conductive layer 355A and a sacrifice layer 340B are formed inside the openings 331A, 351A, and 340A. The conductive layer 355A is formed on parts of the upper surfaces, parts of the lower surfaces, and the side surfaces (inner peripheral surfaces of the opening 340A) of the insulating layers 301, parts of the side surfaces of the insulating layers 302 in the X-direction, and parts of the side surfaces of the sacrifice layers 101B, 102B in the Y-direction. The openings 331A, 351A are filled with the sacrifice layer 340B. The opening 340A is not filled with the sacrifice layer 340B. This process is performed by, for example, CVD.

Next, for example, as illustrated in FIG. 128 and FIG. 129, a part of the sacrifice layer 340B is removed to expose portions of the conductive layer 355A formed on the side surface (inner peripheral surface of the opening 340A) of the insulating layer 301. This process is performed by, for example, wet etching.

Next, for example, as illustrated in FIG. 130, the portions of the conductive layer 355A formed on the side surface (inner peripheral surface of the opening 340A) of the insulating layer 301 is removed. Through this process, the conductive layer 355A is separated in the Z-direction. This process is performed by, for example, wet etching.

Next, for example, as illustrated in FIG. 131, a sacrifice layer 340B is formed inside the opening 340A. In this process, the opening 340A is filled with the sacrifice layer 340B. This process is performed by, for example, CVD.

Next, although not illustrated, the sacrifice layer 102B is removed to expose a portion formed on the side surface of the sacrifice layer 340B of the conductive layer 355A. This process is performed by, for example, wet etching.

Next, for example, as illustrated in FIG. 132 and FIG. 133, portions of the conductive layer 355A formed on the side surfaces of the sacrifice layers 340B are removed. Through this process, the facing electrodes 355 are formed. This process is performed by, for example, wet etching.

Next, for example, as illustrated in FIG. 134 and FIG. 135, a sacrifice layer 102B is formed inside the openings 320A and the trench 102A. In this process, the openings 320A and the trench 102A are filled with the sacrifice layer 102B. This process is performed by, for example, CVD.

Next, for example, as illustrated in FIG. 136 and FIG. 137, the sacrifice layer 340B is removed. This process is performed by, for example, wet etching. Parts of the sacrifice layer 102B in contact with end surfaces of the facing electrodes 355 in the Y-direction are also removed.

Next, for example, as illustrated in FIG. 138 and FIG. 139, an insulating layer 354A, a conductive layer 333A, and a sacrifice layer 340B are formed inside the openings 331A, 351A, and 340A. The insulating layer 354A and the conductive layer 333A are each formed on upper surfaces, lower surfaces, both side surfaces in the X-direction, and side surfaces in the Y-direction of the conductive layers 355, and parts of the upper surfaces, parts of the lower surfaces, and the side surface (inner peripheral surface of the opening 340A) of the insulating layers 301. The openings 331A, 351A are filled with the sacrifice layer 340B. The opening 340A is not filled with the sacrifice layer 340B. This process is performed by, for example, CVD.

Next, for example, as illustrated in FIG. 140 and FIG. 141, a part of the sacrifice layer 340B is removed. In this process, portions of the sacrifice layer 340B formed in the read transistor region R_{RTr} are remained, and the other portion is removed. This process is performed by, for example, wet etching.

Next, for example, as illustrated in FIG. 142 and FIG. 143, parts of the conductive layer 333A are removed. In this process, portions of the conductive layer 333A formed in the read transistor region R_{RTr} are remained, and the other portion is removed. This process is performed by, for example, wet etching.

Next, for example, as illustrated in FIG. 144 and FIG. 145, the sacrifice layer 340B is removed. This process is performed by, for example, wet etching.

Next, for example, as illustrated in FIG. 146 and FIG. 147, a semiconductor member 353A and a sacrifice layer 340B are formed inside the openings 331A, 351A, and 340A. The semiconductor member 353A is formed on upper surfaces, lower surfaces, both side surfaces in the X-direction, and side surfaces in the Y-direction of the conductive layer 333A, and upper surfaces, lower surfaces, both side surfaces in the X-direction, side surfaces in the Y-direction, and portions formed on the inner peripheral surface of the opening 340A of the insulating layer 354A. In this process, the openings 331A, 351A, and 340A are filled with the sacrifice layer 340B. This process is performed by, for example, CVD.

Next, for example, as illustrated in FIG. 148 and FIG. 149, the sacrifice layer 102B is removed to expose portions of the insulating layer 354A formed on the side surfaces of the conductive layer 333A in the Y-direction. This process is performed by, for example, wet etching.

Next, for example, as illustrated in FIG. 150 and FIG. 151, portions of the insulating layer 354A, the conductive layer 333A, and the semiconductor member 353A formed on the side surfaces of the sacrifice layer 340B are removed. Through this process, the insulating layer 354 and the facing electrode 333 are formed. This process is performed by, for example, wet etching.

Next, for example, as illustrated in FIG. 152 and FIG. 153, portions of the sacrifice layer 340B formed in the read transistor region R_{RTr} are removed. This process is performed by, for example, wet etching.

Next, for example, as illustrated in FIG. 154 and FIG. 155, portions of the semiconductor member 353A formed in the read transistor region R_{RTr} are removed. Through this process, the semiconductor members 353 are formed. This process is performed by, for example, wet etching.

Next, for example, as illustrated in FIG. 156 and FIG. 157, the sacrifice layer 340B is removed to form openings 351A. This process is performed by, for example, wet etching.

Next, for example, as illustrated in FIG. 158 and FIG. 159, the insulating layers 332, 352 are formed inside the openings 331A, 351A, and 340A. The insulating layers 332, 352 are formed on the upper surfaces, the lower surfaces, and both side surfaces in the X-direction of the conductive layer 333, the upper surfaces, the lower surfaces, both side surfaces in the X-direction, the side surfaces in the Y-direction, and portions formed on the inner peripheral surface of the opening 340A of the semiconductor members 353, parts of the upper surfaces, parts of the lower surfaces, and the side surfaces in the Y-direction of the insulating layers 301, and parts of both side surfaces in the X-direction and the side surface in the Y-direction of the insulating layers 302. This process is performed by, for example, CVD.

Next, although not illustrated, a sacrifice layer 340B is formed inside the openings 331A, 351A, 340A, 320A, and 102A. In this process, the openings 331A, 351A, 340A, 320A, and 102A are filled with the sacrifice layer 340B. This process is performed by, for example, CVD.

Next, for example, as illustrated in FIG. 160 and FIG. 161, portions of the sacrifice layer 340B formed inside the openings 102A, 320A, and 331A are removed. This process is performed by, for example, wet etching.

Next, for example, as illustrated in FIG. 162 and FIG. 163, a semiconductor member 331B is formed inside the openings 102A, 320A, and 331A. The openings 331A are filled with the semiconductor member 331B. The openings 102A, 320A are not filled with the semiconductor member 331B. This process is performed by, for example, CVD.

Next, for example, as illustrated in FIG. 164 and FIG. 165, a part of the semiconductor member 331B is removed. In this process, portions of the semiconductor member 331B formed in the read transistor region R_{RTr} are remained, and the other portion is removed. Thus, the semiconductor member 331B is separated in the Z-direction. Portions of the semiconductor member 331B formed in the read transistor region R_{RTr} becomes the semiconductor members 331. This process is performed by, for example, wet etching.

Next, for example, as illustrated in FIG. 166 and FIG. 167, the sacrifice layer 340B is removed. This process is performed by, for example, wet etching.

Next, for example, as illustrated in FIG. 168 and FIG. 169, a sacrifice layer 102B is formed inside the trench 102A and the opening 320A. A sacrifice layer 340B is formed inside the openings 351A, 340A. The openings 320A, 351A are filled with the sacrifice layers 102B, 340B. The trench 102A and the opening 340A are not filled with the sacrifices layer 102B, 340B. This process is performed by, for example, CVD.

Next, for example, as illustrated in FIG. 170 and FIG. 171, a part of the sacrifice layer 102B is removed to expose portions of the insulating layer 332 covering the side surfaces (inner wall surface of the opening 102A) of the insulating layers 301 in the Y-direction. A part of the sacrifice layer 340B is removed to expose portions of the insulating layer 352 formed on the side surfaces (inner peripheral surface of the opening 340A) of the semiconductor member 353. This process is performed by, for example, wet etching.

Next, for example, as illustrated in FIG. 172, portions of the insulating layer 332 formed on the side surfaces (inner wall surface of the opening 102A) of the insulating layers 301 are removed. Portions of the insulating layer 352 formed on the side surfaces (inner peripheral surface of the opening 340A) of the semiconductor member 353 are removed. This process is performed by, for example, wet etching.

Next, for example, as illustrated in FIG. 173 and FIG. 174, the sacrifice layers 340B, 102B are removed. This process is performed by, for example, wet etching.

Next, for example, as illustrated in FIG. 175 and FIG. 176, a conductive oxide film 321B is formed inside the openings 102A, 320A. The conductive oxide film 321B is formed on the side surfaces of the semiconductor members 331 in the Y-direction, the upper surfaces, the lower surfaces, both side surfaces in the X-direction, and the side surfaces in the Y-direction of the insulating layers 332, and the side surfaces (inner wall surface of the opening 102A) of the insulating layers 301 in the Y-direction. The connection electrodes 351 are formed inside the openings 351A, and the conductive oxide film 341 is formed inside the opening 340A. This process is performed by, for example, CVD.

Then, the sacrifice layer 101B is removed by, for example, wet etching. The wirings 310, 320, and 340 are formed by CVD, wet etching, and the like, thereby manufacturing the semiconductor memory device according to the third embodiment.

### Fourth Embodiment

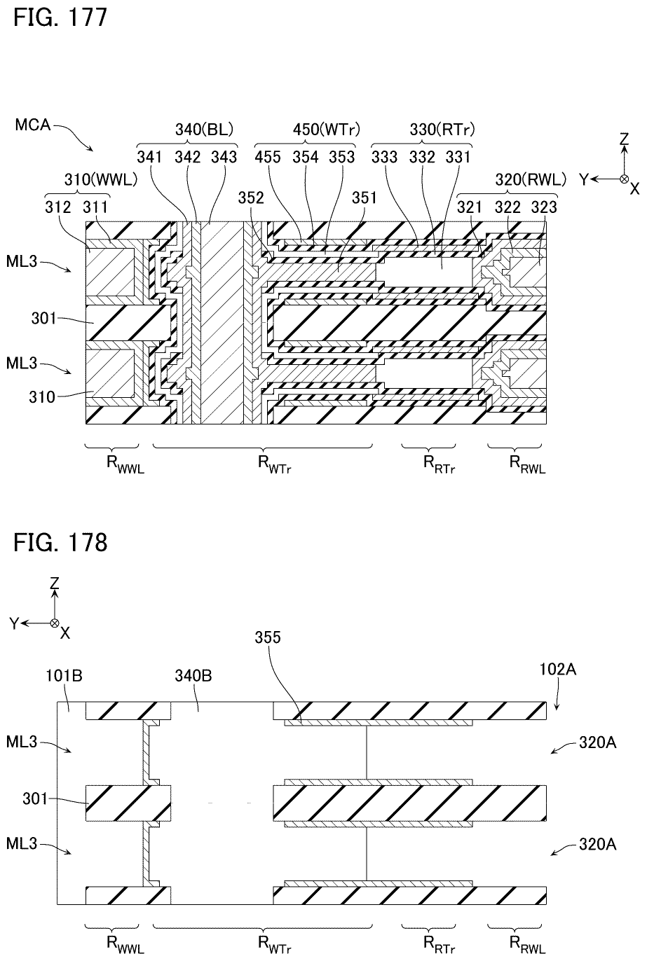

FIG. 177 is a schematic cross-sectional view illustrating a configuration of a part of a semiconductor memory device according to a fourth embodiment. FIG. 177 corresponds to the YZ cross-sectional surface. In the following description, the same reference numerals are attached to parts similar to those in the third embodiment, and the explanation is omitted.

The semiconductor memory device according to the fourth embodiment is basically configured similarly to the semiconductor memory device according to the third embodiment. However, the semiconductor memory device according to the fourth embodiment includes a transistor structure 450 instead of the transistor structure 350. The transistor structure 450 is basically configured similarly to the transistor structure 350. However, the transistor structure 450 includes a facing electrode 455 instead of the facing electrode 355.

The facing electrode 455 is basically configured similarly to the facing electrode 355. However, the facing electrode 455 is provided only in the write transistor region R_{WTr}, and is not provided in the read transistor region R_{RTr}. Therefore, in this embodiment, the upper surface, the lower surface, and both side surfaces in the X-direction of the transistor structure 330 are not covered with the facing electrode 455.

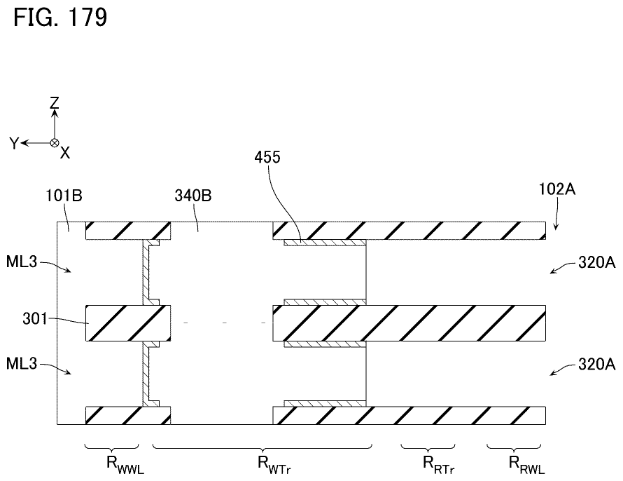

FIG. 178 and FIG. 179 are schematic cross-sectional views for describing a manufacturing method of the semiconductor memory device according to the fourth embodiment. FIG. 178 and FIG. 179 illustrate cross-sectional surfaces corresponding to FIG. 177.

The semiconductor memory device according to the fourth embodiment is basically manufactured similarly to the semiconductor memory device according to the third embodiment.

However, in the manufacture of the semiconductor memory device according to the third embodiment, after executing the process described with reference to FIG. 132 and FIG. 133 and before executing the process described with reference to FIG. 134 and FIG. 135, as illustrated in FIG. 178, portions of the sacrifice layer 340B formed in the read transistor region R_{RTr} are removed. This process is performed by, for example, wet etching.

As illustrated in FIG. 179, portions of the facing electrode 355 formed in the read transistor region R_{RTr} are removed. Through this process, the facing electrodes 455 are formed. This process is performed by, for example, wet etching.

### Other Embodiments

The semiconductor memory devices according to the first embodiment to the fourth embodiment are described above. However, the semiconductor memory devices according to these embodiments are only examples, and the specific configuration and the like can be adjusted as appropriate.

For example, in the first embodiment and the second embodiment, a conductive oxide film may be disposed between the facing electrode 133 and the semiconductor member 143. The conductive oxide film may contain a conductive material containing oxygen, for example, indium tin oxide (ITO), indium zinc oxide (IZO), ruthenium oxide (RuO), iridium oxide (IrO), or the like.

For example, in the first embodiment and the second embodiment, a metal layer containing ruthenium (Ru), iridium (Ir), or another material may be disposed between the facing electrode 133 and the semiconductor member 143.

The manufacturing methods of the semiconductor memory device according to the first embodiment to the fourth embodiment can be appropriately adjusted as well. For example, the order of any two of the above-described processes may be interchanged, or any two of the above-described processes may be simultaneously executed.

The facing electrode 145 of the semiconductor memory device according to the first embodiment and the second embodiment may face not only the upper surface and the lower surface of the semiconductor member 143, but also the upper surface and the lower surface of the facing electrode 133.

When manufacturing this structure, for example, it is considered to remove not only the portions of the insulating layer 135 formed in the write transistor region R_{WTr}, but also the portions of the insulating layer 135 formed in the read transistor region R_{RTr} in the process described with reference to FIG. 55 and FIG. 56.

In the semiconductor memory device according to the second embodiment, the write transistor WTr may be achieved by the transistor structure 350 according to the third embodiment or the transistor structure 450 according to the fourth embodiment. Similarly, the read transistor RTr may be achieved by the transistor structure 330 according to the third embodiment. Furthermore, in the semiconductor memory device according to the first embodiment, the write transistor WTr may be achieved by the transistor structure 350 according to the third embodiment or the transistor structure 450 according to the fourth embodiment.

The read transistor RTr may be not an NMOS transistor but a PMOS transistor. In this case, the connection electrodes 141, 151 may contain not the N-type impurities, such as phosphorus (P), but the P-type impurities, such as boron (B).

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a first wiring extending in a first direction;
a second wiring extending in a second direction intersecting with the first direction;
a first semiconductor member disposed between the first wiring and the second wiring, extending in a third direction intersecting with the first direction and the second direction, and electrically connected to the first wiring and the second wiring;
a first facing electrode facing both surfaces of the first semiconductor member in the first direction and both surfaces of the first semiconductor member in the second direction;
a first connection electrode extending in the third direction and connected to the first semiconductor member and the first wiring;
a second semiconductor member extending in the third direction along both surfaces of the first connection electrode in the first direction and both surfaces of the first connection electrode in the second direction, and connected to the first facing electrode and the first wiring; and
a second facing electrode facing both surfaces of the second semiconductor member in the first direction.

2. The semiconductor memory device according to claim 1, wherein
the second facing electrode faces both surfaces of the second semiconductor member in the second direction.

3. The semiconductor memory device according to claim 1, wherein
the second facing electrode is a part of a wiring extending in the second direction.

4. The semiconductor memory device according to claim 1, wherein
the first semiconductor member contains silicon (Si), and
the second semiconductor member contains an oxide semiconductor.

5. The semiconductor memory device according to claim 4, wherein
the first connection electrode contains silicon (Si) and N-type or P-type impurity.

6. The semiconductor memory device according to claim 4, wherein
the oxide semiconductor contains at least one element of gallium (Ga) or aluminum (Al), and contains indium (In), zinc (Zn), and oxygen (O).

7. The semiconductor memory device according to claim 1, comprising
a second connection electrode extending in the third direction and connected to the first semiconductor member and the second wiring.

8. The semiconductor memory device according to claim 7, wherein
the first semiconductor member contains silicon (Si),
the second semiconductor member contains an oxide semiconductor, and
the first connection electrode and the second connection electrode contain silicon (Si) and N-type or P-type impurity.

9. The semiconductor memory device according to claim 1, comprising
a third facing electrode disposed between the first facing electrode and the second wiring and facing both surfaces of the first semiconductor member in the first direction.

10. The semiconductor memory device according to claim 9, wherein
the third facing electrode faces both surfaces of the first semiconductor member in the second direction.

11. The semiconductor memory device according to claim 9, wherein
the third facing electrode is a part of a wiring extending in the second direction.

12. The semiconductor memory device according to claim 1, wherein
the first connection electrode covers an outer peripheral surface of the first wiring when viewed in the first direction,
the second semiconductor member covers a surface of the first connection electrode on an opposite side of the second wiring in the third direction, and
the second facing electrode covers a surface of the second semiconductor member on the opposite side of the second wiring in the third direction.

13. The semiconductor memory device according to claim 1, wherein
the second semiconductor member covers an outer peripheral surface of the first wiring when viewed in the first direction, and is in contact with the outer peripheral surface of the first wiring.

14. The semiconductor memory device according to claim 1, further comprising
a third wiring extending in the second direction and connected to a surface of the second facing electrode on an opposite side of the second wiring in the third direction.

15. The semiconductor memory device according to claim 1, wherein
the second facing electrode covers both surfaces of the first facing electrode in the first direction.

16. The semiconductor memory device according to claim 1, wherein
the first semiconductor member contains an oxide semiconductor.

17. The semiconductor memory device according to claim 16, wherein
the oxide semiconductor contains at least one element of gallium (Ga) or aluminum (Al), and contains indium (In), zinc (Zn), and oxygen (O).
